(19) United States
(12) Patent Application Publication
(10) Pub. No.: US 2026/0090013 A1
(43) Pub. Date: Mar. 26, 2026

(54) ELECTRONIC COMPONENT

(71) Applicant: ROHM CO., LTD., Kyoto-shi (JP)

(72) Inventors: Seigo MORI, Kyoto-shi (JP); Yuki NAKANO, Kyoto-shi (JP)

(73) Assignee: ROHM CO., LTD., Kyoto-shi (JP)

(21) Appl. No.: 19/404,127

(22) Filed: Dec. 1, 2025

Related U.S. Application Data
(63) Continuation of application No. PCT/JP2024/019655, filed on May 29, 2024.

(30) Foreign Application Priority Data
Jun. 2, 2023 (JP) 2023-091948

(51) Int. Cl. H10D 30/66; H01L 23/31; H10D 62/10; H10D 62/60; H10D 62/832; H10D 64/23; H10D 64/27

(52) U.S. Cl. CPC H10D 30/668; H10D 30/665; H10D 62/107; H10D 62/126; H10D 62/8325; H10D 64/2527; H10D 64/518; H10W 74/147; H10D 62/60

(57) ABSTRACT

An electronic component includes a covered object, an electrode that is arranged on the covered object and has an electrode side wall on the covered object, a wiring that is arranged on the covered object in a periphery of the electrode, an inorganic film with an insulating property that has an inner covering portion covering the electrode so as to expose the electrode side wall and an outer covering portion covering the wiring at an interval from the inner covering portion, and an organic film with an insulating property that extends across the inner covering portion and the outer covering portion and covers the electrode between the inner covering portion and the outer covering portion.

### CROSS-REFERENCE TO RELATED APPLICATIONS

The present application is a bypass continuation of International Patent Application No. PCT/JP2024/019655 filed on May 29, 2024, which claims priority to Japanese Patent Application No. 2023-091948 filed on Jun. 2, 2023, in the Japan Patent Office, and the entire disclosure of these applications is incorporated herein by reference.

### BACKGROUND

### 1. Field of the Disclosure

The present disclosure relates to an electronic component.

### 2. Description of the Related Art

US 2019/0080976A1 discloses a semiconductor device that includes a semiconductor substrate, an interlayer insulating layer, an electrode, an inorganic protective layer, and an organic protective layer. The interlayer insulating layer is formed on the semiconductor substrate and has an opening portion that exposes the semiconductor substrate. The electrode enters into the opening portion from above the interlayer insulating layer and is electrically connected to the semiconductor substrate inside the opening portion. The inorganic protective layer covers an edge portion of the electrode and an outer edge portion that covers the interlayer insulating layer. The organic protective layer covers the electrode and the interlayer insulating layer with the inorganic protective layer interposed therebetween.

### BRIEF DESCRIPTION OF DRAWINGS

FIG. 1 is a plan view showing a semiconductor device.

FIG. 2 is a sectional view taken along line II-II shown in FIG. 1.

FIG. 3 is a sectional view taken along line III-III shown in FIG. 1.

FIG. 4 is a plan view showing a layout example of a first main surface.

FIG. 5 is an enlarged plan view showing a principal portion of an active region.

FIG. 6 is a sectional view taken along line VI-VI shown in FIG. 5.

FIG. 7 is a sectional view taken along line VII-VII shown in FIG. 5.

FIG. 8 is an enlarged plan view showing a principal portion of a first side end region.

FIG. 9 is a sectional view taken along line IX-IX shown in FIG. 8.

FIG. 10 is a sectional view taken along line X-X shown in FIG. 8.

FIG. 11 is a sectional view taken along line XI-XI shown in FIG. 8.

FIG. 12 is a sectional view taken along line XII-XII shown in FIG. 8.

FIG. 13 is an enlarged plan view showing a principal portion of a first terminal region.

FIG. 14 is a sectional view taken along line XIV-XIV shown in FIG. 13.

FIG. 15 is an enlarged plan view showing a principal portion of a third terminal region.

FIG. 16 is a sectional view taken along line XVI-XVI shown in FIG. 15.

FIG. 17 is a sectional view taken along line XVII-XVII shown in FIG. 1.

FIG. 18 is a sectional view taken along line XVIII-XVIII shown in FIG. 1.

FIG. 19 is a plan view showing a layout example of a main electrode.

FIG. 20 is a plan view showing a first layout example of a second inorganic film.

FIG. 21 is an enlarged plan view showing a principal portion of the second inorganic film.

FIG. 22A is a sectional view showing a second layout example of the second inorganic film.

FIG. 22B is a sectional view showing a third layout example of the second inorganic film.

FIG. 22C is a sectional view showing a fourth layout example of the second inorganic film.

FIG. 22D is a sectional view showing a fifth layout example of the second inorganic film.

FIG. 22E is a sectional view showing a sixth layout example of the second inorganic film.

FIG. 22F is an enlarged plan view showing a seventh layout example of the second inorganic film.

FIG. 22G is an enlarged plan view showing an eighth layout example of the second inorganic film.

FIG. 22H is an enlarged plan view showing a ninth layout example of the second inorganic film.

FIG. 22I is a sectional view showing a tenth layout example of the second inorganic film.

FIG. 22J is a sectional view showing an eleventh layout example of the second inorganic film.

FIG. 22K is a sectional view showing a twelfth layout example of the second inorganic film.

FIG. 22L is a sectional view showing a thirteenth layout example of the second inorganic film.

FIG. 22M is a sectional view showing a fourteenth layout example of the second inorganic film.

FIG. 22N is a sectional view showing a fifteenth layout example of the second inorganic film.

FIG. 22O is a sectional view showing a sixteenth layout example of the second inorganic film.

FIG. 22P is a sectional view showing a seventeenth layout example of the second inorganic film.

FIG. 22Q is a sectional view showing an eighteenth layout example of the second inorganic film.

FIG. 22R is a sectional view showing a nineteenth layout example of the second inorganic film.

### DETAILED DESCRIPTION OF THE PREFERRED EMBODIMENTS

Hereinafter, specific embodiments shall be described in detail with reference to attached drawings. The attached drawings are all schematic views and are not strictly illustrated, and relative positional relationships, scales, proportions, angles and the like thereof do not always match. Identical reference signs are given to corresponding structures among the attached drawings, and duplicate descriptions thereof shall be omitted or simplified. For the structures whose description have been omitted or simplified, the description given before the omission or simplification shall apply.

When the wording “substantially equal” is used in this description, the wording includes a numerical value (shape) equal to a numerical value (shape) of a comparison target and also includes numerical errors (shape errors) in a range of ±10% on a basis of the numerical value (shape) of the comparison target. Although the wordings “first,” “second,” “third,” etc., are used in the following description, these are symbols attached to names of respective structures in order to clarify the order of description and are not attached with an intention of restricting the names of the respective structures.

In the following description, a conductivity type of a semiconductor (an impurity) is indicated using “p-type” or “n-type” and the “p-type” may be referred to as a “first conductivity type” and the “n-type” may be referred to as a “second conductivity type.” As a matter of course, the “n-type” may be referred to as the “first conductivity type” and the “p-type” may be referred to as the “second conductivity type” instead. The “p-type” is a conductivity type due to a trivalent element and the “n-type” is a conductivity type due to a pentavalent element. The trivalent element is at least one type among boron, aluminum, gallium, and indium. The pentavalent element is at least one type among nitrogen, phosphorus, arsenic, antimony, and bismuth.

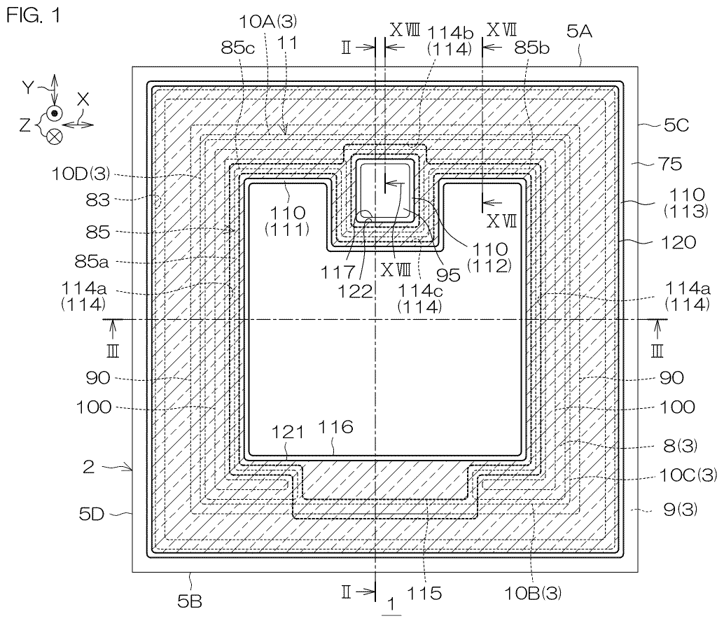

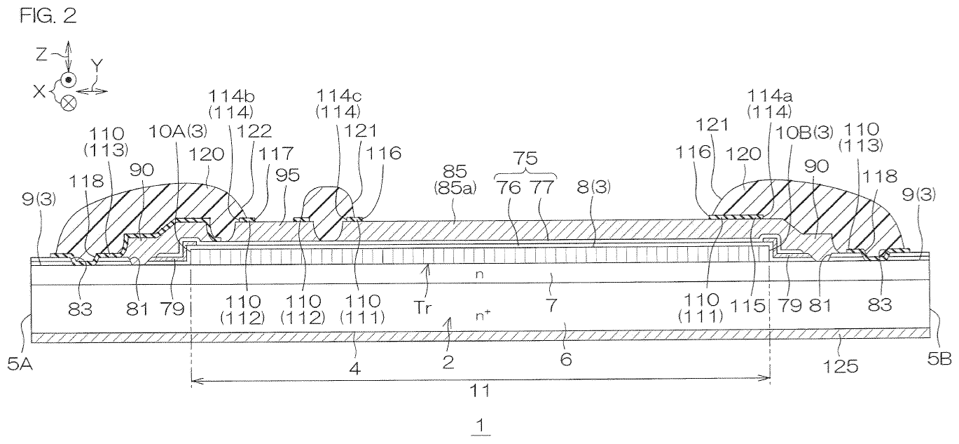

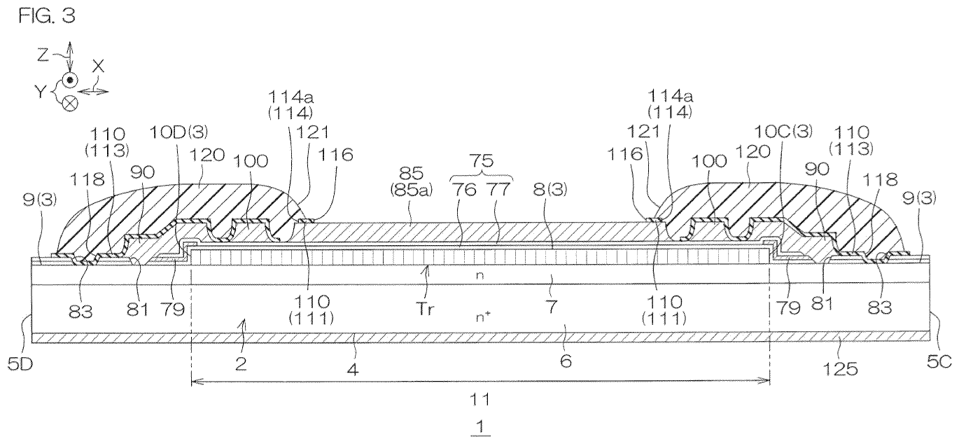

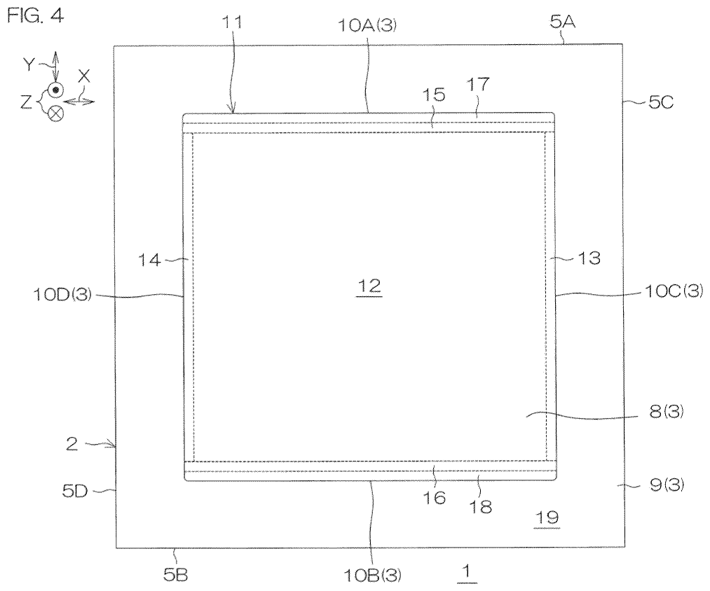

FIG. 1 is a plan view showing a semiconductor device 1 (an electronic component). FIG. 2 is a sectional view taken along line II-II shown in FIG. 1. FIG. 3 is a sectional view taken along line III-III shown in FIG. 1. FIG. 4 is a plan view showing a layout example of a first main surface 3. The semiconductor device 1 is a semiconductor switching device that includes a transistor structure Tr of an insulated gate type. The transistor structure Tr may be referred to as a MISFET structure (metal insulator semiconductor field effect transistor structure).

With reference to FIG. 1 to FIG. 4, in this embodiment, the semiconductor device 1 includes a chip 2 including a monocrystal of a wide bandgap semiconductor and formed in a hexahedral shape (specifically, a rectangular parallelepiped shape). That is, the semiconductor device 1 is a “wide bandgap semiconductor device.” The chip 2 may also be referred to as a “semiconductor chip” or a “wide bandgap semiconductor chip,” etc.

The wide bandgap semiconductor is a semiconductor that has a bandgap exceeding a bandgap of Si (silicon). GaN (gallium nitride), SiC (silicon carbide), C (diamond), etc., can be given as examples of the wide bandgap semiconductor. In this embodiment, the chip 2 is an “SiC chip” that includes, as an example of the wide bandgap semiconductor, an SiC monocrystal that is a hexagonal crystal. That is, the semiconductor device 1 is an “SiC semiconductor device.”

The semiconductor device 1 may also be referred to as an “SiC-MISFET.” The SiC monocrystal that is a hexagonal crystal has multiple polytypes including a 2H (hexagonal)-SiC monocrystal, a 4H—SiC monocrystal, a 6H—SiC monocrystal, etc. In this embodiment, an example in which the chip 2 includes the 4H—SiC monocrystal is given, but the chip 2 may include another polytype instead.

The chip 2 has the first main surface 3 on one side, a second main surface 4 on the other side, and first to fourth side surfaces 5A to 5D connecting the first main surface 3 and the second main surface 4. In a plan view as viewed from a vertical direction Z (hereinafter referred to simply as “plan view”), the first main surface 3 and the second main surface 4 are formed in quadrangle shapes. The vertical direction Z is also a thickness direction of the chip 2.

The first main surface 3 and the second main surface 4 are preferably formed by c-planes of the SiC monocrystal. In this case, preferably, the first main surface 3 is formed by a silicon plane (a (0001) plane) of the SiC monocrystal and the second main surface 4 is formed by a carbon plane (a (000-1) plane) of the SiC monocrystal.

The first side surface 5A and the second side surface 5B extend in a first direction X oriented along the first main surface 3 and are opposed in a second direction Y that intersects the first direction X along the first main surface 3. Specifically, the second direction Y is orthogonal to the first direction X. The third side surface 5C and the fourth side surface 5D extend in the second direction Y and are opposed in the first direction X.

In this embodiment, the first direction X is an a-axis direction (a [11-20] direction) of the SiC monocrystal and the second direction Y is an m-axis direction (a [1-100] direction) of the SiC monocrystal. As a matter of course, the first direction X may be the m-axis direction of the SiC monocrystal and the second direction Y may be the a-axis direction of the SiC monocrystal instead. In the following, directions extending along the first main surface 3 are expressed at times as “horizontal directions.” The horizontal directions are also an XY plane (horizontal plane) formed by the first direction X and the second direction Y and are orthogonal to the vertical direction Z.

The first main surface 3 and the second main surface 4 may have an off angle inclined at a predetermined angle in a predetermined off direction with respect to the c-plane. The off direction is preferably the a-axis direction (the [11-20] direction) of the SiC monocrystal. The off angle may exceed 0° and be not more than 10°. The off angle is preferably not more than 5°.

The chip 2 (the first main surface 3 and the second main surface 4) has the off angle inclined at the predetermined angle in the predetermined off direction with respect to the c-plane of the SiC monocrystal. That is, a c-axis (a (0001) axis) of the SiC monocrystal is inclined by just the off angle toward the off direction from a vertical line. Also, the c-plane of the SiC monocrystal is inclined by just the off angle with respect to the horizontal plane.

The off direction is preferably the a-axis direction (that is, the first direction X) of the SiC monocrystal. The off angle may exceed 0° and be not more than 10°. The off angle may have a value belonging to at least one range among exceeding 0° and being not more than 1°, being not less than 1° and not more than 2.5°, being not less than 2.5° and not more than 5°, being not less than 5° and not more than 7.5°, and being not less than 7.5° and not more than 10°.

The off angle is preferably not more than 5°. The off angle is particularly preferably not less than 2° and not more than 4.5°. The off angle is typically set in a range of 4°+0.1°. This Description does not exclude an embodiment in which the off angle is 0° (that is, an embodiment in which the first main surface 3 is a just surface with respect to the c-plane).

The semiconductor device 1 includes a first semiconductor region 6 of the n-type that is formed in a surface layer portion of second main surface 4 of the chip 2. A drain potential is applied as a first potential (a high potential) to the first semiconductor region 6. The first semiconductor region 6 may be referred to as a “semiconductor layer,” a “first semiconductor layer,” a “drain region,” etc. The first semiconductor region 6 is formed in a layered shape extending along the second main surface 4 and is exposed from the second main surface 4 of the chip 2 and the first to fourth side surfaces 5A to 5D of the chip 2.

In this embodiment, the first semiconductor region 6 is constituted of a semiconductor layer of the n-type. Specifically, the first semiconductor region 6 is constituted of a substrate (an SiC substrate) that includes an SiC monocrystal (a semiconductor monocrystal) and forms the second main surface 4 of the chip 2 and the first to fourth side surfaces 5A to 5D of the chip 2. The first semiconductor region 6 (the substrate) has the off direction and the off angle described above.

The first semiconductor region 6 may have a thickness of not less than 10 μm and not more than 500 μm. The thickness of the first semiconductor region 6 may have a value belonging to at least one range among not less than 10 μm and not more than 50 μm, not less than 50 μm and not more than 100 μm, not less than 100 μm and not more than 150 μm, not less than 150 μm and not more than 200 μm, not less than 200 μm and not more than 300 μm, not less than 300 μm and not more than 400 μm, and not less than 400 μm and not more than 500 μm.

The semiconductor device 1 includes a second semiconductor region 7 of the n-type that is formed in a surface layer portion of first main surface 3 of the chip 2. The second semiconductor region 7 may be referred to as a “semiconductor layer,” a “second semiconductor layer,” a “drift region,” etc. The second semiconductor region 7 has an n-type impurity concentration that is less than an n-type impurity concentration of the first semiconductor region 6.

The second semiconductor region 7 is formed in a layered shape extending along the first main surface 3 and is electrically connected to the first semiconductor region 6. The second semiconductor region 7 is exposed from the first main surface 3 of the chip 2 and the first to fourth side surfaces 5A to 5D of the chip 2. In this embodiment, the second semiconductor region 7 is constituted of a semiconductor layer of the n-type.

In this embodiment, the second semiconductor region 7 is constituted of a semiconductor layer of the n-type. Specifically, the second semiconductor region 7 is constituted of an epitaxial layer (an SiC epitaxial layer) including an SiC monocrystal (a semiconductor monocrystal) and forms the first main surface 3 of the chip 2 and the first to fourth side surfaces 5A to 5D of the chip 2. The second semiconductor region 7 (the epitaxial layer) has the off direction and the off angle described above.

The second semiconductor region 7 preferably has a thickness less than the thickness of the first semiconductor region 6. As a matter of course, the thickness of the second semiconductor region 7 may instead be greater than the thickness of the first semiconductor region 6. The thickness of the second semiconductor region 7 may be not less than 5 μm and not more than 50 μm.

The thickness of the second semiconductor region 7 may have a value belonging to at least one range among not less than 5 μm and not more than 10 μm, not less than 10 μm and not more than 15 μm, not less than 15 μm and not more than 20 μm, not less than 20 μm and not more than 25 μm, not less than 25 μm and not more than 30 μm, not less than 30 μm and not more than 35 μm, not less than 35 μm and not more than 40 μm, not less than 40 μm and not more than 45 μm, and not less than 45 μm and not more than 50 μm.

The semiconductor device 1 includes a first surface portion 8, a second surface portion 9, and first to fourth connecting surface portions 10A to 10D that are formed in the first main surface 3. The first surface portion 8, the second surface portion 9, and the first to fourth connecting surface portions 10A to 10D demarcate a mesa 11 in the first main surface 3. The first surface portion 8, the second surface portion 9, and the first to fourth connecting surface portions 10A to 10D (that is, the mesa 11) may be regarded as constituent elements of the chip 2 (the first main surface 3).

The first surface portion 8 may be referred to as an “active surface,” the second surface portion 9 may be referred to as an “outer surface,” the first to fourth connecting surface portions 10A to 10D may be referred to as “connecting surfaces,” and the mesa 11 may be referred to as an “active mesa.”

The first surface portion 8 is formed at intervals inward from peripheral edges of the first main surface 3 (from the first to fourth side surfaces 5A to 5D). The first surface portion 8 has a flat surface extending in the horizontal directions and is formed by a c-plane (an Si plane). In this embodiment, the first surface portion 8 is formed in a polygonal shape (specifically, a quadrangle shape) having four sides parallel to the first to fourth side surfaces 5A to 5D in plan view. A planar area of the first surface portion 8 is preferably not less than 50% and not more than 90% of a planar area of the first main surface 3.

The second surface portion 9 is positioned at a peripheral edge portion side of the first main surface 3 with respect to the first surface portion 8 and is recessed in the thickness direction (to the second main surface 4 side) of the chip 2 from a height position of the first surface portion 8. In plan view, the second surface portion 9 extends in a band shape along the first surface portion 8 and is formed in an annular shape (specifically, a quadrangle annular shape) surrounding the first surface portion 8. The second surface portion 9 is continuous to the first to fourth side surfaces 5A to 5D.

The second surface portion 9 is formed substantially parallel to the first surface portion 8 and has a flat surface extending in the horizontal directions. In this embodiment, the second surface portion 9 is formed by a c-plane (an Si plane). The second surface portion 9 is formed in the second semiconductor region 7 at an interval from the first semiconductor region 6. That is, the second surface portion 9 is recessed to a depth less than the thickness of the second semiconductor region 7 and exposes the second semiconductor region 7.

The second surface portion 9 has a depth of not less than 0.1 μm and not more than 3 μm. The depth of the second surface portion 9 may have a value belonging to at least one range among not less than 0.1 μm and not more than 0.5 μm, not less than 0.5 μm and not more than 1 μm, not less than 1 μm and not more than 1.5 μm, not less than 1.5 μm and not more than 2 μm, not less than 2 μm and not more than 2.5 μm, and not less than 2.5 μm and not more than 3 μm. The depth of the second surface portion 9 is preferably not less than 1.5 μm and not more than 2.5 μm.

The first to fourth connecting surface portions 10A to 10D extend in the vertical direction Z and are connected to the first surface portion 8 and the second surface portion 9. The first connecting surface portion 10A is positioned at the first side surface 5A side, the second connecting surface portion 10B is positioned at the second side surface 5B side, the third connecting surface portion 10C is positioned at the third side surface 5C side, and the fourth connecting surface portion 10D is positioned at the fourth side surface 5D side. The first connecting surface portion 10A and the second connecting surface portion 10B extend in the first direction X and are opposed in the second direction Y. The third connecting surface portion 10C and the fourth connecting surface portion 10D extend in the second direction Y and are opposed in the first direction X.

The mesa 11 is thus demarcated in a projecting shape (a convex shape) in the first main surface 3. The mesa 11 is formed just in the second semiconductor region 7 and is not formed in the first semiconductor region 6. The first to fourth connecting surface portions 10A to 10D may extend substantially perpendicularly between the first surface portion 8 and the second surface portion 9 and demarcate the mesa 11 of a quadrilateral prism shape.

The first to fourth connecting surface portions 10A to 10D may be inclined obliquely downward from the first surface portion 8 toward the second surface portion 9 and demarcate the mesa 11 of a truncated quadrilateral prism shape. The first to fourth connecting surface portions 10A to 10D may be inclined at an angle exceeding 90° and being not more than 135° with respect to the first surface portion 8.

With reference to FIG. 4, the semiconductor device 1 includes, in the first main surface 3, an active region 12, a first side end region 13, a second side end region 14, a first terminal region 15, a second terminal region 16, a third terminal region 17, a fourth terminal region 18, and an outer peripheral region 19.

The active region 12 includes the device structure (the transistor structure Tr) and is a region in which an output current (a drain current) is generated. The active region 12 is set in an inner portion of the first surface portion 8. Specifically, the active region 12 is provided in the inner portion of the first surface portion 8 at intervals from the peripheral edges of the first surface portion 8 (from the first to fourth connecting surface portions 10A to 10D). In this embodiment, the active region 12 is provided in a polygonal shape (specifically, a quadrangle shape) having four sides parallel to the first to fourth side surfaces 5A to 5D in plan view.

A proportion at which the active region 12 occupies the first surface portion 8 is preferably not less than 50% and not more than 95%. The proportion of the active region 12 may have a value belonging to any one range among not less than 50% and not more than 60%, not less than 60% and not more than 70%, not less than 70% and not more than 80%, not less than 80% and not more than 90%, and not less than 90% and not more than 95%. The proportion of the active region 12 is preferably not less than 70%.

The first side end region 13 is provided, in the first surface portion 8, at one side (the third connecting surface portion 10C side) in the first direction X with respect to the active region 12 and faces the active region 12 in the first direction X. In this embodiment, the first side end region 13 extends in a band shape in the second direction Y in plan view.

The second side end region 14 is provided, in the first surface portion 8, at the other side (the fourth connecting surface portion 10D side) in the first direction X with respect to the active region 12 and faces the first side end region 13 in the first direction X with the active region 12 interposed therebetween. In this embodiment, the second side end region 14 extends in a band shape in the second direction Y in plan view.

The first terminal region 15 is provided at one side (the first connecting surface portion 10A side) in the second direction Y with respect to the active region 12 and faces the active region 12 in the second direction Y. In this embodiment, the first terminal region 15 extends in the first direction X and faces the first side end region 13 and the second side end region 14 in the second direction Y in plan view.

The second terminal region 16 is provided at the other side (the second connecting surface portion 10B side) in the second direction Y with respect to the active region 12 and faces the first terminal region 15 in the second direction Y with the active region 12 interposed therebetween. In this embodiment, the second terminal region 16 extends in the first direction X and faces the active region 12, the first side end region 13 and the second side end region 14 in the second direction Y in plan view.

The third terminal region 17 is provided at the one side (the first connecting surface portion 10A side) in the second direction Y with respect to the first terminal region 15 and faces the active region 12 in the second direction Y with the first terminal region 15 interposed therebetween. The third terminal region 17 is provided in a region between a peripheral edge of the first surface portion 8 and the first terminal region 15. In this embodiment, the third terminal region 17 extends in a band shape in the first direction X and faces the first side end region 13 and the second side end region 14 with the first terminal region 15 interposed therebetween in plan view.

The fourth terminal region 18 is provided at the other side (the second connecting surface portion 10B side) in the second direction Y with respect to the second terminal region 16 and faces the active region 12 in the second direction Y with the second terminal region 16 interposed therebetween. The fourth terminal region 18 is provided in a region between a peripheral edge of the first surface portion 8 and the second terminal region 16. In this embodiment, the fourth terminal region 18 extends in a band shape in the first direction X and faces the first side end region 13 and the second side end region 14 with the second terminal region 16 interposed therebetween in plan view.

The outer peripheral region 19 is provided as a non-active region in the second surface portion 9. In this embodiment, outer peripheral region 19 is provided in an annular shape (specifically, a quadrangle annular shape) surrounding the first surface portion 8 (the mesa 11) in plan view. That is, in plan view, the outer peripheral region 19 surrounds the active region 12, the first side end region 13, the second side end region 14, the first terminal region 15, the second terminal region 16, the third terminal region 17, and the fourth terminal region 18.

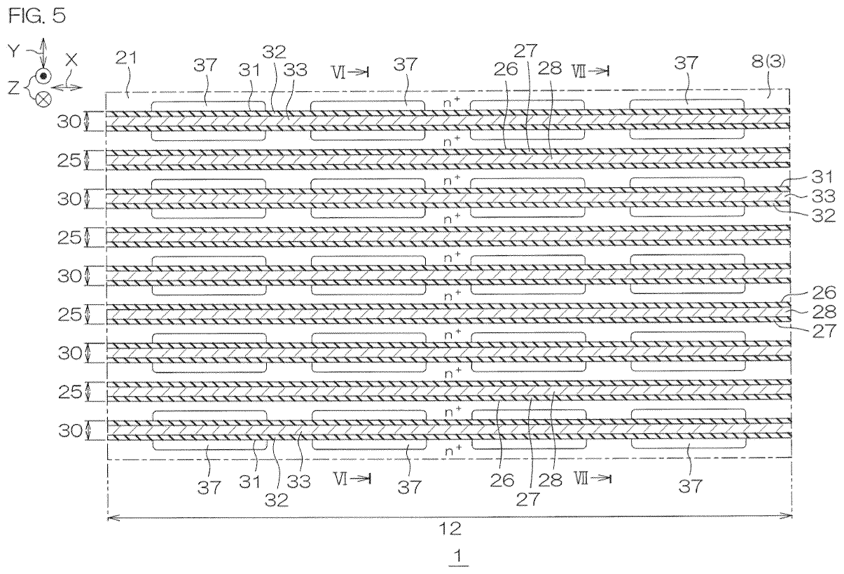

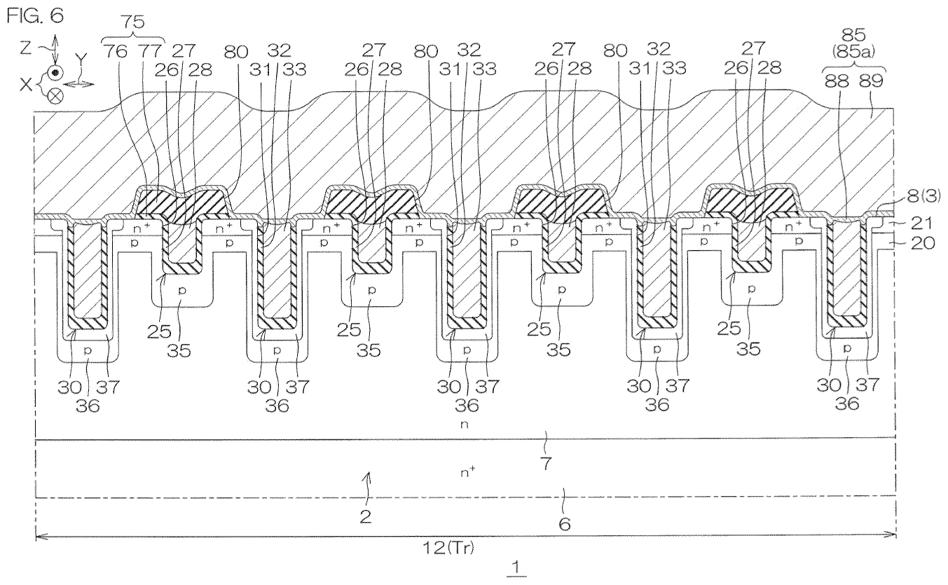

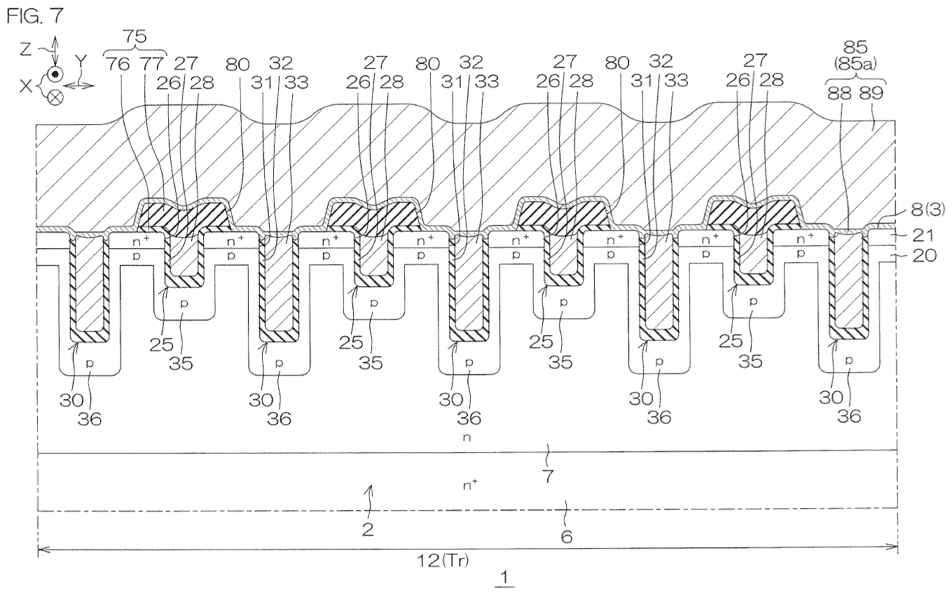

Hereinafter, the arrangement of the active region 12 shall be described. FIG. 5 is an enlarged plan view showing a principal portion of the active region 12. FIG. 6 is a sectional view taken along line VI-VI shown in FIG. 5. FIG. 7 is a sectional view taken along line VII-VII shown in FIG. 5.

With reference to FIG. 5 to FIG. 7, the semiconductor device 1 includes a body region 20 of the p-type that is formed in a surface layer portion of the first surface portion 8 (the first main surface 3) in the active region 12. The body region 20 may be referred to as a “channel region,” a “base region,” etc. A source potential is applied as a second potential (low potential) differing from the first potential (high potential) to the body region 20. The source potential may be a reference potential serving as a reference of circuit operation. The reference potential may be a ground potential or a potential other than the ground potential.

The body region 20 is formed at an interval to the first surface portion 8 side from a bottom portion of the second semiconductor region 7 and faces the first semiconductor region 6 with a portion of the second semiconductor region 7 interposed therebetween. The body region 20 is formed at an interval to the first surface portion 8 side from a depth position of the second surface portion 9.

The body region 20 is formed in a layered shape extending along the first surface portion 8. In this embodiment, the body region 20 is formed across an entirety of the first surface portion 8 and is exposed from the first to fourth connecting surface portions 10A to 10D. As a matter of course, the body region 20 may instead be formed at intervals inward from the peripheral edges of the first surface portion 8.

The semiconductor device 1 includes a source region 21 (an impurity region) of the n-type that is formed in a surface layer portion of the first surface portion 8 (the first main surface 3) in the active region 12. The source potential is applied to the source region 21. The source region 21 has an n-type impurity concentration higher than the impurity concentration of the second semiconductor region 7.

The source region 21 is formed in a surface layer portion of the body region 20. Specifically, the source region 21 is formed at an interval to the first surface portion 8 side from a bottom portion of the body region 20. That is, the source region 21 is formed in a region to the first surface portion 8 side with respect to the body region 20. The source region 21 forms, together with the second semiconductor region 7, channels of the transistor inside the body region 20.

In this embodiment, the source region 21 is formed at intervals inward from the peripheral edges of the first surface portion 8. Therefore, the source region 21 is not exposed from the first to fourth connecting surface portions 10A to 10D. In this embodiment, the source region 21 is formed just in the active region 12 and is not formed in a region other than the active region 12.

As a matter of course, the source region 21 may be formed in at least one region among the first side end region 13, the second side end region 14, the first terminal region 15, the second terminal region 16, the third terminal region 17, and the fourth terminal region 18 within a range of not influencing the electrical characteristics. As a matter of course, the source region 21 may be formed across an entire area of the first surface portion 8 and be exposed from the first to fourth connecting surface portions 10A to 10D.

The semiconductor device 1 includes a plurality of gate structures 25 of a trench type (a trench electrode type) that are formed in the first surface portion 8 (the first main surface 3) in the active region 12. The gate structures 25 may be referred to as “trench structures” or as “trench gate structures.” A gate potential is applied as a control potential to the plurality of gate structures 25. The plurality of gate structures 25 control inversion and non-inversion of the channels inside the body region 20 in response to the gate potential.

The plurality of gate structures 25 are arranged in the first surface portion 8 at intervals inward from the peripheral edges of the first surface portion 8 (from the first to fourth connecting surface portions 10A to 10D) and demarcate the active region 12 in the inner portion of the first surface portion 8. That is, the plurality of gate structures 25 are formed just in the active region 12 and are not formed in the first side end region 13, the second side end region 14, the first terminal region 15, the second terminal region 16, the third terminal region 17, and the fourth terminal region 18.

In plan view, the plurality of gate structures 25 each extend in a band shape in the first direction X and are aligned at intervals in the second direction Y. That is, in plan view, the plurality of gate structures 25 are aligned in a stripe shape extending in the first direction X.

The plurality of gate structures 25 penetrate through the body region 20 and the source region 21 so as to reach the second semiconductor region 7. That is, the body region 20 and the source region 21 are each positioned at both sides of the plurality of gate structures 25.

The plurality of gate structures 25 are formed at intervals to the first surface portion 8 side from the bottom portion of the second semiconductor region 7 and face the first semiconductor region 6 with portions of the second semiconductor region 7 interposed therebetween. In this embodiment, the plurality of gate structures 25 are formed substantially perpendicular to the first surface portion 8. As a matter of course, the plurality of gate structures 25 may each be formed in a shape tapering toward the bottom portion of the second semiconductor region 7 instead.

Side walls of the plurality of gate structures 25 are each formed by an m-plane (a (1-100) plane) of the SiC monocrystal. As a matter of course, the side walls of the plurality of gate structures 25 may each be formed instead by an a-plane (a (11-20) plane) of the SiC monocrystal in accordance with the extension direction of the gate structures 25. The side walls of the plurality of gate structures 25 are formed substantially perpendicular to the first main surface 3.

Bottom walls of the plurality of gate structures 25 are formed by a c-plane (an Si plane) of the SiC monocrystal. The bottom walls of the plurality of gate structures 25 preferably extend substantially flatly along the horizontal directions. As a matter of course, the bottom walls of the plurality of gate structures 25 may instead be curved in arcuate shapes toward the second main surface 4 side.

An inclination angle (absolute value) of each side wall of the gate structures 25 on a basis of a vertical line may be not less than 85° and not more than 95°. The inclination angle may have a value belonging to at least one range among not less than 85° and not more than 87.5°, not less than 87.5° and not more than 90°, not less than 90° and not more than 92.5°, and not less than 92.5° and not more than 95°. The inclination angle is preferably not less than 87° and not more than 93°. The gate structure 25 may have a width of not less than 0.1 μm and not more than 3 μm.

The width of the gate structure 25 may have a value belonging to at least one range among not less than 0.1 μm and not more than 0.5 μm, not less than 0.5 μm and not more than 1 μm, not less than 1 μm and not more than 1.5 μm, not less than 1.5 μm and not more than 2 μm, not less than 2 μm and not more than 2.5 μm, and not less than 2.5 μm and not more than 3 μm. The width of the gate structure 25 is preferably not less than 0.5 μm and not more than 2 μm.

The gate structure 25 preferably has a depth less than the depth of the second surface portion 9. As a matter of course, the depth of the gate structure 25 may be substantially equal to the depth of the second surface portion 9 or may be greater than the depth of the second surface portion 9.

The depth of the gate structure 25 may be not less than 0.1 μm and not more than 3 μm. The depth of the gate structure 25 may have a value belonging to at least one range among not less than 0.1 μm and not more than 0.5 μm, not less than 0.5 μm and not more than 1 μm, not less than 1 μm and not more than 1.5 μm, not less than 1.5 μm and not more than 2 μm, not less than 2 μm and not more than 2.5 μm, and not less than 2.5 μm and not more than 3 μm. The depth of the gate structure 25 is preferably not less than 0.5 μm and not more than 1.5 μm.

Hereinafter, the arrangement of the single gate structure 25 shall be described. The gate structure 25 includes a first trench 26, a first insulating film 27, and a first embedded electrode 28. The first trench 26 is formed in the first surface portion 8 and demarcates wall surfaces (the side walls and the bottom wall) of the gate structure 25.

The first insulating film 27 covers wall surfaces of the first trench 26. The first insulating film 27 may include at least one among a silicon oxide film, a silicon nitride film, and a silicon oxynitride film. In this embodiment, the first insulating film 27 has a single layer structure constituted of a silicon oxide film. The first insulating film 27 particularly preferably includes a silicon oxide film that is constituted of an oxide of the chip 2.

The first insulating film 27 includes a first film portion and a second film portion. The first film portion covers side walls of the first trench 26 in a film shape. The second film portion covers a bottom wall of the first trench 26 in a film shape and is continuous to the first film portion. The second film portion has a thickness greater than a thickness of the first film portion. The thickness of the second film portion may instead be substantially equal to the thickness of the first film portion.

The first insulating film 27 may have a thickness of not less than 10 nm and not more than 150 nm. The thickness of the first insulating film 27 may have a value belonging to at least one range among not less than 10 nm and not more than 25 nm, not less than 25 nm and not more than 50 nm, not less than 50 nm and not more than 75 nm, not less than 75 nm and not more than 100 nm, not less than 100 nm and not more than 125 nm, and not less than 125 nm and not more than 150 nm.

The first embedded electrode 28 is embedded in the first trench 26 with the first insulating film 27 interposed therebetween. The first embedded electrode 28 may contain either or both of a conductive polysilicon of the p-type and a conductive polysilicon of the n-type. The first embedded electrode 28 faces a channel with the first insulating film 27 interposed therebetween. That is, the first embedded electrode 28 faces the second semiconductor region 7, the body region 20, and the source region 21 with the first insulating film 27 interposed therebetween.

The first embedded electrode 28 has an electrode surface exposed from the first trench 26. The electrode surface of the first embedded electrode 28 is positioned at the bottom wall side of the first trench 26 with respect to the height position of the first surface portion 8. The electrode surface of the first embedded electrode 28 is positioned at the first main surface 3 side with respect to a depth position of the bottom portion of the body region 20. The electrode surface of the first embedded electrode 28 has, in an inner portion, a recess that is recessed in a shape tapering toward the bottom wall side of the first trench 26.

The semiconductor device 1 includes a plurality of first source structures 30 of a trench type (a trench electrode type) that are formed in the first main surface 3 (the first surface portion 8) in the active region 12. The first source structures 30 may be referred to as “trench structures,” “trench source structures,” “first trench source structures,” etc. The source potential is applied to the plurality of first source structures 30.

The plurality of first source structures 30 are formed in the first surface portion 8 so as to be mutually adjacent to the plurality of gate structures 25 in the second direction Y in the active region 12. Specifically, the plurality of first source structures 30 are respectively arranged in regions between the plurality of gate structures 25 and face the plurality of gate structures 25 in the second direction Y. That is, the plurality of first source structures 30 are aligned alternately with the plurality of gate structures 25 in the second direction Y.

The plurality of first source structures 30 each extend in a band shape in the first direction X in plan view. In this embodiment, the plurality of first source structures 30 are led out from the active region 12 to either or both (in this embodiment, both) of the first side end region 13 and the second side end region 14. The plurality of first source structures 30 face the gate structures 25 in the second direction Y in the active region 12 but do not face the gate structures 25 in the second direction Y in the first side end region 13 (the second side end region 14).

The plurality of first source structures 30 are exposed from at least one of the third connecting surface portion 10C and the fourth connecting surface portion 10D. In this embodiment, the plurality of first source structures 30 penetrate through both the third connecting surface portion 10C and the fourth connecting surface portion 10D and are exposed from both the third connecting surface portion 10C and the fourth connecting surface portion 10D.

The plurality of first source structures 30 penetrate through the body region 20 and the source region 21 so as to reach the second semiconductor region 7. That is, the body region 20 and the source region 21 are each positioned at both sides of the plurality of first source structures 30.

The plurality of first source structures 30 are formed at intervals to the first surface portion 8 side from the bottom portion of the second semiconductor region 7 and face the first semiconductor region 6 with portions of the second semiconductor region 7 interposed therebetween. In this embodiment, the plurality of first source structures 30 are formed substantially perpendicular to the first surface portion 8. As a matter of course, the plurality of first source structures 30 may each be formed in a shape tapering toward the bottom portion of the second semiconductor region 7 instead.

Side walls of the plurality of first source structures 30 are each formed by an m-plane of the SiC monocrystal. As a matter of course, the side walls of the plurality of first source structures 30 may each be formed instead by an a-plane of the SiC monocrystal in accordance with the extension direction of the first source structures 30. The side walls of the plurality of first source structures 30 are formed substantially perpendicular to the first main surface 3.

Bottom walls of the plurality of first source structures 30 are formed by a c-plane (an Si plane) of the SiC monocrystal. The bottom walls of the plurality of first source structures 30 preferably extend substantially flatly along the horizontal directions. As a matter of course, the bottom walls of the plurality of first source structures 30 may instead be curved in arcuate shapes toward the second main surface 4 side.

An inclination angle (absolute value) of each side wall of the first source structures 30 on a basis of a vertical line may be not less than 85° and not more than 95°. The inclination angle may have a value belonging to at least one range among not less than 85° and not more than 87.5°, not less than 87.5° and not more than 90°, not less than 90° and not more than 92.5°, and not less than 92.5° and not more than 95°. The inclination angle is preferably not less than 87° and not more than 93°.

The first source structure 30 preferably has a width greater than the width of the gate structure 25. As a matter of course, the width of the first source structure 30 may be substantially equal to the width of the gate structure 25 or may be less than the width of the gate structure 25.

The width of the first source structure 30 may be not less than 0.1 μm and not more than 3 μm. The width of the first source structure 30 may have a value belonging to at least one range among not less than 0.1 μm and not more than 0.5 μm, not less than 0.5 μm and not more than 1 μm, not less than 1 μm and not more than 1.5 μm, not less than 1.5 μm and not more than 2 μm, not less than 2 μm and not more than 2.5 μm, and not less than 2.5 μm and not more than 3 μm. The width of the first source structure 30 is preferably not less than 0.5 μm and not more than 2 μm.

The first source structure 30 preferably has a depth greater than the depth of the gate structure 25. As a matter of course, the depth of the first source structure 30 may be substantially equal to the depth of the gate structure 25 or may be less than the depth of the gate structure 25. The depth of the first source structure 30 is preferably substantially equal to the depth of the second surface portion 9. As a matter of course, the depth of the first source structure 30 may be less than the depth of the second surface portion 9 or may be greater than the depth of the second surface portion 9.

A ratio (a depth ratio) of the depth of the first source structure 30 with respect to the depth of the gate structure 25 is preferably not less than 1 and not more than 3. The depth ratio may have a value belonging to at least one range among not less than 1 and not more than 1.25, not less than 1.25 and not more than 1.5, not less than 1.5 and not more than 1.75, not less than 1.75 and not more than 2, not less than 2 and not more than 2.25, not less than 2.25 and not more than 2.5, not less than 2.5 and not more than 2.75, and not less than 2.75 and not more than 3. The depth ratio is preferably not less than 1.5 and not more than 2.5.

The depth of the first source structure 30 may be not less than 0.1 μm and not more than 3 μm. The depth of the first source structure 30 may have a value belonging to at least one range among not less than 0.1 μm and not more than 0.5 μm, not less than 0.5 μm and not more than 1 μm, not less than 1 μm and not more than 1.5 μm, not less than 1.5 μm and not more than 2 μm, not less than 2 μm and not more than 2.5 μm, and not less than 2.5 μm and not more than 3 μm. The depth of the first source structure 30 is preferably not less than 1.5 μm and not more than 2.5 μm.

Hereinafter, the arrangement of the single first source structure 30 shall be described. The first source structure 30 includes a second trench 31, a second insulating film 32, and a second embedded electrode 33. The second trench 31 is formed in the first surface portion 8 and demarcates wall surfaces (the side walls and the bottom wall) of the first source structure 30. Side walls of the second trench 31 are connected to either or both (in this embodiment, both) of the third connecting surface portion 10C and the fourth connecting surface portion 10D. A bottom wall of the second trench 31 is connected to the second surface portion 9.

The second insulating film 32 covers wall surfaces of the second trench 31. The second insulating film 32 may include at least one among a silicon oxide film, a silicon nitride film, and a silicon oxynitride film. The second insulating film 32 preferably includes the same type of insulating material as the insulating material of the first insulating film 27. In this embodiment, the second insulating film 32 has a single layer structure constituted of a silicon oxide film. The second insulating film 32 particularly preferably includes a silicon oxide film that is constituted of the oxide of the chip 2.

The second insulating film 32 includes a first film portion and a second film portion. The first film portion covers the side walls of the second trench 31 in a film shape. The second film portion covers the bottom wall of the second trench 31 in a film shape and is continuous to the first film portion.

The second film portion has a thickness greater than a thickness of the first film portion. The thickness of the second film portion may instead be substantially equal to the thickness of the first film portion. The thickness of the first film portion of the second insulating film 32 may be substantially equal to the thickness of the first film portion of the first insulating film 27. The thickness of the second film portion of the second insulating film 32 may be substantially equal to the thickness of the second film portion of the first insulating film 27.

The second insulating film 32 may have a thickness of not less than 10 nm and not more than 150 nm. The thickness of the second insulating film 32 may have a value belonging to at least one range among not less than 10 nm and not more than 25 nm, not less than 25 nm and not more than 50 nm, not less than 50 nm and not more than 75 nm, not less than 75 nm and not more than 100 nm, not less than 100 nm and not more than 125 nm, and not less than 125 nm and not more than 150 nm.

The second embedded electrode 33 is embedded in the second trench 31 with the second insulating film 32 interposed therebetween. The second embedded electrode 33 may contain either or both of a conductive polysilicon of the p-type and a conductive polysilicon of the n-type. The second embedded electrode 33 preferably contains the same type of conductive material as the conductive material of the first embedded electrode 28. The second embedded electrode 33 faces the second semiconductor region 7, the body region 20, and the source region 21 with the second insulating film 32 interposed therebetween.

The second embedded electrode 33 has an electrode surface exposed from the second trench 31. The electrode surface of the second embedded electrode 33 is positioned at the bottom wall side of the second trench 31 with respect to the height position of the first surface portion 8. The electrode surface of the second embedded electrode 33 is positioned at the first main surface 3 side with respect to the depth position of the bottom portion of the body region 20. The electrode surface of the second embedded electrode 33 has, in an inner portion, a recess that is recessed in a shape tapering toward the bottom wall side of the second trench 31.

The semiconductor device 1 includes a plurality of first well regions 35 of the p-type that are formed in regions along the plurality of gate structures 25 in a surface layer portion of the first surface portion 8 (the first main surface 3) of the active region 12. The first well regions 35 have a p-type impurity concentration higher than a p-type impurity concentration of the body region 20. As a matter of course, the p-type impurity concentration of the first well regions 35 may be less than the p-type impurity concentration of the body region 20.

The plurality of first well regions 35 are respectively formed in a one-to-one correspondence with respect to the plurality of gate structures 25. The plurality of first well regions 35 are respectively formed in the regions along the corresponding gate structures 25 at intervals from the plurality of first source structures 30.

The plurality of first well regions 35 are formed along the side walls and the bottom walls of the corresponding gate structures 25 and are each electrically connected to the body region 20 in the surface layer portion of the first surface portion 8. The plurality of first well regions 35 are formed at intervals to the first surface portion 8 side from the bottom portion of the second semiconductor region 7 and face the first semiconductor region 6 with portions of the second semiconductor region 7 interposed therebetween. The plurality of first well regions 35 form pn junction portions with the second semiconductor region 7.

The semiconductor device 1 includes a plurality of second well regions 36 of the p-type that are formed in regions along the plurality of first source structures 30 in a surface layer portion of the first surface portion 8 (the first main surface 3) of the active region 12. The second well regions 36 have a p-type impurity concentration higher than the p-type impurity concentration of the body region 20. As a matter of course, the p-type impurity concentration of the second well regions 36 may be less than the p-type impurity concentration of the body region 20. The p-type impurity concentration of the second well regions 36 is preferably substantially equal to the p-type impurity concentration of the first well regions 35.

The plurality of second well regions 36 are respectively formed in a one-to-one correspondence with respect to the plurality of first source structures 30. The plurality of second well regions 36 are respectively formed in the regions along the corresponding first source structures 30 at intervals from the plurality of gate structures 25.

The plurality of second well regions 36 are formed along the side walls and the bottom walls of the corresponding first source structures 30 and are each electrically connected to the body region 20 in the surface layer portion of the first surface portion 8. The plurality of second well regions 36 extend along the wall surfaces of the corresponding first source structures 30 in the active region 12, the first side end region 13, and the second side end region 14 and are exposed from the third connecting surface portion 10C and the fourth connecting surface portion 10D. The plurality of second well regions 36 are formed at intervals to the first surface portion 8 side from the bottom portion of the second semiconductor region 7 and face the first semiconductor region 6 with portions of the second semiconductor region 7 interposed therebetween. Bottom portions of the plurality of second well regions 36 are positioned to the bottom portion side of the second semiconductor region 7 with respect to depth positions of bottom portions of the plurality of first well regions 35. The plurality of second well regions 36 form pn junction portions with the second semiconductor region 7.

The semiconductor device 1 includes a plurality of contact regions 37 of the p-type that are formed in regions along the plurality of first source structures 30 in a surface layer portion of the first surface portion 8 (the first main surface 3) of the active region 12. The contact regions 37 may be referred to as “back gate regions.” The contact regions 37 have a p-type impurity concentration higher than the p-type impurity concentration of the body region 20. The p-type impurity concentration of the contact regions 37 is higher than the p-type impurity concentration of the first well regions 35 (the second well regions 36).

The plurality of contact regions 37 are formed inside the plurality of second well regions 36. The plurality of contact regions 37 extend along the wall surfaces of the corresponding first source structures 30 inside the corresponding second well regions 36. The plurality of contact regions 37 are formed in a multiple-to-one correspondence with respect to the corresponding single first source structure 30.

The plurality of contact regions 37 are formed at intervals in the first direction X along the corresponding first source structure 30. The plurality of contact regions 37 are led out to a surface layer portion of the body region 20 along the wall surfaces of the corresponding first source structure 30 inside the corresponding second well region 36 and are exposed from the first surface portion 8.

In this embodiment, the plurality of contact regions 37 each extend in a band shape in the first direction X in plan view. A length in the first direction X of each of the plurality of contact regions 37 is preferably not less than the width in the second direction Y of the first source structure 30. The length of each of the plurality of contact regions 37 is preferably greater than a distance between two of the contact regions 37 that are mutually adjacent in the first direction X.

The plurality of contact regions 37 along the single first source structure 30 face, in the second direction Y, the plurality of contact regions 37 along another first source structure 30. That is, in this embodiment, the plurality of contact regions 37 are arrayed, as a whole, in a matrix at intervals in the first direction X and the second direction Y in plan view.

The plurality of contact regions 37 along the single first source structure 30 may be aligned shifted in the first direction X so as to face, in the second direction Y, regions between the plurality of contact regions 37 along another first source structure 30. That is, the plurality of contact regions 37 may be arrayed, as a whole, in a staggered arrangement at intervals in the first direction X and the second direction Y in plan view.

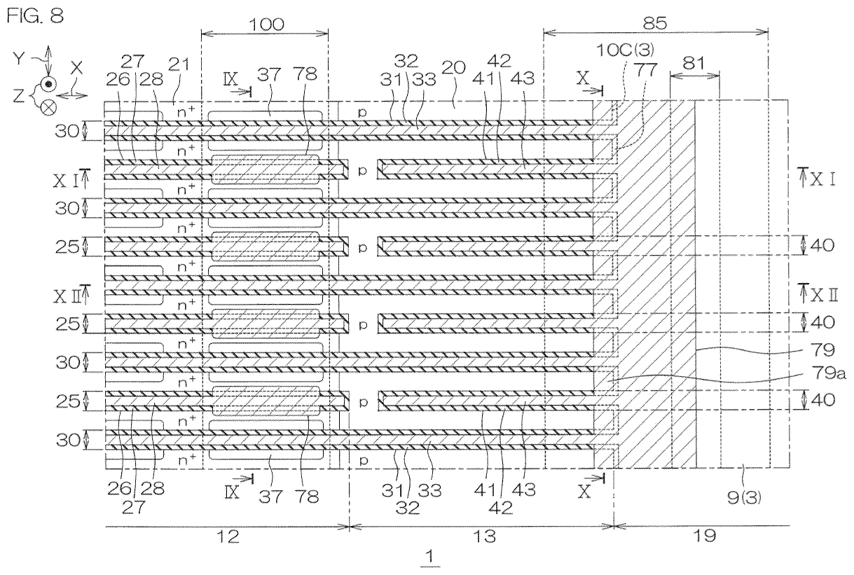

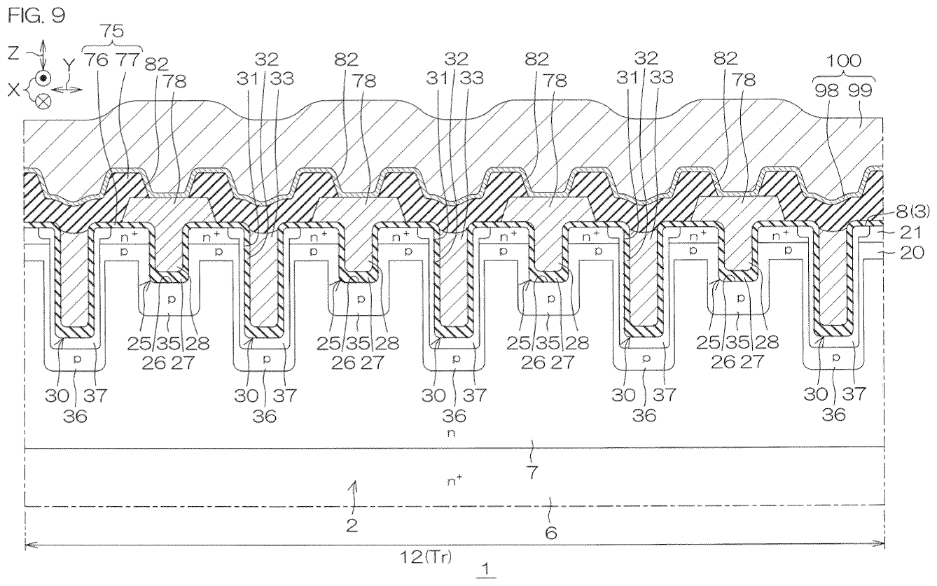

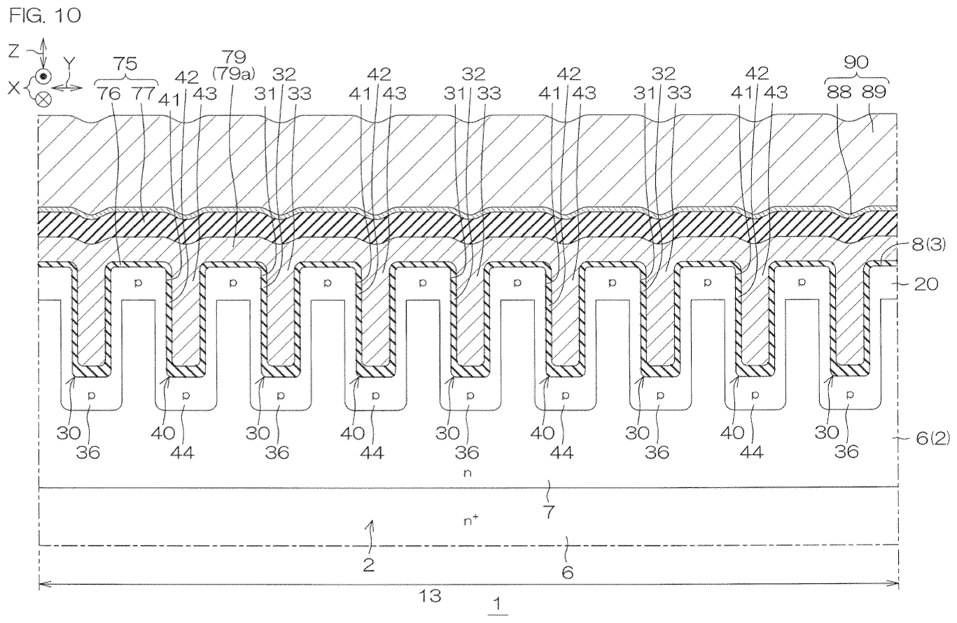

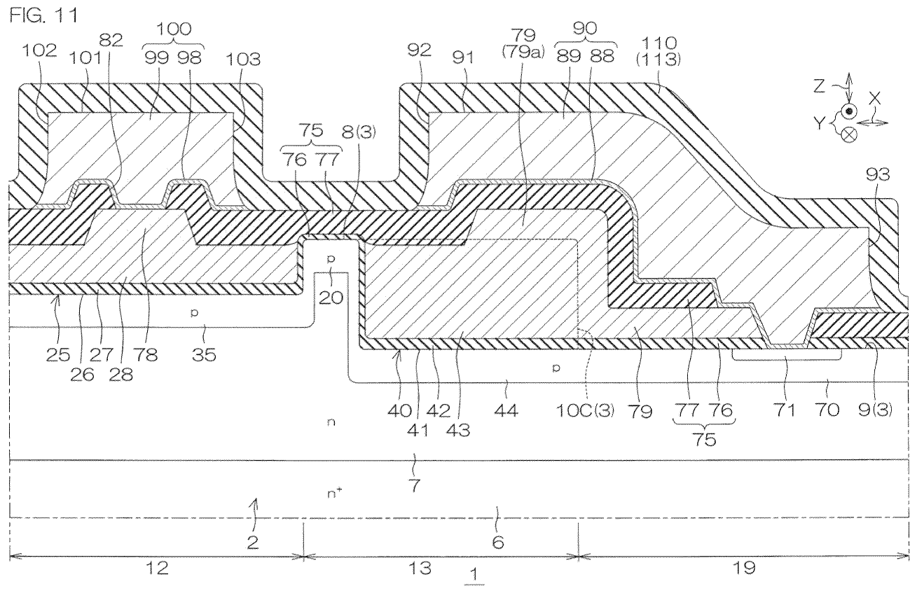

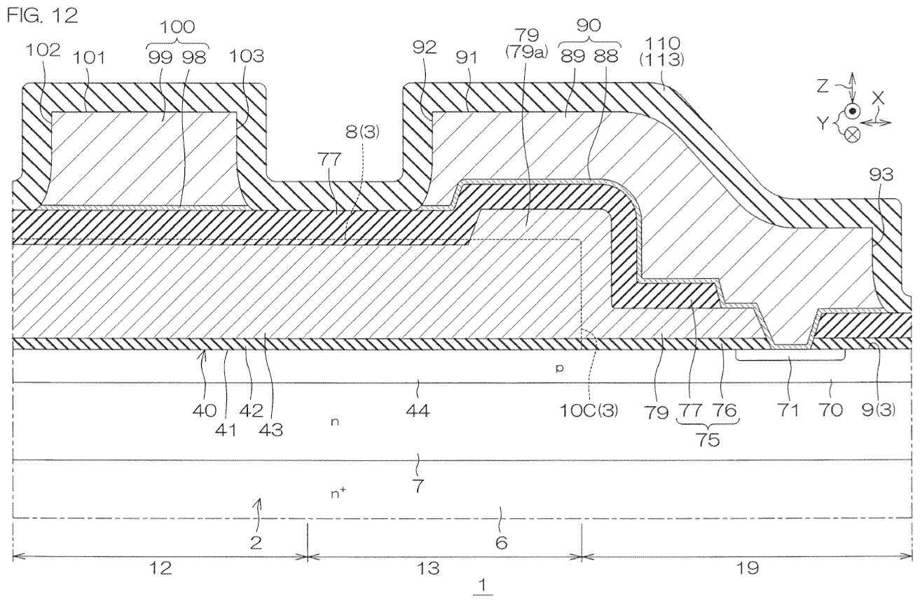

Hereinafter, the arrangement of the first side end region 13 shall be described. FIG. 8 is an enlarged plan view showing a principal portion of the first side end region 13. FIG. 9 is a sectional view taken along line IX-IX shown in FIG. 8. FIG. 10 is a sectional view taken along line X-X shown in FIG. 8. FIG. 11 is a sectional view taken along line XI-XI shown in FIG. 8. FIG. 12 is a sectional view taken along line XII-XII shown in FIG. 8.

A layout of the second side end region 14 is the same as a layout of the first side end region 13 and therefore, a description of the layout of the second side end region 14 shall be omitted. The layout of the second side end region 14 is obtained by replacing “first side end region 13” with “second side end region 14” and replacing “third connecting surface portion 10C” with “fourth connecting surface portion 10D” in the description of the first side end region 13.

With reference to FIG. 8 to FIG. 12, the semiconductor device 1 includes a plurality of second source structures 40 of a trench type (a trench electrode type) that are formed in the first surface portion 8 (the first main surface 3) in the first side end region 13. The source potential is applied to the plurality of second source structures 40. The second source structures 40 may be referred to as “trench structures,” “source side end structures,” “trench source structures,” “second trench source structures,” etc.

The plurality of second source structures 40 are respectively arranged in regions between a peripheral edge of the first surface portion 8 (the third connecting surface portion 10C) and the plurality of gate structures 25. The plurality of second source structures 40 are respectively arranged in regions between the plurality of first source structures 30 and face the plurality of first source structures 30 in the second direction Y. That is, the plurality of second source structures 40 are aligned alternately with the plurality of first source structures 30 in the second direction Y.

The plurality of second source structures 40 face the plurality of gate structures 25 in a one-to-one correspondence in the first direction X and, together with the plurality of gate structures 25, demarcate a plurality of side end mesa portions. The plurality of side end mesa portions are aligned in a single row in the second direction Y. As a matter of course, the plurality of side end mesa portions may be aligned shifted in one direction and the other direction of the first direction X with respect to each other such as not proximally face other side end mesa portions in the second direction Y.

The plurality of second source structures 40 each extend in a band shape in the first direction X in plan view. In this embodiment, the plurality of second source structures 40 penetrate through the third connecting surface portion 10C and are exposed from the third connecting surface portion 10C. The plurality of second source structures 40 penetrate through the body region 20 so as to reach the second semiconductor region 7. The plurality of second source structures 40 are formed at intervals to the first surface portion 8 side from the bottom portion of the second semiconductor region 7 and face the first semiconductor region 6 with portions of the second semiconductor region 7 interposed therebetween.

In this embodiment, the plurality of second source structures 40 are formed substantially perpendicular to the first surface portion 8. As a matter of course, the plurality of second source structures 40 may each be formed in a shape tapering toward the bottom portion of the second semiconductor region 7 instead.

Side walls of the plurality of second source structures 40 are each formed by an m-plane of the SiC monocrystal. As a matter of course, the side walls of the plurality of second source structures 40 may each be formed instead by an a-plane of the SiC monocrystal in accordance with the extension direction of the second source structures 40. The side walls of the plurality of second source structures 40 are formed substantially perpendicular to the first main surface 3.

Bottom walls of the plurality of second source structures 40 are formed by a c-plane (an Si plane) of the SiC monocrystal. The bottom walls of the plurality of second source structures 40 preferably extend substantially flatly along the horizontal directions. As a matter of course, the bottom walls of the plurality of second source structures 40 may instead be curved in arcuate shapes toward the second main surface 4 side.

An inclination angle (absolute value) of each side wall of the second source structures 40 on a basis of a vertical line may be not less than 85° and not more than 95°. The inclination angle may have a value belonging to at least one range among not less than 85° and not more than 87.5°, not less than 87.5° and not more than 90°, not less than 90° and not more than 92.5°, and not less than 92.5° and not more than 95°. The inclination angle is preferably not less than 87° and not more than 93°.

The second source structure 40 preferably has a width greater than the width of the gate structure 25. As a matter of course, the width of the second source structure 40 may be substantially equal to the width of the gate structure 25 or may be less than the width of the gate structure 25. The width of the second source structure 40 is preferably substantially equal to the width of the first source structure 30.

The width of the second source structure 40 may be not less than 0.1 μm and not more than 3 μm. The width of the second source structure 40 may have a value belonging to at least one range among not less than 0.1 μm and not more than 0.5 μm, not less than 0.5 μm and not more than 1 μm, not less than 1 μm and not more than 1.5 μm, not less than 1.5 μm and not more than 2 μm, not less than 2 μm and not more than 2.5 μm, and not less than 2.5 μm and not more than 3 μm. The width of the second source structure 40 is preferably not less than 0.5 μm and not more than 2 μm.

The second source structure 40 preferably has a depth greater than the depth of the gate structure 25. As a matter of course, the depth of the second source structure 40 may be substantially equal to the depth of the gate structure 25 or may be less than the depth of the gate structure 25.

The depth of the second source structure 40 is preferably substantially equal to the depth of the second surface portion 9. As a matter of course, the depth of the second source structure 40 may be less than the depth of the second surface portion 9 or may be greater than that of the second surface portion 9. The depth of each of the plurality of second source structures 40 is preferably substantially equal to the depth of each of the plurality of first source structures 30.

A ratio (a depth ratio) of the depth of the second source structure 40 with respect to the depth of the gate structure 25 is preferably not less than 1 and not more than 3. The depth ratio may have a value belonging to at least one range among not less than 1 and not more than 1.25, not less than 1.25 and not more than 1.5, not less than 1.5 and not more than 1.75, not less than 1.75 and not more than 2, not less than 2 and not more than 2.25, not less than 2.25 and not more than 2.5, not less than 2.5 and not more than 2.75, and not less than 2.75 and not more than 3. The depth ratio is preferably not less than 1.5 and not more than 2.5.

The depth of the second source structure 40 may be not less than 0.1 μm and not more than 3 μm. The depth of the second source structure 40 may have a value belonging to at least one range among not less than 0.1 μm and not more than 0.5 μm, not less than 0.5 μm and not more than 1 μm, not less than 1 μm and not more than 1.5 μm, not less than 1.5 μm and not more than 2 μm, not less than 2 μm and not more than 2.5 μm, and not less than 2.5 μm and not more than 3 μm. The depth of the second source structure 40 is preferably not less than 1.5 μm and not more than 2.5 μm.

The plurality of second source structures 40 are arranged at first intervals in the first direction X from the plurality of gate structures 25. Each first interval is preferably not less than 0.5 times and not more than 2 times the width of the second source structure 40.

The plurality of second source structures 40 are arranged at second intervals in the second direction Y from the plurality of first source structures 30. Each second interval may be substantially equal to each first interval. The second interval may be greater than the first interval or may be less than the first interval. The second interval is preferably not less than 0.5 times and not more than 2 times the width of the second source structure 40.

The first interval (the second interval) may be not less than 0.1 μm and not more than 3 μm. The first interval (the second interval) may have a value belonging to at least one range among not less than 0.1 μm and not more than 0.5 μm, not less than 0.5 μm and not more than 1 μm, not less than 1 μm and not more than 1.5 μm, not less than 1.5 μm and not more than 2 μm, not less than 2 μm and not more than 2.5 μm, and not less than 2.5 μm and not more than 3 μm. The first interval (the second interval) is preferably not less than 0.5 μm and not more than 2 μm.

Hereinafter, the arrangement of the single second source structure 40 shall be described. The second source structure 40 includes a third trench 41, a third insulating film 42, and a third embedded electrode 43. The third trench 41 is formed in the first surface portion 8 and demarcates wall surfaces (the side walls and the bottom wall) of the second source structure 40. Side walls of the third trench 41 are connected to the third connecting surface portion 10C. A bottom wall of the third trench 41 is connected to the second surface portion 9.

The third insulating film 42 covers wall surfaces of the third trench 41. The third insulating film 42 may include at least one among a silicon oxide film, a silicon nitride film, and a silicon oxynitride film. The third insulating film 42 preferably includes the same type of insulating material as the insulating material of the first insulating film 27 (the second insulating film 32). In this embodiment, the third insulating film 42 has a single layer structure constituted of a silicon oxide film. The third insulating film 42 particularly preferably includes a silicon oxide film that is constituted of the oxide of the chip 2.

The third insulating film 42 includes a first film portion and a second film portion. The first film portion covers the side walls of the third trench 41 in a film shape. The second film portion covers the bottom wall of the third trench 41 in a film shape and is continuous to the first film portion. The second film portion has a thickness greater than a thickness of the first film portion. The thickness of the second film portion may instead be substantially equal to the thickness of the first film portion. The thickness of the first film portion of the third insulating film 42 may be substantially equal to the thickness of the first film portion of the first insulating film 27. The thickness of the second film portion of the third insulating film 42 may be substantially equal to the thickness of the second film portion of the first insulating film 27.

The third insulating film 42 may have a thickness of not less than 10 nm and not more than 150 nm. The thickness of the third insulating film 42 may have a value belonging to at least one range among not less than 10 nm and not more than 25 nm, not less than 25 nm and not more than 50 nm, not less than 50 nm and not more than 75 nm, not less than 75 nm and not more than 100 nm, not less than 100 nm and not more than 125 nm, and not less than 125 nm and not more than 150 nm.

The third embedded electrode 43 is embedded in the third trench 41 with the third insulating film 42 interposed therebetween. The third embedded electrode 43 may contain either or both of a conductive polysilicon of the p-type and a conductive polysilicon of the n-type. The third embedded electrode 43 preferably contains the same type of conductive material as the conductive material of the first embedded electrode 28 (the second embedded electrode 33). The third embedded electrode 43 faces the second semiconductor region 7 and the body region 20 with the third insulating film 42 interposed therebetween.

The third embedded electrode 43 has an electrode surface exposed from the third trench 41. The electrode surface of the third embedded electrode 43 is positioned at the bottom wall side of the third trench 41 with respect to the height position of the first surface portion 8. The electrode surface of the third embedded electrode 43 is positioned at the first main surface 3 side with respect to the depth position of the bottom portion of the body region 20. The electrode surface of the third embedded electrode 43 has, in an inner portion, a recess that is recessed in a shape tapering toward the bottom wall side of the third trench 41.

The semiconductor device 1 includes a plurality of third well regions 44 of the p-type that are formed in regions along the plurality of second source structures 40 in a surface layer portion of the first surface portion 8 (the first main surface 3) of the first side end region 13. The third well regions 44 have a p-type impurity concentration higher than the p-type impurity concentration of the body region 20. As a matter of course, the p-type impurity concentration of the third well regions 44 may be less than the p-type impurity concentration of the body region 20. The p-type impurity concentration of the third well regions 44 is preferably substantially equal to the p-type impurity concentration of the first well regions 35 (the second well regions 36).

The plurality of third well regions 44 are respectively formed in a one-to-one correspondence with respect to the plurality of second source structures 40. The plurality of third well regions 44 are respectively formed in the regions along the corresponding second source structures 40 at intervals from the plurality of first well regions 35 and the plurality of second well regions 36. As a matter of course, the plurality of third well regions 44 may be formed integral to the plurality of first well regions 35. The plurality of third well regions 44 may be formed integral to the plurality of second well regions 36.

The plurality of third well regions 44 are formed along the side walls and the bottom walls of the corresponding second source structures 40 and are each electrically connected to the body region 20 in the surface layer portion of the first surface portion 8. The plurality of third well regions 44 are exposed from the third connecting surface portion 10C.

The plurality of third well regions 44 are formed at intervals to the first surface portion 8 side from the bottom portion of the second semiconductor region 7 and face the first semiconductor region 6 with portions of the second semiconductor region 7 interposed therebetween. Bottom portions of the plurality of third well regions 44 are positioned at the bottom portion side of the second semiconductor region 7 with respect to depth positions of bottom portions of the plurality of first well regions 35. The bottom portions of the plurality of third well regions 44 are formed at depth positions substantially equal to bottom portions of the plurality of second well regions 36. The plurality of third well regions 44 form pn junction portions with the second semiconductor region 7.

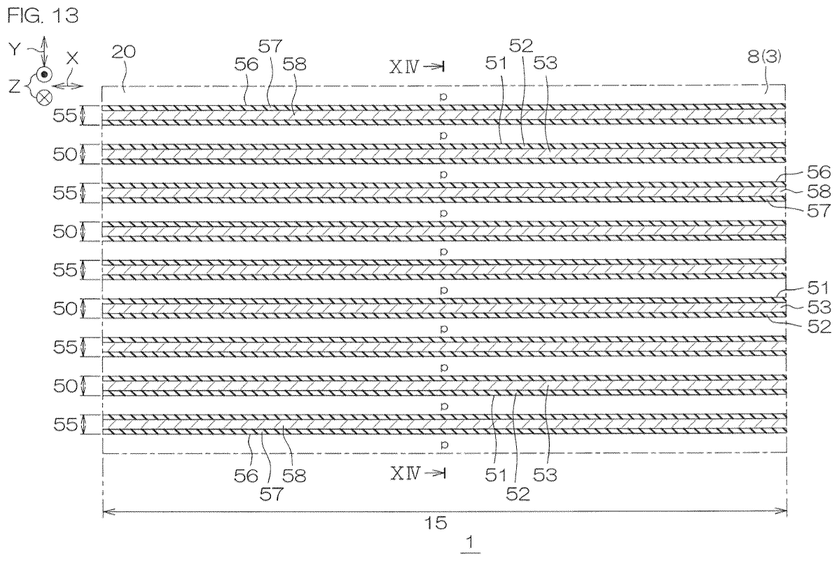

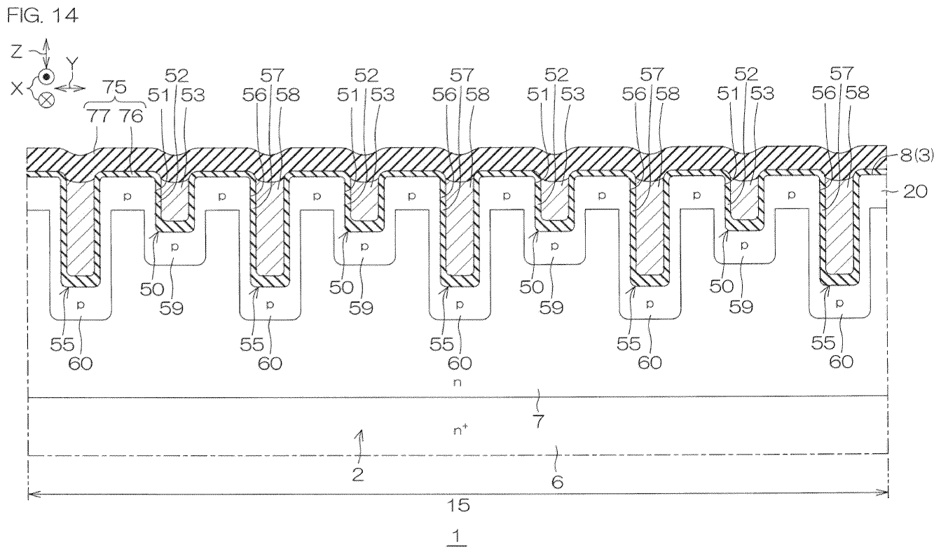

Hereinafter, the arrangement of the first terminal region 15 shall be described. FIG. 13 is an enlarged plan view showing a principal portion of the first terminal region 15. FIG. 14 is a sectional view taken along line XIV-XIV shown in FIG. 13.

A layout of the second terminal region 16 is the same as a layout of the first terminal region 15 and therefore, a description of the layout of the second terminal region 16 shall be omitted. The layout of the second terminal region 16 is obtained by replacing “first terminal region 15” with “second terminal region 16” and replacing “first connecting surface portion 10A” with “second connecting surface portion 10B” in the description of the first terminal region 15.

The semiconductor device 1 includes a plurality of dummy gate structures 50 of a trench type (a trench electrode type) that are formed in the first surface portion 8 (the first main surface 3) in the first terminal region 15. The dummy gate structures 50 may be referred to as “trench structures,” “trench terminal structures,” “gate terminal structures,” “dummy trench structures,” or as “dummy trench gate structures.” The source potential is applied to the plurality of dummy gate structures 50. That is, the plurality of dummy gate structures 50 do not contribute to the inversion and non-inversion of the channels.

The plurality of dummy gate structures 50 are formed in a region at the first connecting surface portion 10A side with respect to the active region 12. In plan view, the plurality of dummy gate structures 50 each extend in a band shape in the first direction X and are aligned at intervals in the second direction Y. That is, in plan view, the plurality of dummy gate structures 50 are aligned in a stripe shape extending in the first direction X. The plurality of dummy gate structures 50 face the plurality of gate structures 25 and the plurality of first source structures 30 in the second direction Y.

In this embodiment, the plurality of dummy gate structures 50 are led out to regions facing either or both (in this embodiment, both) of the first side end region 13 and the second side end region 14 in the second direction Y and face the plurality of second source structures 40 in the second direction Y.

The plurality of dummy gate structures 50 are exposed from at least one of the third connecting surface portion 10C and the fourth connecting surface portion 10D. In this embodiment, the plurality of dummy gate structures 50 penetrate through both the third connecting surface portion 10C and the fourth connecting surface portion 10D and are exposed from both the third connecting surface portion 10C and the fourth connecting surface portion 10D.

The plurality of dummy gate structures 50 penetrate through the body region 20 so as to reach the second semiconductor region 7. The plurality of dummy gate structures 50 are formed at intervals to the first surface portion 8 side from the bottom portion of the second semiconductor region 7 and face the first semiconductor region 6 with portions of the second semiconductor region 7 interposed therebetween. In this embodiment, the plurality of dummy gate structures 50 are formed substantially perpendicular to the first surface portion 8. As a matter of course, the plurality of dummy gate structures 50 may each be formed in a shape tapering toward the bottom portion of the second semiconductor region 7 instead.

Side walls of the plurality of dummy gate structures 50 are each formed by an m-plane of the SiC monocrystal. As a matter of course, the side walls of the plurality of dummy gate structures 50 may each be formed instead by an a-plane of the SiC monocrystal in accordance with the extension direction of the dummy gate structures 50. The side walls of the plurality of dummy gate structures 50 are formed substantially perpendicular to the first main surface 3. Bottom walls of the plurality of dummy gate structures 50 are formed by a c-plane (an Si plane) of the SiC monocrystal. The bottom walls of the plurality of dummy gate structures 50 preferably extend substantially flatly along the horizontal directions. As a matter of course, the bottom walls of the plurality of dummy gate structures 50 may instead be curved in arcuate shapes toward the second main surface 4 side.

An inclination angle (absolute value) of each side wall of the dummy gate structures 50 on a basis of a vertical line may be not less than 85° and not more than 95°. The inclination angle may have a value belonging to at least one range among not less than 85° and not more than 87.5°, not less than 87.5° and not more than 90°, not less than 90° and not more than 92.5°, and not less than 92.5° and not more than 95°. The inclination angle is preferably not less than 87° and not more than 93°.

The dummy gate structure 50 preferably has a width substantially equal to the width of the gate structure 25. As a matter of course, the width of the dummy gate structure 50 may be greater than the width of the gate structure 25 or may be less than the width of the gate structure 25. The width of the dummy gate structure 50 is preferably less than the width of the first source structure 30 (the second source structure 40). As a matter of course, the dummy gate structure 50 may be substantially equal in width to the first source structure 30 (the second source structure 40) or may be greater in width than the first source structure 30 (the second source structure 40).

The width of the dummy gate structure 50 may be not less than 0.1 μm and not more than 3 μm. The width of the dummy gate structure 50 may have a value belonging to at least one range among not less than 0.1 μm and not more than 0.5 μm, not less than 0.5 μm and not more than 1 μm, not less than 1 μm and not more than 1.5 μm, not less than 1.5 μm and not more than 2 μm, not less than 2 μm and not more than 2.5 μm, and not less than 2.5 μm and not more than 3 μm. The width of the dummy gate structure 50 is preferably not less than 0.5 μm and not more than 2 μm.

The dummy gate structure 50 preferably has a depth less than the depth of the second surface portion 9. As a matter of course, the depth of the dummy gate structure 50 may be substantially equal to the depth of the second surface portion 9 or may be greater than the depth of the second surface portion 9. The dummy gate structure 50 preferably has a depth substantially equal to the depth of the gate structure 25. As a matter of course, the depth of the dummy gate structure 50 may be greater than the depth of the gate structure 25 or may be less than the depth of the gate structure 25.

The depth of the dummy gate structure 50 is preferably less than the depth of the first source structure 30 (the second of source structure 40). As a matter of course, the depth of the dummy gate structure 50 may be substantially equal to the depth of the first source structure 30 (the second source structure 40) or may be greater than the depth of the first source structure 30 (the second source structure 40).

The depth of the dummy gate structure 50 may be not less than 0.1 μm and not more than 3 μm. The depth of the dummy gate structure 50 may have a value belonging to at least one range among not less than 0.1 μm and not more than 0.5 μm, not less than 0.5 μm and not more than 1 μm, not less than 1 μm and not more than 1.5 μm, not less than 1.5 μm and not more than 2 μm, not less than 2 μm and not more than 2.5 μm, and not less than 2.5 μm and not more than 3 μm. The depth of the dummy gate structure 50 is preferably not less than 1.5 μm and not more than 2.5 μm.

Hereinafter, the arrangement of the single dummy gate structure 50 shall be described. The dummy gate structure 50 includes a fourth trench 51, a fourth insulating film 52, and a fourth embedded electrode 53. The fourth trench 51 is formed in the first surface portion 8 and demarcates wall surfaces (the side walls and the bottom wall) of the dummy gate structure 50.

The fourth insulating film 52 covers wall surfaces of the fourth trench 51. The fourth insulating film 52 may include at least one among a silicon oxide film, a silicon nitride film, and a silicon oxynitride film. The fourth insulating film 52 preferably includes the same type of insulating material as the insulating material of the first insulating film 27 (the second insulating film 32). In this embodiment, the fourth insulating film 52 has a single layer structure constituted of a silicon oxide film. The fourth insulating film 52 particularly preferably includes a silicon oxide film that is constituted of the oxide of the chip 2.

The fourth insulating film 52 includes a first film portion and a second film portion. The first film portion covers side walls of the fourth trench 51 in a film shape. The second film portion covers a bottom wall of the fourth trench 51 in a film shape and is continuous to the first film portion. The second film portion has a thickness greater than a thickness of the first film portion. The thickness of the second film portion may instead be substantially equal to the thickness of the first film portion. The thickness of the first film portion of the fourth insulating film 52 may be substantially equal to the thickness of the first film portion of the first insulating film 27. The thickness of the second film portion of the fourth insulating film 52 may be substantially equal to the thickness of the second film portion of the first insulating film 27.

The fourth insulating film 52 may have a thickness of not less than 10 nm and not more than 150 nm. The thickness of the fourth insulating film 52 may have a value belonging to at least one range among not less than 10 nm and not more than 25 nm, not less than 25 nm and not more than 50 nm, not less than 50 nm and not more than 75 nm, not less than 75 nm and not more than 100 nm, not less than 100 nm and not more than 125 nm, and not less than 125 nm and not more than 150 nm.

The fourth embedded electrode 53 is embedded in the fourth trench 51 with the fourth insulating film 52 interposed therebetween. The fourth embedded electrode 53 may contain either or both of a conductive polysilicon of the p-type and a conductive polysilicon of the n-type. The fourth embedded electrode 53 preferably contains the same type of conductive material as the conductive material of the first embedded electrode 28 (the second embedded electrode 33). The fourth embedded electrode 53 faces the second semiconductor region 7 and the body region 20 with the fourth insulating film 52 interposed therebetween.

The fourth embedded electrode 53 has an electrode surface exposed from the fourth trench 51. The electrode surface of the fourth embedded electrode 53 is positioned at the bottom wall side of the fourth trench 51 with respect to the height position of the first surface portion 8. The electrode surface of the fourth embedded electrode 53 is positioned at the first main surface 3 side with respect to the depth position of the bottom portion of the body region 20. The electrode surface of the fourth embedded electrode 53 has, in an inner portion, a recess that is recessed in a shape tapering toward the bottom wall side of the fourth trench 51.

The semiconductor device 1 includes a plurality of third source structures 55 of a trench type (a trench electrode type) that are formed in the first surface portion 8 (the first main surface 3) in the first terminal region 15. The source potential is applied to the plurality of third source structures 55. The third source structures 55 may be referred to as “trench structures,” “source terminal structures,” “trench source structures,” “third trench source structures,” etc.

The plurality of third source structures 55 are formed in a region to the first connecting surface portion 10A side with respect to the active region 12. The plurality of third source structures 55 are formed in the first surface portion 8 so as to be mutually adjacent to the plurality of dummy gate structures 50 in the second direction Y in the first terminal region 15. Specifically, the plurality of third source structures 55 are respectively arranged in regions between the plurality of dummy gate structures 50 and face the plurality of dummy gate structures 50 in the second direction Y.

That is, the plurality of third source structures 55 are aligned alternately with the plurality of dummy gate structures 50 in the second direction Y. The plurality of third source structures 55 each extend in a band shape in the first direction X in plan view. The plurality of third source structures 55 face the plurality of gate structures 25 and the plurality of first source structures 30 in the second direction Y.

In this embodiment, the plurality of third source structures 55 are led out to regions facing either or both (in this embodiment, both) of the first side end region 13 and the second side end region 14 in the second direction Y and face the plurality of second source structures 40 in the second direction Y. In this embodiment, the plurality of third source structures 55 face the plurality of second source structures 40 in the second direction Y with the plurality of dummy gate structures 50 interposed therebetween.

The plurality of third source structures 55 are exposed from at least one of the third connecting surface portion 10C and the fourth connecting surface portion 10D. In this embodiment, the plurality of third source structures 55 penetrate through both the third connecting surface portion 10C and the fourth connecting surface portion 10D and are exposed from both the third connecting surface portion 10C and the fourth connecting surface portion 10D.

The plurality of third source structures 55 penetrate through the body region 20 so as to reach the second semiconductor region 7. The plurality of third source structures 55 are formed at intervals to the first surface portion 8 side from the bottom portion of the second semiconductor region 7 and face the first semiconductor region 6 with portions of the second semiconductor region 7 interposed therebetween. In this embodiment, the plurality of third source structures 55 are formed substantially perpendicular to the first surface portion 8. As a matter of course, the plurality of third source structures 55 may each be formed in a shape tapering toward the bottom portion of the second semiconductor region 7 instead.

Side walls of the plurality of third source structures 55 are each formed by an m-plane of the SiC monocrystal. As a matter of course, the side walls of the plurality of third source structures 55 may each be formed instead by an a-plane of the SiC monocrystal in accordance with the extension direction of the third source structures 55. The side walls of the plurality of third source structures 55 are formed substantially perpendicular to the first main surface 3.

Bottom walls of the plurality of third source structures 55 are formed by a c-plane (an Si plane) of the SiC monocrystal. The bottom walls of the plurality of third source structures 55 preferably extend substantially flatly along the horizontal directions. As a matter of course, the bottom walls of the plurality of third source structures 55 may instead be curved in arcuate shapes toward the second main surface 4 side.

An inclination angle (absolute value) of each side wall of the third source structures 55 on a basis of a vertical line may be not less than 85° and not more than 95°. The inclination angle may have a value belonging to at least one range among not less than 85° and not more than 87.5°, not less than 87.5° and not more than 90°, not less than 90° and not more than 92.5°, and not less than 92.5° and not more than 95°. The inclination angle is preferably not less than 87° and not more than 93°.

The third source structure 55 preferably has a width greater than the width of the dummy gate structure 50. As a matter of course, the width of the third source structure 55 may be substantially equal to the width of the dummy gate structure 50 or may be less than the width of the dummy gate structure 50. The width of the third source structure 55 is preferably substantially equal to the width of the first source structure 30 (the second source structure 40). As a matter of course, the width of the third source structure 55 may be greater than the width of the first source structure 30 (the second source structure 40) or may be less than the width of the first source structure 30 (the second source structure 40).

The width of the third source structure 55 may be not less than 0.1 μm and not more than 3 μm. The width of the third source structure 55 may have a value belonging to at least one range among not less than 0.1 μm and not more than 0.5 μm, not less than 0.5 μm and not more than 1 μm, not less than 1 μm and not more than 1.5 μm, not less than 1.5 μm and not more than 2 μm, not less than 2 μm and not more than 2.5 μm, and not less than 2.5 μm and not more than 3 μm. The width of the third source structure 55 is preferably not less than 0.5 μm and not more than 2 μm.

The third source structure 55 preferably has a depth greater than the depth of the dummy gate structure 50 (the gate structure 25). As a matter of course, the depth of the third source structure 55 may be substantially equal to the depth of the dummy gate structure 50 (gate structure 25) or may be less than the depth of the dummy gate structure 50 (gate structure 25).

The depth of the third source structure 55 is preferably substantially equal to depth of the first source structure 30 (the second source structure 40). As a matter of course, the depth of the third source structure 55 may be less than the depth of the first source structure 30 (the second source structure 40) or may be greater than the depth of the first source structure 30 (the second source structure 40). The depth of the third source structure 55 is preferably substantially equal to the depth of the second surface portion 9. As a matter of course, the depth of the third source structure 55 may be less than the depth of the second surface portion 9 or may be greater than the depth of the second surface portion 9.

A ratio (a depth ratio) of the depth of the third source structure 55 with respect to the depth of the gate structure 25 (the dummy gate structure 50) is preferably not less than 1 and not more than 3. The depth ratio may have a value belonging to at least one range among not less than 1 and not more than 1.25, not less than 1.25 and not more than 1.5, not less than 1.5 and not more than 1.75, not less than 1.75 and not more than 2, not less than 2 and not more than 2.25, not less than 2.25 and not more than 2.5, not less than 2.5 and not more than 2.75, and not less than 2.75 and not more than 3. The depth ratio is preferably not less than 1.5 and not more than 2.5.

The depth of the third source structure 55 may be not less than 0.1 μm and not more than 3 μm. The depth of the third source structure 55 may have a value belonging to at least one range among not less than 0.1 μm and not more than 0.5 μm, not less than 0.5 μm and not more than 1 μm, not less than 1 μm and not more than 1.5 μm, not less than 1.5 μm and not more than 2 μm, not less than 2 μm and not more than 2.5 μm, and not less than 2.5 μm and not more than 3 μm. The depth of the third source structure 55 is preferably not less than 1.5 μm and not more than 2.5 μm.

Hereinafter, the arrangement of the single third source structure 55 shall be described. The third source structure 55 includes a fifth trench 56, a fifth insulating film 57, and a fifth embedded electrode 58. The fifth trench 56 is formed in the first surface portion 8 and demarcates wall surfaces (the side walls and the bottom wall) of the third source structure 55. Side walls of the fifth trench 56 are connected to either or both (in this embodiment, both) of the third connecting surface portion 10C and the fourth connecting surface portion 10D. A bottom wall of the fifth trench 56 is connected to the second surface portion 9.

The fifth insulating film 57 covers wall surfaces of the fifth trench 56. The fifth insulating film 57 may include at least one among a silicon oxide film, a silicon nitride film, and a silicon oxynitride film. The fifth insulating film 57 preferably includes the same type of insulating material as the insulating material of the first insulating film 27 (the second insulating film 32). In this embodiment, the fifth insulating film 57 has a single layer structure constituted of a silicon oxide film. The fifth insulating film 57 particularly preferably includes a silicon oxide film that is constituted of the oxide of the chip 2.

The fifth insulating film 57 includes a first film portion and a second film portion. The first film portion covers the side walls of the fifth trench 56 in a film shape. The second film portion covers the bottom wall of the fifth trench 56 in a film shape and is continuous to the first film portion. The second film portion has a thickness greater than a thickness of the first film portion. The thickness of the second film portion may instead be substantially equal to the thickness of the first film portion. The thickness of the first film portion of the fifth insulating film 57 may be substantially equal to the thickness of the first film portion of the first insulating film 27. The thickness of the second film portion of the fifth insulating film 57 may be substantially equal to the thickness of the second film portion of the first insulating film 27.

The fifth insulating film 57 may have a thickness of not less than 10 nm and not more than 150 nm. The thickness of the fifth insulating film 57 may have a value belonging to at least one range among not less than 10 nm and not more than 25 nm, not less than 25 nm and not more than 50 nm, not less than 50 nm and not more than 75 nm, not less than 75 nm and not more than 100 nm, not less than 100 nm and not more than 125 nm, and not less than 125 nm and not more than 150 nm.

The fifth embedded electrode 58 is embedded in the fifth trench 56 with the fifth insulating film 57 interposed therebetween. The fifth embedded electrode 58 may contain either or both of a conductive polysilicon of the p-type and a conductive polysilicon of the n-type. The fifth embedded electrode 58 preferably contains the same type of conductive material as the conductive material of the first embedded electrode 28 (the second embedded electrode 33). The fifth embedded electrode 58 faces the second semiconductor region 7 and the body region 20 with the fifth insulating film 57 interposed therebetween.

The fifth embedded electrode 58 has an electrode surface exposed from the fifth trench 56. The electrode surface of the fifth embedded electrode 58 is positioned at the bottom wall side of the fifth trench 56 with respect to the height position of the first surface portion 8. The electrode surface of the fifth embedded electrode 58 is positioned at the first main surface 3 side with respect to the depth position of the bottom portion of the body region 20. The electrode surface of the fifth embedded electrode 58 has, in an inner portion, a recess that is recessed in a shape tapering toward the bottom wall side of the fifth trench 56.

The semiconductor device 1 includes a plurality of fourth well regions 59 of the p-type that are formed in regions along the plurality of dummy gate structures 50 in a surface layer portion of the first surface portion 8 (the first main surface 3) of the first terminal region 15. The fourth well regions 59 have a p-type impurity concentration higher than the p-type impurity concentration of the body region 20. As a matter of course, the p-type impurity concentration of the fourth well regions 59 may be less than the p-type impurity concentration of the body region 20. The p-type impurity concentration of the fourth well regions 59 is preferably substantially equal to the p-type impurity concentration of the first well regions 35 (the second well regions 36).

The plurality of fourth well regions 59 are respectively formed in a one-to-one correspondence with respect to the plurality of dummy gate structures 50. The plurality of fourth well regions 59 are respectively formed in the regions along the corresponding dummy gate structures 50 at intervals from the plurality of third source structures 55. The plurality of fourth well regions 59 are formed along the side walls and the bottom walls of the corresponding dummy gate structures 50 and are each electrically connected to the body region 20 in the surface layer portion of the first surface portion 8.

The plurality of fourth well regions 59 are formed at intervals to the first surface portion 8 side from the bottom portion of the second semiconductor region 7 and face the first semiconductor region 6 with portions of the second semiconductor region 7 interposed therebetween. Bottom portions of the plurality of fourth well regions 59 are positioned to the first surface portion 8 side with respect to the depth positions of the bottom portions of the plurality of second well regions 36. In this embodiment, the plurality of fourth well regions 59 are exposed from either or both (in this embodiment, both) of the third connecting surface portion 10C and the fourth connecting surface portion 10D. The plurality of fourth well regions 59 form pn junction portions with the second semiconductor region 7.

The semiconductor device 1 includes a plurality of fifth well regions 60 of the p-type that are formed in regions along the plurality of third source structures 55 in a surface layer portion of the first surface portion 8 (the first main surface 3) of the first terminal region 15. The fifth well regions 60 have a p-type impurity concentration higher than the p-type impurity concentration of the body region 20. As a matter of course, the p-type impurity concentration of the fifth well regions 60 may be less than the p-type impurity concentration of the body region 20. The p-type impurity concentration of the fifth well regions 60 is preferably substantially equal to the p-type impurity concentration of the first well regions 35 (the second well regions 36).

The plurality of fifth well regions 60 are respectively formed in a one-to-one correspondence with respect to the plurality of third source structures 55. The plurality of fifth well regions 60 are respectively formed in the regions along the corresponding third source structures 55 at intervals from the plurality of dummy gate structures 50. The plurality of fifth well regions 60 are formed along the side walls and the bottom walls of the corresponding third source structures 55 and are each electrically connected to the body region 20 in the surface layer portion of the first surface portion 8.

The plurality of fifth well regions 60 are formed at intervals to the first surface portion 8 side from the bottom portion of the second semiconductor region 7 and face the first semiconductor region 6 with portions of the second semiconductor region 7 interposed therebetween. Bottom portions of the plurality of fifth well regions 60 are positioned to the bottom portion side of the second semiconductor region 7 with respect to the depth positions of the bottom portions of the plurality of fourth well regions 59.

The bottom portions of the plurality of fifth well regions 60 are formed at depth positions substantially equal to the bottom portions of the plurality of second well regions 36. In this embodiment, the plurality of fifth well regions 60 are exposed from either or both (in this embodiment, both) of the third connecting surface portion 10C and the fourth connecting surface portion 10D. The plurality of fifth well regions 60 form pn junction portions with the second semiconductor region 7.

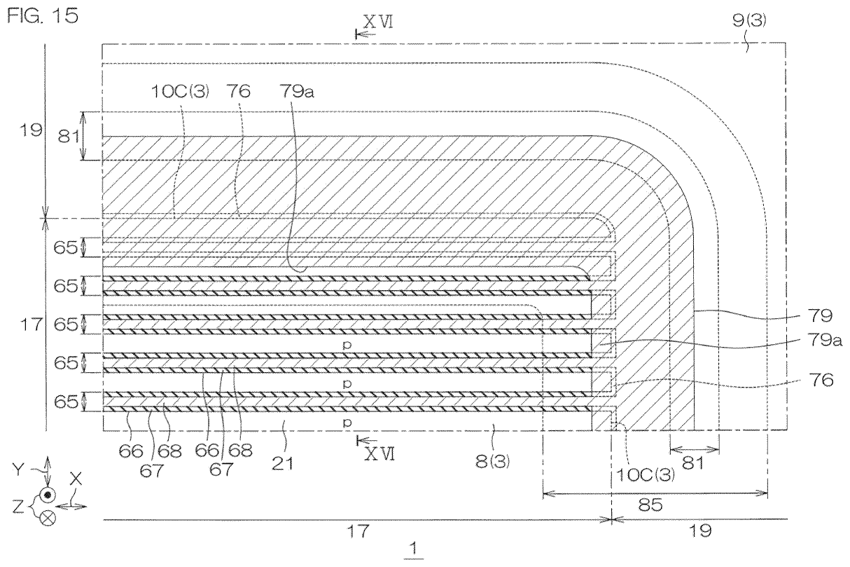

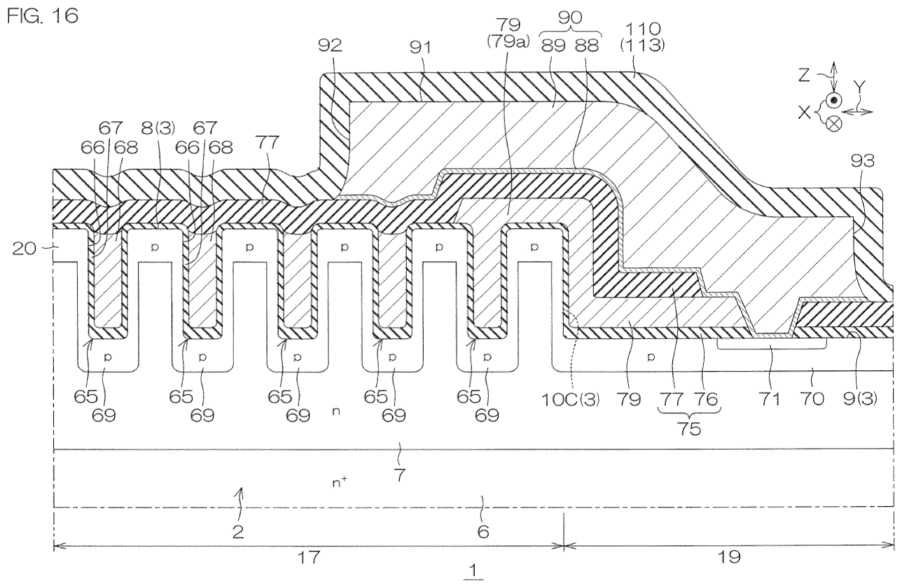

Hereinafter, the arrangement of the third terminal region 17 shall be described. FIG. 15 is an enlarged plan view showing a principal portion of the third terminal region 17. FIG. 16 is a sectional view taken along line XVI-XVI shown in FIG. 15.

A layout of the fourth terminal region 18 is the same as a layout of the third terminal region 17 and therefore, a description of the layout of the fourth terminal region 18 shall be omitted. The layout of the fourth terminal region 18 is obtained by replacing “third terminal region 17” with “fourth terminal region 18,” replacing “first terminal region 15” with “second terminal region 16,” and replacing “first connecting surface portion 10A” with “second connecting surface portion 10B” in the description of the third terminal region 17.

The semiconductor device 1 includes a plurality of fourth source structures 65 of a trench type (a trench electrode type) that are formed in the first surface portion 8 (the first main surface 3) in the third terminal region 17. The source potential is applied to the plurality of fourth source structures 65. The fourth source structures 65 may be referred to as “trench structures,” “source terminal structures,” “trench source structures,” “fourth trench source structures,” etc.

The plurality of fourth source structures 65 are formed in a region to the first connecting surface portion 10A side with respect to the active region 12 (the first terminal region 15). In plan view, the plurality of fourth source structures 65 each extend in a band shape in the first direction X and are aligned at intervals in the second direction Y. That is, in plan view, the plurality of fourth source structures 65 are aligned in a stripe shape extending in the first direction X. The plurality of fourth source structures 65 are adjacent to each other without any other trench structure interposed therebetween.

The plurality of fourth source structures 65 face the active region 12 (the plurality of gate structures 25 and the plurality of first source structures 30) in the second direction Y with the first terminal region 15 (the plurality of dummy gate structures 50 and the plurality of third source structures 55) interposed therebetween.

In this embodiment, the plurality of fourth source structures 65 are led out to regions facing either or both (in this embodiment, both) of the first side end region 13 and the second side end region 14 in the second direction Y and face the plurality of second source structures 40 in the second direction Y. In this embodiment, the plurality of fourth source structures 65 face the plurality of second source structures 40 with the first terminal region 15 (the plurality of dummy gate structures 50 and the plurality of third source structures 55) interposed therebetween.

The plurality of fourth source structures 65 are exposed from at least one of the third connecting surface portion 10C and the fourth connecting surface portion 10D. In this embodiment, the plurality of fourth source structures 65 penetrate through both the third connecting surface portion 10C and the fourth connecting surface portion 10D and are exposed from both the third connecting surface portion 10C and the fourth connecting surface portion 10D.

The plurality of fourth source structures 65 penetrate through the body region 20 so as to reach the second semiconductor region 7. The plurality of fourth source structures 65 are formed at intervals to the first surface portion 8 side from the bottom portion of the second semiconductor region 7 and face the first semiconductor region 6 with portions of the second semiconductor region 7 interposed therebetween. In this embodiment, the plurality of fourth source structures 65 are formed substantially perpendicular to the first surface portion 8. As a matter of course, the plurality of fourth source structures 65 may each be formed in a shape tapering toward the bottom portion of the second semiconductor region 7 instead.

Side walls of the plurality of fourth source structures 65 are each formed by an m-plane of the SiC monocrystal. As a matter of course, the side walls of the plurality of fourth source structures 65 may each be formed instead by an a-plane of the SiC monocrystal in accordance with the extension direction of the fourth source structures 65. The side walls of the plurality of fourth source structures 65 are formed substantially perpendicular to the first main surface 3.

Bottom walls of the plurality of fourth source structures 65 are formed by a c-plane (an Si plane) of the SiC monocrystal. The bottom walls of the plurality of fourth source structures 65 preferably extend substantially flatly along the horizontal directions. As a matter of course, the bottom walls of the plurality of fourth source structures 65 may instead be curved in arcuate shapes toward the second main surface 4 side.

An inclination angle (absolute value) of each side wall of the fourth source structures 65 on a basis of a vertical line may be not less than 85° and not more than 95°. The inclination angle may have a value belonging to at least one range among not less than 85° and not more than 87.5°, not less than 87.5° and not more than 90°, not less than 90° and not more than 92.5°, and not less than 92.5° and not more than 95°. The inclination angle is preferably not less than 87° and not more than 93°.

The fourth source structure 65 preferably has a width greater than the width of the gate structure 25. As a matter of course, the width of the fourth source structure 65 may be substantially equal to the width of the gate structure 25 or may be less than the width of the gate structure 25. The width of the fourth source structure 65 is preferably substantially equal to the width of the first source structure 30 (the second source structure 40). As a matter of course, the width of the fourth source structure 65 may be greater than the width of the first source structure 30 (the second source structure 40) or may be less than the width of the first source structure 30 (the second source structure 40).

The width of the fourth source structure 65 may be not less than 0.1 μm and not more than 3 μm. The width of the fourth source structure 65 may have a value belonging to at least one range among not less than 0.1 μm and not more than 0.5 μm, not less than 0.5 μm and not more than 1 μm, not less than 1 μm and not more than 1.5 μm, not less than 1.5 μm and not more than 2 μm, not less than 2 μm and not more than 2.5 μm, and not less than 2.5 μm and not more than 3 μm. The width of the fourth source structure 65 is preferably not less than 0.5 μm and not more than 2 μm.

The fourth source structure 65 preferably has a depth greater than the depth of the gate structure 25. As a matter of course, the depth of the fourth source structure 65 may be substantially equal to the depth of the gate structure 25 or may be less than the depth of the gate structure 25.

The depth of the fourth source structure 65 is preferably substantially equal to depth of the first source structure 30 (the second of source structure 40). As a matter of course, the depth of the fourth source structure 65 may be less than the depth of the first source structure 30 (the second source structure 40) or may be greater than the depth of the first source structure 30 (the second source structure 40). The depth of the fourth source structure 65 is preferably substantially equal to the depth of the second surface portion 9. As a matter of course, the depth of the fourth source structure 65 may be less than the depth of the second surface portion 9 or may be greater than the depth of the second surface portion 9.

A ratio (a depth ratio) of the depth of the fourth source structure 65 with respect to the depth of the gate structure 25 (dummy gate structure 50) is preferably not less than 1 and not more than 3. The depth ratio may have a value belonging to at least one range among not less than 1 and not more than 1.25, not less than 1.25 and not more than 1.5, not less than 1.5 and not more than 1.75, not less than 1.75 and not more than 2, not less than 2 and not more than 2.25, not less than 2.25 and not more than 2.5, not less than 2.5 and not more than 2.75, and not less than 2.75 and not more than 3. The depth ratio is preferably not less than 1.5 and not more than 2.5.

The depth of the fourth source structure 65 may be not less than 0.1 μm and not more than 3 μm. The depth of the fourth source structure 65 may have a value belonging to at least one range among not less than 0.1 μm and not more than 0.5 μm, not less than 0.5 μm and not more than 1 μm, not less than 1 μm and not more than 1.5 μm, not less than 1.5 μm and not more than 2 μm, not less than 2 μm and not more than 2.5 μm, and not less than 2.5 μm and not more than 3 μm. The depth of the fourth source structure 65 is preferably not less than 1.5 μm and not more than 2.5 μm.

A ratio (an interval ratio) of each interval between the plurality of fourth source structures 65 and each interval between the gate structures 25 and the first source structures 30 is preferably not less than 0.5 and not more than 2. The interval ratio may have a value belonging to at least one range among not less than 0.5 and not more than 0.75, not less than 0.75 and not more than 1, not less than 1 and not more than 1.25, not less than 1.25 and not more than 1.5, not less than 1.5 and not more than 1.75, and not less than 1.75 and not more than 2. The interval ratio is preferably not less than 0.75 and not more than 1.25.

Hereinafter, the arrangement of the single fourth source structure 65 shall be described. The fourth source structure 65 includes a sixth trench 66, a sixth insulating film 67, and a sixth embedded electrode 68. The sixth trench 66 is formed in the first surface portion 8 and demarcates wall surfaces (the side walls and the bottom wall) of the fourth source structure 65. Side walls of the sixth trench 66 are connected to either or both (in this embodiment, both) of the third connecting surface portion 10C and the fourth connecting surface portion 10D. A bottom wall of the sixth trench 66 is connected to the second surface portion 9.

The sixth insulating film 67 covers wall surfaces of the sixth trench 66. The sixth insulating film 67 may include at least one among a silicon oxide film, a silicon nitride film, and a silicon oxynitride film. The sixth insulating film 67 preferably includes the same type of insulating material as the insulating material of the first insulating film 27 (the second insulating film 32). In this embodiment, the sixth insulating film 67 has a single layer structure constituted of a silicon oxide film. The sixth insulating film 67 particularly preferably includes a silicon oxide film that is constituted of the oxide of the chip 2.

The sixth insulating film 67 includes a first film portion and a second film portion. The first film portion covers the side walls of the sixth trench 66 in a film shape. The second film portion covers the bottom wall of the sixth trench 66 in a film shape and is continuous to the first film portion. The second film portion has a thickness greater than a thickness of the first film portion. The thickness of the second film portion may instead be substantially equal to the thickness of the first film portion. The thickness of the first film portion of the sixth insulating film 67 may be substantially equal to the thickness of the first film portion of the first insulating film 27. The thickness of the second film portion of the sixth insulating film 67 may be substantially equal to the thickness of the second film portion of the first insulating film 27.

The sixth insulating film 67 may have a thickness of not less than 10 nm and not more than 150 nm. The thickness of the sixth insulating film 67 may have a value belonging to at least one range among not less than 10 nm and not more than 25 nm, not less than 25 nm and not more than 50 nm, not less than 50 nm and not more than 75 nm, not less than 75 nm and not more than 100 nm, not less than 100 nm and not more than 125 nm, and not less than 125 nm and not more than 150 nm.

The sixth embedded electrode 68 is embedded in the sixth trench 66 with the sixth insulating film 67 interposed therebetween. The sixth embedded electrode 68 may contain either or both of a conductive polysilicon of the p-type and a conductive polysilicon of the n-type. The sixth embedded electrode 68 preferably contains the same type of conductive material as the conductive material of the first embedded electrode 28 (the second embedded electrode 33). The sixth embedded electrode 68 faces the second semiconductor region 7 and the body region 20 with the sixth insulating film 67 interposed therebetween.

The sixth embedded electrode 68 has an electrode surface exposed from the sixth trench 66. The electrode surface of the sixth embedded electrode 68 is positioned at the bottom wall side of the sixth trench 66 with respect to the height position of the first surface portion 8. The electrode surface of the sixth embedded electrode 68 is positioned at the first main surface 3 side with respect to the depth position of the bottom portion of the body region 20. The electrode surface of the sixth embedded electrode 68 has, in an inner portion, a recess that is recessed in a shape tapering toward the bottom wall side of the sixth trench 66.

The semiconductor device 1 includes a plurality of sixth well regions 69 of the p-type that are formed in regions along the plurality of fourth source structures 65 in a surface layer portion of the first surface portion 8 (the first main surface 3) of the third terminal region 17. The sixth well regions 69 have a p-type impurity concentration higher than the p-type impurity concentration of the body region 20. As a matter of course, the p-type impurity concentration of the sixth well regions 69 may be less than the p-type impurity concentration of the body region 20. The p-type impurity concentration of the sixth well regions 69 is preferably substantially equal to the p-type impurity concentration of the first well regions 35 (the second well regions 36).

The plurality of sixth well regions 69 are respectively formed in a one-to-one correspondence with respect to the plurality of fourth source structures 65. The plurality of sixth well regions 69 are respectively formed in the regions along the corresponding fourth source structures 65 at intervals from each other. The plurality of sixth well regions 69 are formed along the side walls and the bottom walls of the corresponding fourth source structures 65 and are each electrically connected to the body region 20 in the surface layer portion of the first surface portion 8.

The plurality of sixth well regions 69 are formed at intervals to the first surface portion 8 side from the bottom portion of the second semiconductor region 7 and face the first semiconductor region 6 with portions of the second semiconductor region 7 interposed therebetween. Bottom portions of the plurality of sixth well regions 69 are positioned to the bottom portion side of the second semiconductor region 7 with respect to the depth positions of the bottom portions of the plurality of first well regions 35. In this embodiment, the plurality of sixth well regions 69 are exposed from either or both (in this embodiment, both) of the third connecting surface portion 10C and the fourth connecting surface portion 10D. The plurality of sixth well regions 69 form pn junction portions with the second semiconductor region 7.

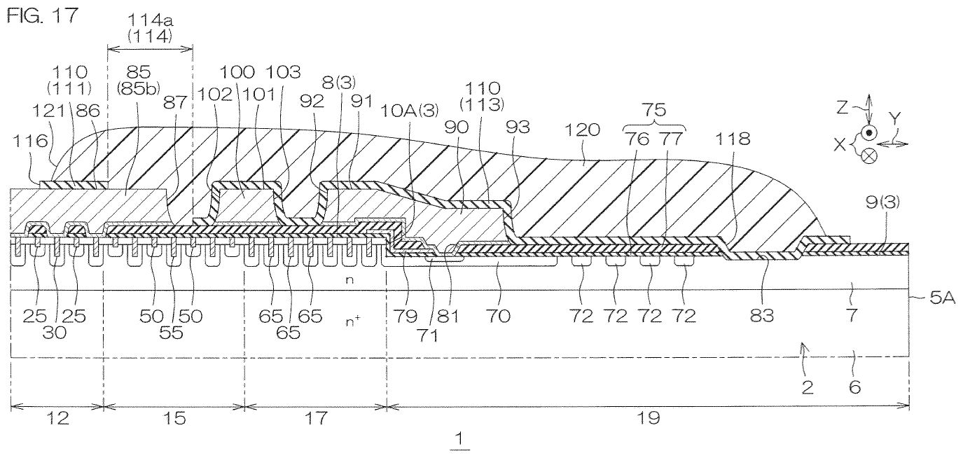

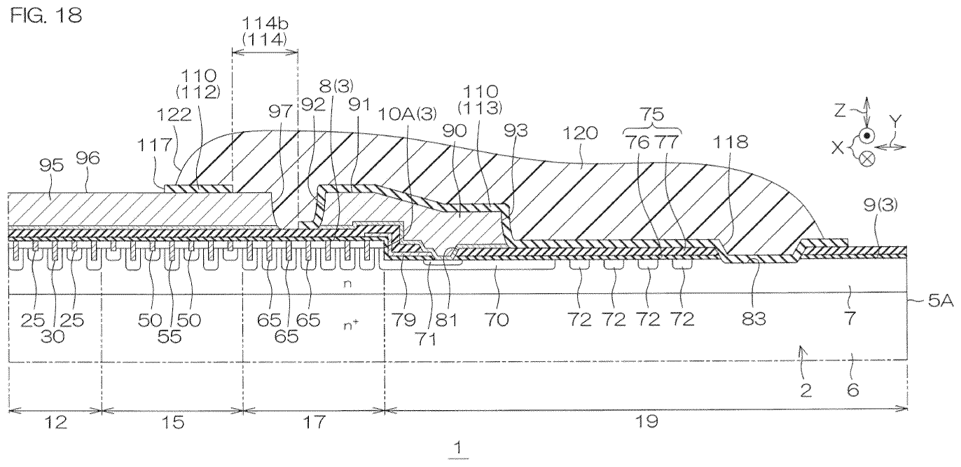

Hereinafter, the arrangement at the outer peripheral region 19 side shall be described. FIG. 17 is a sectional view taken along line XVII-XVII shown in FIG. 1. FIG. 18 is a sectional view taken along line XVIII-XVIII shown in FIG. 1. With reference to FIG. 17 and FIG. 18, the semiconductor device 1 includes an outer well region 70 of the p-type that is formed in a surface layer portion of the second surface portion 9 in the outer peripheral region 19. The source potential is applied to the outer well region 70.

The outer well region 70 has a p-type impurity concentration lower than the p-type impurity concentration of the contact regions 37. The p-type impurity concentration of the outer well region 70 is higher than the p-type impurity concentration of the body region 20. As a matter of course, the p-type impurity concentration of the outer well region 70 may be less than the p-type impurity concentration of the body region 20. The outer well region 70 preferably has a p-type impurity concentration substantially equal to that of the first well regions 35 (the second well regions 36).

The outer well region 70 is formed at intervals to the first surface portion 8 side from the peripheral edges of the second surface portion 9 (from the first to fourth side surfaces 5A to 5D) in plan view. The outer well region 70 extends in a band shape along the first surface portion 8 in plan view.

In this embodiment, the outer well region 70 is formed in a polygonal annular shape (in this embodiment, a quadrangle annular shape) having four sides parallel to peripheral edges of the chip 2 and surrounds the first surface portion 8 in plan view. The outer well region 70 may have an edge portion connecting, in an arcuate shape (preferably, a quarter arcuate shape), a portion extending in the first direction X and a portion extending in the second direction Y.

The outer well region 70 extends from the surface layer portion of the second surface portion 9 to surface layer portions of the first to fourth connecting surface portions 10A to 10D and has a portion extending in the vertical direction Z along the first to fourth connecting surface portions 10A to 10D. The outer well region 70 is electrically connected to the body region 20 in a surface layer portion of the first surface portion 8. At the third connecting surface portion 10C (the fourth connecting surface portion 10D), the outer well region 70 is connected to the second well regions 36, the third well regions 44, the fourth well regions 59, the fifth well regions 60, and the sixth well regions 69.

The outer well region 70 is formed at an interval to the second surface portion 9 side from the bottom portion of the second semiconductor region 7 and faces the first semiconductor region 6 with a portion of the second semiconductor region 7 interposed therebetween. A bottom portion of the outer well region 70 is positioned at the bottom portion side of the second semiconductor region 7 with respect to depth positions of the bottom walls of the gate structures 25. The bottom portion of the outer well region 70 is positioned at the bottom portion side of the second semiconductor region 7 with respect to depth positions of the bottom walls of the first source structures 30 (the second source structures 40).

The bottom portion of the outer well region 70 is positioned at the bottom portion side of the second semiconductor region 7 with respect to depth positions of the contact regions 37. The bottom portion of the outer well region 70 is preferably formed at a depth position substantially equal to the bottom portions of the second well regions 36 (the third well regions 44).

The outer well region 70 forms a pn junction portion with the second semiconductor region 7. The outer well region 70 spreads a depletion layer in the second semiconductor region 7 when a reverse bias voltage is applied. The depletion layer of the outer well region 70 spreads in the horizontal directions and the thickness direction and becomes integral with a depletion layer spreading from the active region 12 side. The outer well region 70 expands the depletion layer, spreading from the active region 12, toward the peripheral edge sides of the second surface portion 9 and relaxes an electric field strength (a concentration of electric field) at the peripheral edges of the first surface portion 8 (at the first to fourth connecting surface portions 10A to 10D).

The semiconductor device 1 includes an outer contact region 71 of the p-type that is formed in a surface layer portion of the second surface portion 9 in the outer peripheral region 19. The outer contact region 71 has a p-type impurity concentration higher than the p-type impurity concentration of the body region 20. The p-type impurity concentration of the outer contact region 71 is higher than the p-type impurity concentration of the outer well region 70. The p-type impurity concentration of the outer contact region 71 is preferably substantially equal to the p-type impurity concentration of the contact regions 37.

The outer contact region 71 is formed in the surface layer portion of the second surface portion 9 at intervals from the peripheral edges of the first surface portion 8 (from the first to fourth connecting surface portions 10A to 10D) and from the peripheral edges of the second surface portion 9 (from the first to fourth side surfaces 5A to 5D) in plan view. Specifically, the outer contact region 71 is formed in a surface layer portion of the outer well region 70. The outer contact region 71 is formed at an interval to the second surface portion 9 side from the bottom portion of the outer well region 70 and faces the second semiconductor region 7 with a portion of the outer well region 70 interposed therebetween.

The outer contact region 71 extends in a band shape along the first surface portion 8 in plan view. In this embodiment, the outer contact region 71 is formed in a polygonal annular shape (in this embodiment, a quadrangle annular shape) having four sides parallel to the peripheral edges of the chip 2 and surrounds the first surface portion 8 in plan view. The outer contact region 71 may have an edge portion connecting, in an arcuate shape (preferably, a quarter arcuate shape), a portion extending in the first direction X and a portion extending in the second direction Y.

The bottom portion of the outer well region 70 is positioned at the bottom portion side of the second semiconductor region 7 with respect to the depth positions of the bottom walls of the gate structures 25. The bottom portion of the outer well region 70 is positioned at the bottom portion side of the second semiconductor region 7 with respect to the depth positions of the bottom walls of the first source structures 30 (the second source structures 40). The bottom portion of the outer contact region 71 is preferably formed at a depth position substantially equal to the bottom portions of the contact regions 37.

The semiconductor device 1 includes at least one field region 72 of the p-type that is formed in a surface layer portion of the second surface portion 9 in the outer peripheral region 19. A plurality of the field regions 72 may be formed in an electrically floating state or may be fixed at the source potential. The plurality of field regions 72 relax an electric field inside the chip 2 in the outer peripheral region 19.

The number of field regions 72 is arbitrary. The number of field regions 72 may be not less than 1 and not more than 20. The number of field regions 72 may have a value belonging to at least one range among not less than 1 and not more than 5, not less than 5 and not more than 10, not less than 10 and not more than 15, and not less than 15 and not more than 20. The number of field regions 72 is typically not less than 1 and not more than 8. In this embodiment, the semiconductor device 1 includes four field regions 72.

The plurality of field regions 72 are formed in the surface layer portion of the second surface portion 9 at intervals from the peripheral edges of the first surface portion 8 (from the first to fourth connecting surface portions 10A to 10D) and from the peripheral edges of the second surface portion 9 (from the first to fourth side surfaces 5A to 5D) in plan view. Specifically, the plurality of field regions 72 are formed, in the region between the peripheral edges of the second surface portion 9 and the outer well region 70, at intervals to the peripheral edge side of the second surface portion 9 from the outer well region 70.

The plurality of field regions 72 are formed at intervals to the second surface portion 9 side from the bottom portion of the second semiconductor region 7 and face the first semiconductor region 6 with portions of the second semiconductor region 7 interposed therebetween. The plurality of field regions 72 each extend in a band shape along the first surface portion 8 in plan view.

In this embodiment, the plurality of field regions 72 are each formed in a polygonal annular shape (in this embodiment, a quadrangle annular shape) having four sides parallel to peripheral edges of the chip 2 and surround the first surface portion 8 in plan view. The plurality of field regions 72 may each have an edge portion connecting, in an arcuate shape (preferably, a quarter arcuate shape), a portion extending in the first direction X and a portion extending in the second direction Y.

The plurality of field regions 72 each form a pn junction portion with the second semiconductor region 7. The plurality of field regions 72 each spread a depletion layer in the second semiconductor region 7 when the reverse bias voltage is applied.

The depletion layers of the plurality of field regions 72 spread in the horizontal directions and the thickness direction and become integral with the depletion layer of the outer well region 70. The plurality of field regions 72 expand the depletion layer, spreading from the active region 12, toward the peripheral edge sides of the second surface portion 9 and relax the electric field strength (the concentration of electric field) at the peripheral edges of the first surface portion 8 (at the first to fourth connecting surface portions 10A to 10D).

Widths, depths, intervals, p-type impurity concentrations, etc., of the plurality of field regions 72 are arbitrary and can take on various values in accordance with the electric field to be relaxed. The widths of the plurality of field regions 72 may be substantially fixed or may be non-uniform. The widths of the plurality of field regions 72 may increase gradually toward the peripheral edge sides of the second surface portion 9. The widths of the plurality of field regions 72 may decrease gradually toward the peripheral edge sides of the second surface portion 9.

The depths of the plurality of field regions 72 may be substantially fixed or may be non-uniform. The depths of the plurality of field regions 72 may increase gradually toward the peripheral edge sides of the second surface portion 9. The depths of the plurality of field regions 72 may decrease gradually toward the peripheral edge sides of the second surface portion 9.

The intervals of the plurality of field regions 72 may be substantially fixed or may be non-uniform. The intervals of the plurality of field regions 72 may increase gradually toward the peripheral edge sides of the second surface portion 9. The intervals of the plurality of field regions 72 may decrease gradually toward the peripheral edge sides of the second surface portion 9.

The p-type impurity concentrations of the plurality of field regions 72 may be substantially fixed or may be non-uniform. The p-type impurity concentrations of the plurality of field regions 72 may increase gradually toward the peripheral edge sides of the second surface portion 9. The p-type impurity concentrations of the plurality of field regions 72 may decrease gradually toward the peripheral edge sides of the second surface portion 9.

The p-type impurity concentrations of the plurality of field regions 72 may be substantially equal to the p-type impurity concentration of the body region 20. The p-type impurity concentrations of the plurality of field regions 72 may be higher than the p-type impurity concentration of the body region 20 or may be less than the p-type impurity concentration of the body region 20.

The p-type impurity concentrations of the plurality of field regions 72 may be substantially equal to the p-type impurity concentration of the first well regions 35 (the second well regions 36). The p-type impurity concentrations of the plurality of field regions 72 may be higher than the p-type impurity concentration of the first well regions 35 (the second well regions 36) or may be less than the p-type impurity concentration of the first well regions 35 (the second well regions 36).

The p-type impurity concentrations of the plurality of field regions 72 may be substantially equal to the p-type impurity concentration of the outer well region 70. The p-type impurity concentrations of the plurality of field regions 72 may be higher than the p-type impurity concentration of the outer well region 70 or may be less than the p-type impurity concentration of the outer well region 70.

The p-type impurity concentrations of the plurality of field regions 72 may be substantially equal to the p-type impurity concentration of the contact regions 37 (the outer contact region 71). The p-type impurity concentrations of the plurality of field regions 72 may be higher than the p-type impurity concentration of the contact regions 37 (the outer contact region 71) or may be less than the p-type impurity concentration of the contact regions 37 (the outer contact region 71).

The semiconductor device 1 includes a first inorganic film 75 with an insulating property that selectively covers the first main surface 3. The first inorganic film 75 is an example of a “covered object.” The first inorganic film 75 may be referred to as an “inorganic insulating film (first inorganic insulating film),” etc.

The first inorganic film 75 selectively covers the first surface portion 8, the second surface portion 9, and the first to fourth connecting surface portions 10A to 10D. In this embodiment, the first inorganic film 75 is continuous to the peripheral edges of the second surface portion 9 (the first to fourth side surfaces 5A to 5D). That is, the first inorganic film 75 is formed flush with the peripheral edges of the second surface portion 9 (the first to fourth side surfaces 5A to 5D).

The first inorganic film 75 has a laminated structure that includes a lower inorganic film 76 and an upper inorganic film 77. The lower inorganic film 76 may be referred to as a “base insulating film,” a “main surface insulating film,” etc. The upper inorganic film 77 may be referred to as an “overlaying insulating film,” an “interlayer insulating film,” an “intermediate insulating film,” etc.

The lower inorganic film 76 may include at least one among a silicon oxide film, a silicon nitride film, and a silicon oxynitride film. The lower inorganic film 76 preferably includes the same type of insulating material as the insulating material of the first insulating film 27, etc. In this embodiment, the lower inorganic film 76 has a single layer structure constituted of a silicon oxide film. The lower inorganic film 76 particularly preferably includes a silicon oxide film that is constituted of the oxide of the chip 2.

The lower inorganic film 76 selectively covers the first surface portion 8, the second surface portion 9, and the first to fourth connecting surface portions 10A to 10D. In the first surface portion 8, the lower inorganic film 76 is connected to the first insulating films 27, the second insulating films 32, the third insulating films 42, the fourth insulating films 52, the fifth insulating films 57, and the sixth insulating films 67 and exposes the first embedded electrodes 28, the second embedded electrodes 33, the third embedded electrodes 43, the fourth embedded electrodes 53, the fifth embedded electrodes 58, and the sixth embedded electrodes 68.

In the second surface portion 9, the lower inorganic film 76 covers the outer well region 70, the outer contact region 71, and the plurality of field regions 72. At the first to fourth connecting surface portions 10A to 10D, the lower inorganic film 76 is connected to the second insulating films 32, the third insulating films 42, the fourth insulating films 52, the fifth insulating films 57, and the sixth insulating films 67 and exposes the second embedded electrodes 33, the third embedded electrodes 43, the fourth embedded electrodes 53, the fifth embedded electrodes 58, and the sixth embedded electrodes 68.

At the first to fourth connecting surface portions 10A to 10D, the lower inorganic film 76 covers the body region 20, the second well regions 36, the third well regions 44, the fourth well regions 59, the fifth well regions 60, the sixth well regions 69, and the outer well region 70.

The upper inorganic film 77 may include at least one among a silicon oxide film, a silicon nitride film, and a silicon oxynitride film. The upper inorganic film 77 preferably includes a silicon oxide film. The upper inorganic film 77 preferably includes an insulating material with a property different from that of the insulating material of the lower inorganic film 76.

For example, the upper inorganic film 77 preferably has a single layer structure or a laminated structure that includes at least one among a silicon oxide film that contains phosphorus (a PSG film), a silicon oxide film that contains phosphorus and boron (a BPSG film), a non-doped silicon oxide film (an NSG film), and a tetraethyl orthosilicate film (a TEOS film). For example, the upper inorganic film 77 may have a laminated structure that includes an NSG film laminated on the lower inorganic film 76 and a PSG film (or a BPSG film) laminated on the NSG film.

The upper inorganic film 77 is laminated on the lower inorganic film 76 and selectively covers the first surface portion 8, the second surface portion 9, and the first to fourth connecting surface portions 10A to 10D with the lower inorganic film 76 interposed therebetween. In the first surface portion 8, the upper inorganic film 77 covers the plurality of gate structures 25 (the first embedded electrodes 28), the plurality of first source structures 30 (the second embedded electrodes 33), the plurality of second source structures 40 (the third embedded electrodes 43), the plurality of dummy gate structures 50 (the fourth embedded electrodes 53), the plurality of third source structures 55 (the fifth embedded electrodes 58), and the plurality of fourth source structures 65 (the sixth embedded electrodes 68).

In the second surface portion 9, the upper inorganic film 77 covers the outer well region 70, the outer contact region 71, and the plurality of field regions 72 with the lower inorganic film 76 interposed therebetween. At the first to fourth connecting surface portions 10A to 10D, the upper inorganic film 77 covers the plurality of first source structures 30 (the second embedded electrodes 33), the plurality of second source structures 40 (the third embedded electrodes 43), the plurality of dummy gate structures 50 (the fourth embedded electrodes 53), the plurality of third source structures 55 (the fifth embedded electrodes 58), and the plurality of fourth source structures 65 (the sixth embedded electrodes 68).

With reference again to FIG. 8 to FIG. 12, etc., the semiconductor device 1 includes a plurality of gate connection electrodes 78 that selectively cover the plurality of gate structures 25 in the active region 12. The gate connection electrodes 78 may be referred to as “connection electrodes,” “connection electrode films,” “gate connection electrode films,” etc.

The gate connection electrode 78 may each be deemed to be a constituent element of the gate structure 25. The plurality of gate connection electrodes 78 contains either or both of a conductive polysilicon of the p-type and a conductive polysilicon of the n-type. The plurality of gate connection electrodes 78 preferably contain the same type of conductive material as the conductive material of the first embedded electrodes 28.

The plurality of gate connection electrodes 78 are respectively interposed between the plurality of gate structures 25 and the upper inorganic film 77. That is, the plurality of gate connection electrodes 78 are respectively arranged on the plurality of gate structures 25 and are covered by the upper inorganic film 77.

In this embodiment, the plurality of gate connection electrodes 78 are respectively formed in a multiple-to-one correspondence with respect to the plurality of gate structures 25. In this embodiment, the plurality of gate connection electrodes 78 respectively cover both end portions of the corresponding gate structures 25 in film shapes and each extend in a band shape in the first direction X.

In plan view, the plurality of gate connection electrodes 78 are formed at intervals in the second direction Y from the plurality of first source structures 30 and are formed at intervals in the first direction X from the plurality of second source structures 40.

The plurality of gate connection electrodes 78 expose the plurality of first source structures 30 and the plurality of second source structures 40 and are electrically separated from the plurality of first source structures 30 and the plurality of second source structures 40. In plan view, the plurality of gate connection electrodes 78 are aligned alternately with the plurality of first source structures 30 in the second direction Y and do not face the plurality of second source structures 40 in the second direction Y.

The plurality of gate connection electrodes 78 are each connected to the first embedded electrode 28 at a portion that covers the corresponding gate structure 25 and each have a portion that is led out from above the first embedded electrode 28 to above the lower inorganic film 76. That is, the plurality of gate connection electrodes 78 each have a portion facing the corresponding gate structure 25 in the vertical direction Z and a portion facing the body region 20 in the vertical direction Z.

In this embodiment, the plurality of gate connection electrodes 78 are each formed integral to the first embedded electrode 28 of the corresponding gate structure 25. That is, the plurality of gate connection electrodes 78 are each constituted of a lead-out portion of the corresponding first embedded electrode 28. As a matter of course, the gate connection electrode 78 may instead be formed as a separate member from the first embedded electrode 28.

The plurality of gate connection electrodes 78 each have an electrode surface extending along the first surface portion 8. In this embodiment, the plurality of gate connection electrodes 78 are each formed in a shape (a truncated quadrilateral prism shape) tapering toward the electrode surface in sectional view. The electrode surface is preferably formed wider than the gate structure 25 in regard to the second direction Y.

A thickness of the gate connection electrode 78 may be less than the depth of the first source structure 30 or may be greater than the depth of the first source structure 30. The thickness of the gate connection electrode 78 may be less than the depth of the second surface portion 9 or may be greater than the depth of the second surface portion 9. The thickness of the gate connection electrode 78 may be less than the depth of the gate structure 25 or may be greater than the depth of the gate structure 25.

The thickness of the gate connection electrode 78 may be not less than 0.05 μm and not more than 3 μm. The thickness of the gate connection electrode 78 may have a value belonging to at least one range among not less than 0.05 μm and not more than 0.1 μm, not less than 0.1 μm and not more than 0.5 μm, not less than 0.5 μm and not more than 1 μm, not less than 1 μm and not more than 1.5 μm, not less than 1.5 μm and not more than 2 μm, not less than 2 μm and not more than 2.5 μm, and not less than 2.5 μm and not more than 3 μm. The thickness of the gate connection electrode 78 is preferably not less than 1.5 μm and not more than 2.5 μm.

With reference again to FIG. 8 to FIG. 16, etc., the semiconductor device 1 includes a side wall wiring 79 that covers at least one of the first to fourth connecting surface portions 10A to 10D on the second surface portion 9. Specifically, the side wall wiring 79 is interposed between the lower inorganic film 76 and the upper inorganic film 77. That is, the side wall wiring 79 is arranged on the lower inorganic film 76 and is covered by the upper inorganic film 77. The side wall wiring 79 also functions as a “side wall structure” that moderates a level difference between the first surface portion 8 and the second surface portion 9.

The side wall wiring 79 preferably extends in a band shape at least along either of the third connecting surface portion 10C and the fourth connecting surface portion 10D. In this embodiment, the side wall wiring 79 is formed in a polygonal annular shape (specifically, a quadrangle annular shape) extending along the first to fourth connecting surface portions 10A to 10D and surrounds the first surface portion 8 in plan view. The side wall wiring 79 may have an edge portion connecting, in an arcuate shape (preferably, a quarter arcuate shape), a portion extending in the first direction X and a portion extending in the second direction Y.

The side wall wiring 79 includes a portion extending in a film shape along the second surface portion 9 and a portion extending in a film shape along the first to fourth connecting surface portions 10A to 10D. The portion of the side wall wiring 79 positioned on the second surface portion 9 may cover the second surface portion 9 in a film shape in a region to the second surface portion 9 side with respect to the height position of the first surface portion 8. That is, the portion of the side wall wiring 79 positioned on the second surface portion 9 may have a thickness less than the depth of the second surface portion 9.

The side wall wiring 79 is formed at intervals to the first surface portion 8 side from the plurality of field regions 72 and faces the outer well region 70 with the lower inorganic film 76 interposed therebetween. The side wall wiring 79 is formed at an interval to the first surface portion 8 side from an outer edge portion of the outer well region 70.

In this embodiment, the side wall wiring 79 is formed at an interval to the first surface portion 8 side from an outer edge portion of the outer contact region 71 and has a portion facing the outer contact region 71 with the lower inorganic film 76 interposed therebetween. The side wall wiring 79 may be formed at an interval to the first surface portion 8 side from an inner edge portion of the outer contact region 71 instead.

The side wall wiring 79 covers the first to fourth connecting surface portions 10A to 10D with the lower inorganic film 76 interposed therebetween. At the first to fourth connecting surface portions 10A to 10D, the side wall wiring 79 covers the body region 20, the second well regions 36, the third well regions 44, the fourth well regions 59, the fifth well regions 60, the sixth well regions 69, and the outer well region 70 with the lower inorganic film 76 interposed therebetween.

At the first to fourth connecting surface portions 10A to 10D, the side wall wiring 79 is electrically connected to the plurality of first source structures 30 (the second embedded electrodes 33), the plurality of second source structures 40 (the third embedded electrodes 43), the plurality of dummy gate structures 50 (the fourth embedded electrodes 53), the plurality of third source structures 55 (the fifth embedded electrodes 58), and the plurality of fourth source structures 65 (the sixth embedded electrodes 68).

The side wall wiring 79 has an overlap portion 79a that overlaps onto an edge portion of the first surface portion 8 from at least one of the first to fourth connecting surface portions 10A to 10D. In this embodiment, the overlap portion 79a overlaps onto the first surface portion 8 from all of the first to fourth connecting surface portions 10A to 10D and is formed in an annular shape (specifically, a quadrangle annular shape) surrounding an inner portion of the first surface portion 8. The overlap portion 79a covers the first surface portion 8 in a film shape and extends in a band shape along the edge portion of the first surface portion 8 in plan view.

The overlap portion 79a covers a peripheral edge portion of the first surface portion 8 at intervals from the plurality of gate structures 25. In the peripheral edge portion of the first surface portion 8, the overlap portion 79a is electrically connected to the plurality of first source structures 30 (the second embedded electrodes 33), the plurality of second source structures 40 (the third embedded electrodes 43), the plurality of dummy gate structures 50 (the fourth embedded electrodes 53), the plurality of third source structures 55 (the fifth embedded electrodes 58), and the plurality of fourth source structures 65 (the sixth embedded electrodes 68).

The side wall wiring 79 contains either or both of a conductive polysilicon of the p-type and a conductive polysilicon of the n-type. The side wall wiring 79 preferably contains the same type of conductive material as the conductive material of the first embedded electrodes 28, etc.

In this embodiment, the side wall wiring 79 is formed integral to the second embedded electrodes 33, the third embedded electrodes 43, the fourth embedded electrodes 53, the fifth embedded electrodes 58, and the sixth embedded electrodes 68. As a matter of course, the side wall wiring 79 may instead be formed as a separate member from the second embedded electrodes 33, the third embedded electrodes 43, the fourth embedded electrodes 53, the fifth embedded electrodes 58, and the sixth embedded electrodes 68.

With reference again to FIG. 5 to FIG. 7, the semiconductor device 1 includes a plurality of source openings 80 that are formed in the first inorganic film 75 in the active region 12. The plurality of source openings 80 penetrate through the first inorganic film 75 and selectively expose the plurality of first source structures 30. Specifically, the plurality of source openings 80 are respectively formed in a one-to-one correspondence with respect to the plurality of source structures and each extend in a band shape along the corresponding first source structure 30.

As a matter of course the plurality of source openings 80 may be formed in a multiple-to-one correspondence with respect to the corresponding first source structures 30. In this case, the plurality of source openings 80 may be formed at intervals in the second direction Y along the corresponding first source structures 30. The plurality of source openings 80 each expose the corresponding single first source structure 30, the source region 21, and the plurality of contact regions 37.

With reference again to FIG. 8 to FIG. 16, the semiconductor device 1 includes at least one (in this embodiment, one) outer opening 81 that is formed in the first inorganic film 75 in the outer peripheral region 19. The outer opening 81 penetrates through the first inorganic film 75 and exposes both the outer contact region 71 and the side wall wiring 79.

Specifically, the outer opening 81 penetrates through the upper inorganic film 77 and exposes the side wall wiring 79. Also, the outer opening 81 penetrates through both the lower inorganic film 76 and the upper inorganic film 77 and exposes the outer contact region 71. In plan view, the outer opening 81 extends in a band shape along the outer contact region 71 and the side wall wiring 79.

In this embodiment, the outer opening 81 is formed in a polygonal annular shape (specifically, a quadrangle annular shape) surrounding the first surface portion 8 in plan view. As a matter of course, the semiconductor device 1 may have a plurality of the outer openings 81. In this case, the plurality of outer openings 81 may be formed at intervals along the outer contact region 71 so as to surround the first surface portion 8.

With reference to FIG. 8 to FIG. 12, the semiconductor device 1 includes a plurality of gate openings 82 that are formed in the first inorganic film 75 in the active region 12. The plurality of gate openings 82 penetrate through the first inorganic film 75 and selectively expose the plurality of gate structures 25.

Specifically, the plurality of gate openings 82 are respectively formed in portions of the first inorganic film 75 that covers the plurality of gate connection electrodes 78 and respectively expose the plurality of gate connection electrodes 78. The plurality of gate openings 82 are formed in a one-to-one correspondence with respect to the plurality of gate connection electrodes 78 and each extend in a band shape in the first direction X in plan view.

With reference to FIG. 17 and FIG. 18, the semiconductor device 1 includes at least one (in this embodiment, one) anchor opening 83 that is formed in the first inorganic film 75 in the outer peripheral region 19. The anchor opening 83 is selectively formed in a portion of the first inorganic film 75 that covers a peripheral edge portion of the second surface portion 9.

That is, the anchor opening 83 is formed in a region between the first surface portion 8 and the second surface portion 9. Specifically, the anchor opening 83 is formed in a region between the peripheral edges of the second surface portion 9 and the outer well region 70. More specifically, the anchor opening 83 is formed between the peripheral edges of the second surface portion 9 and the plurality of field regions 72 (the outermost field region 72).

The anchor opening 83 penetrates through the first inorganic film 75 and exposes the second surface portion 9. Specifically, the anchor opening 83 exposes the second semiconductor region 7. The anchor opening 83 may be dug in to the bottom portion side of the second semiconductor region 7 with respect to a height position of the second surface portion 9. That is, a bottom wall of the anchor opening 83 may be positioned at the bottom portion side of the second semiconductor region 7 with respect to a height position of the second surface portion 9.

The anchor opening 83 extends in a band shape along the first surface portion 8 in plan view. In this embodiment, the anchor opening 83 is formed in a polygonal annular shape (specifically, a quadrangle annular shape) surrounding the first surface portion 8 in plan view. As a matter of course, the semiconductor device 1 may have a plurality of the anchor openings 83. In this case, the plurality of anchor openings 83 may be formed at intervals along the first surface portion 8 so as to surround the first surface portion 8.

The plurality of anchor openings 83 may be formed in a matrix or a staggered arrangement at intervals in the first direction X and the second direction Y so as to surround the first surface portion 8. As a matter of course, the plurality of anchor openings 83 may be formed in a stripe shape or in a lattice so as to surround the first surface portion 8. Also, the plurality of anchor openings 83 may be formed in a concentric shape so as to surround the first surface portion 8.

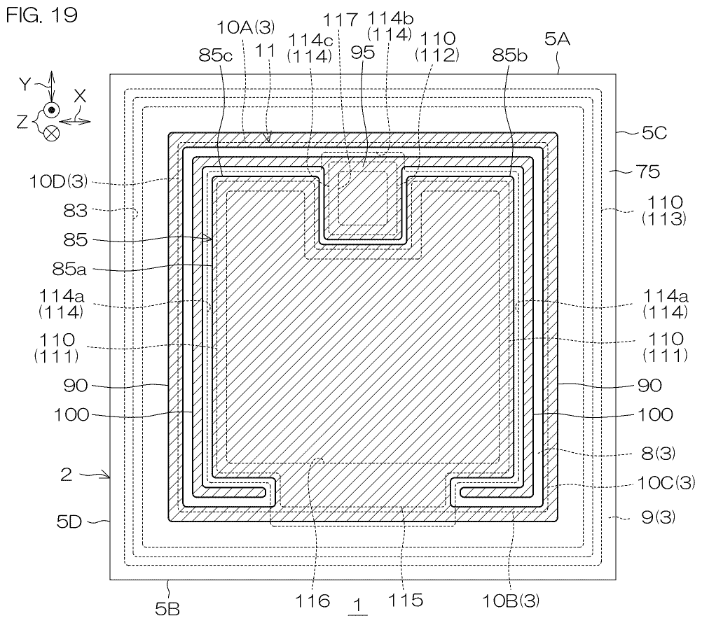

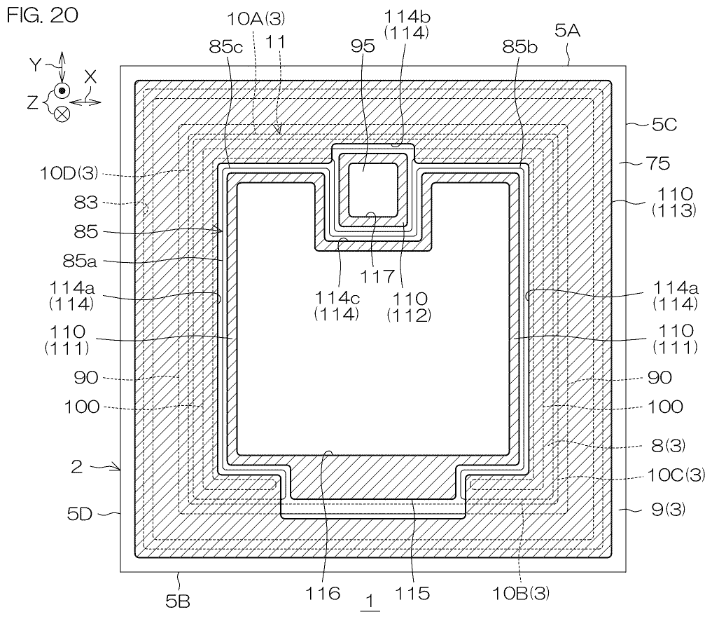

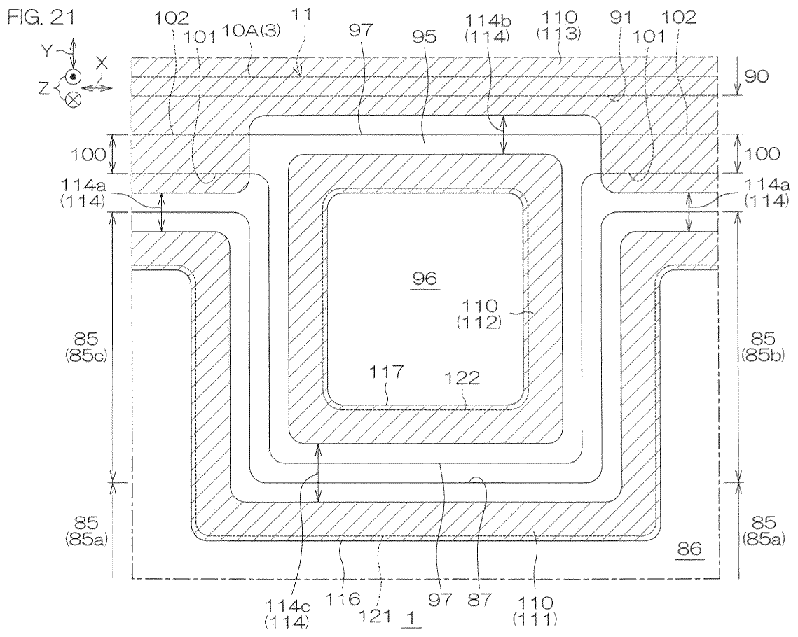

Hereinafter, the arrangement on the first main surface 3 shall be described. FIG. 19 is a plan view showing a layout example of a main electrode (a source electrode 85, a source wiring 90, a gate electrode 95, and a gate wiring 100) that is arranged on the first main surface 3. FIG. 20 is a plan view showing a first layout example of a second inorganic film 110. FIG. 21 is an enlarged plan view showing a principal portion of the second inorganic film 110.

With reference to FIG. 19 to FIG. 21, the semiconductor device 1 includes the source electrode 85 that is arranged on the first inorganic film 75. The source electrode 85 is a terminal electrode to which the source potential is applied from an exterior. The source electrode 85 may be referred to as an “electrode,” a “first electrode,” a “first pad electrode,” a “first main surface electrode,” a “first terminal electrode,” a “source pad electrode,” etc.

The source electrode 85 has a thickness greater than the depth of the gate structure 25. The thickness of the source electrode 85 is preferably greater than the depth of the first source structure 30. The thickness of the source electrode 85 is preferably greater than the depth of the second surface portion 9. The thickness of the source electrode 85 is preferably greater than a thickness (a total thickness) of the first inorganic film 75.

The thickness of the source electrode 85 may be not less than 0.5 μm and not more than 5 μm. The thickness of the source electrode 85 may have a value belonging to at least one range among not less than 0.5 μm and not more than 1 μm, not less than 1 μm and not more than 1.5 μm, not less than 1.5 μm and not more than 2 μm, not less than 2 μm and not more than 2.5 μm, not less than 2.5 μm and not more than 3 μm, not less than 3 μm and not more than 3.5 μm, not less than 3.5 μm and not more than 4 μm, not less than 4 μm and not more than 4.5 μm, and not less than 4.5 μm and not more than 5 μm.

The source electrode 85 is arranged on a covering portion of the first inorganic film 75 that covers the first surface portion 8. In plan view, the source electrode 85 covers at least the active region 12. The source electrode 85 covers the active region 12 at intervals from the first side end region 13 and the second side end region 14. That is, the source electrode 85 covers the first surface portion 8 at intervals from both end portions of the plurality of gate structures 25. Specifically, the source electrode 85 is formed at intervals inward from the plurality of gate connection electrodes 78.

The source electrode 85 may cover either or both of the first terminal region 15 and the third terminal region 17. That is, at the first terminal region 15 side, the source electrode 85 may face the plurality of dummy gate structures 50 and the plurality of third source structures 55 with the first inorganic film 75 interposed therebetween. At the third terminal region 17 side, the source electrode 85 may face the plurality of fourth source structures 65. As a matter of course, the source electrode 85 may cover the active region 12 at an interval from either or both of the first terminal region 15 and the third terminal region 17.

In this embodiment, the source electrode 85 has a first pad portion 85a, a second pad portion 85b, and a third pad portion 85c. The first pad portion 85a has a comparatively large planar area and forms a main body of the source electrode 85. In this embodiment, the first pad portion 85a, in plan view, is formed in a polygonal shape (in this embodiment, a quadrangle shape) having four sides parallel to the peripheral edges of the chip 2 and is shifted to the second side surface 5B (the second connecting surface portion 10B) side with respect to the first side surface 5A (the first connecting surface portion 10A).

The second pad portion 85b has a planar area less than a planar area of the first pad portion 85a and is led out in a band shape (quadrangle shape) toward the first connecting surface portion 10A from one end portion (an end portion at the third connecting surface portion 10C side) in the first direction X of the first pad portion 85a. The third pad portion 85c has a planar area less than the planar area of the first pad portion 85a, is led out in a band shape (quadrangle shape) toward the first connecting surface portion 10A from the other end portion (an end portion at the fourth connecting surface portion 10D side) in the first direction X of the first pad portion 85a, and faces the second pad portion 85b in the second direction Y.

The planar area of the third pad portion 85c may be substantially equal to the planar area of the second pad portion 85b. As a matter of course, the planar area of the third pad portion 85c may be greater than the planar area of the second pad portion 85b or may be less than the planar area of the second pad portion 85b. Either or both of the second pad portion 85b and the third pad portion 85c may be used as a terminal portion for current monitoring.

A proportion at which the source electrode 85 occupies the first surface portion 8 is preferably not less than 50% and less than 100%. The proportion of the source electrode 85 may have a value belonging to any one range among not less than 50% and not more than 60%, not less than 60% and not more than 70%, not less than 70% and not more than 80%, not less than 80% and not more than 90%, and not less than 90% and less than 100%.

The source electrode 85 does not necessarily have to have both the second pad portion 85b and the third pad portion 85c at the same time. The source electrode 85 may have just either of the second pad portion 85b and the third pad portion 85c. As a matter of course, the source electrode 85 may be constituted of just the first pad portion 85a and may lack both the second pad portion 85b and the third pad portion 85c.

The source electrode 85 enters into the plurality of source openings 80 from above the first inorganic film 75 and is electrically connected to the plurality of first source structures 30, the source region 21, and the plurality of contact regions 37 inside the plurality of source openings 80.

The source electrode 85 includes a first electrode surface 86 and a first electrode side wall 87. The first electrode surface 86 extends along the first inorganic film 75. The first electrode surface 86 may have a plurality of depressions recessed toward the first surface portion 8 side at portions that cover the plurality of source openings 80. The first electrode side wall 87 is positioned on the first inorganic film 75. The first electrode side wall 87 is inclined obliquely downward from the first electrode surface 86 toward the first inorganic film 75. In this embodiment, the first electrode side wall 87 is inclined obliquely downward in a curved shape from the first electrode surface 86 toward the first inorganic film 75.

In this embodiment, the source electrode 85 has a laminated structure that includes a first lower electrode film 88 and a first upper electrode film 89 that are laminated in that order from the first inorganic film 75 side. The first lower electrode film 88 is laminated in a film shape as a base film (a barrier film) of the source electrode 85 on the first inorganic film 75 and forms a lower layer portion of the first electrode side wall 87 of the source electrode 85.

In this embodiment, the first lower electrode film 88 has a laminated structure including a Ti film and a TiN film that are laminated in that order from the first inorganic film 75 side. The first lower electrode film 88 may instead have a single layer structure constituted of the Ti film or the TiN film. The first lower electrode film 88 has a thickness (a total thickness) less than the thickness (the total thickness) of the first inorganic film 75.

The thickness (the total thickness) of the first lower electrode film 88 may be not less than 0.01 μm and not more than 1 μm. The thickness (the total thickness) of the first lower electrode film 88 may be not more than 0.75 μm, not more than 0.5 μm, not more than 0.25 μm, or not more than 0.1 μm.

The first lower electrode film 88 entirely covers, in a film shape, a region of the first inorganic film 75 in which the plurality of source openings 80 are formed and enters into the plurality of source openings 80 from above the first inorganic film 75. The first lower electrode film 88 has a portion that covers an insulating main surface of the first inorganic film 75 in a film shape, portions that cover wall surfaces of the plurality of source openings 80 in film shapes, and portions that cover the first surface portion 8 inside the plurality of source openings 80 in film shapes.

Specifically, the first lower electrode film 88 directly covers the insulating main surface of the first inorganic film 75 and faces the plurality of gate structures 25 with the first inorganic film 75 interposed therebetween. The first lower electrode film 88 enters into the plurality of source openings 80 from above the insulating main surface of the first inorganic film 75 and covers, in film shapes, the wall surfaces of the plurality of source openings 80.

The first lower electrode film 88 covers, in film shapes, the first surface portion 8 inside the plurality of source openings 80. Inside the plurality of source openings 80, the first lower electrode film 88 is mechanically and electrically connected to the plurality of first source structures 30, the source region 21, and the plurality of contact regions 37.

As a main body portion of the source electrode 85, the first upper electrode film 89 is laminated in a film shape on the first lower electrode film 88 and forms the first electrode surface 86 and an upper layer portion of the first electrode side wall 87 of the source electrode 85. The first upper electrode film 89 includes a conductive material differing from the first lower electrode film 88. The first upper electrode film 89 may include at least one among an Al film, an Al alloy film, a Cu film, and a Cu alloy film. The Al alloy film may include at least one among an AlSi alloy film, an AlCu alloy film, and an AlSiCu alloy film.

The first upper electrode film 89 has a thickness greater than the thickness (the total thickness) of the first lower electrode film 88. The thickness of the first upper electrode film 89 is preferably greater than the thickness of the first inorganic film 75. The thickness of the first upper electrode film 89 is preferably greater than the depth of the gate structure 25. The thickness of the first upper electrode film 89 is preferably greater than the depth of the first source structure 30. The thickness of the first upper electrode film 89 is preferably greater than the depth of the second surface portion 9.

The thickness of the first upper electrode film 89 may be not less than 0.5 μm and not more than 5 μm. The thickness of the first upper electrode film 89 may have a value belonging to at least one range among not less than 0.5 μm and not more than 1 μm, not less than 1 μm and not more than 1.5 μm, not less than 1.5 μm and not more than 2 μm, not less than 2 μm and not more than 2.5 μm, not less than 2.5 μm and not more than 3 μm, not less than 3 μm and not more than 3.5 μm, not less than 3.5 μm and not more than 4 μm, not less than 4 μm and not more than 4.5 μm, and not less than 4.5 μm and not more than 5 μm.

The first upper electrode film 89 entirely covers, in a film shape, the region of the first inorganic film 75 in which the plurality of source openings 80 are formed and refills the plurality of source openings 80. The first upper electrode film 89 has a portion that covers the insulating main surface of the first inorganic film 75 with the first lower electrode film 88 interposed therebetween, portions that cover wall surfaces of the plurality of source openings 80 with the first lower electrode film 88 interposed therebetween, and portions that cover the first surface portion 8 with the first lower electrode film 88 interposed therebetween.

Specifically, the first upper electrode film 89 covers the insulating main surface of the first inorganic film 75 with the first lower electrode film 88 interposed therebetween and faces the plurality of gate structures 25 with the first inorganic film 75 and the first lower electrode film 88 interposed therebetween. The first upper electrode film 89 enters into the plurality of source openings 80 from above the first inorganic film 75 and covers, in film shapes, the wall surfaces of the plurality of source openings 80 with the first lower electrode film 88 interposed therebetween.

The first upper electrode film 89 covers, in film shapes, the first surface portion 8 inside the plurality of source openings 80 with the first lower electrode film 88 interposed therebetween. Inside the plurality of source openings 80, the first upper electrode film 89 is electrically connected to the plurality of first source structures 30, the source region 21, and the plurality of contact regions 37 via the first lower electrode film 88.

The semiconductor device 1 includes the source wiring 90 that is arranged in a periphery of the source electrode 85 on the first inorganic film 75. The same potential (the source potential) as the potential (the source potential) applied to the source electrode 85 is applied to the source wiring 90. The source wiring 90 may be referred to as a “wiring,” a “first wiring,” a “finger electrode,” a “source finger,” etc.

The source wiring 90 has a thickness greater than the depth of the gate structure 25. The thickness of the source wiring 90 is preferably greater than the depth of the first source structure 30. The thickness of the source wiring 90 is preferably greater than the depth of the second surface portion 9. The thickness of the source wiring 90 is preferably substantially equal to the thickness of the source electrode 85.

As a matter of course, the thickness of the source wiring 90 may be greater than the thickness of the source electrode 85 or may be less than the thickness of the source electrode 85. The thickness of the source wiring 90 is preferably greater than the thickness (the total thickness) of the first inorganic film 75.

The thickness of the source wiring 90 may be not less than 0.5 μm and not more than 5 μm. The thickness of the source wiring 90 may have a value belonging to at least one range among not less than 0.5 μm and not more than 1 μm, not less than 1 μm and not more than 1.5 μm, not less than 1.5 μm and not more than 2 μm, not less than 2 μm and not more than 2.5 μm, not less than 2.5 μm and not more than 3 μm, not less than 3 μm and not more than 3.5 μm, not less than 3.5 μm and not more than 4 μm, not less than 4 μm and not more than 4.5 μm, and not less than 4.5 μm and not more than 5 μm.

The source wiring 90 has a wiring width that is smaller than an electrode width of the source electrode 85 and is selectively routed on the first inorganic film 75. The source wiring 90 extends in a band shape along the first electrode side wall 87 of the source electrode 85 at an interval from the first electrode side wall 87.

The source wiring 90 preferably extends in a band shape at least along either of the third connecting surface portion 10C and the fourth connecting surface portion 10D. In this embodiment, the source wiring 90 is formed in a polygonal annular shape (specifically, a quadrangle annular shape) extending along the first to fourth connecting surface portions 10A to 10D and surrounds the source electrode 85 in plan view.

In this embodiment, the source wiring 90 is arranged on the first side end region 13, the second side end region 14, the first terminal region 15, second terminal region 16, the third terminal region 17, and the fourth terminal region 18 and surrounds the active region 12 in plan view. The source wiring 90 may have an edge portion connecting, in an arcuate shape (preferably, a quarter arcuate shape), a portion extending in the first direction X and a portion extending in the second direction Y.

The source wiring 90 is electrically connected to the source electrode 85 on the first surface portion 8. Specifically, the source wiring 90 has, in a portion extending along the second connecting surface portion 10B, a portion extending in a band shape in the second direction Y toward the source electrode 85 (the first pad portion 85a) and is connected to an end portion of the source electrode 85 (the first pad portion 85a). That is, the source wiring 90 is formed as a lead-out wiring that is led out from the source electrode 85.

In a connection portion with the source electrode 85, the source wiring 90 covers the second terminal region 16 and the fourth terminal region 18. In the connection with the source electrode 85, the source wiring 90 faces the second terminal region 16 (the plurality of dummy gate structures 50 and the plurality of third source structures 55) with the first inorganic film 75 interposed therebetween.

In the connection portion with the source electrode 85, the source wiring 90 faces the fourth terminal region 18 (the plurality of fourth source structures 65) with the first inorganic film 75 interposed therebetween. The connection portion of the source electrode 85 and the source wiring 90 may be regarded as a portion of the source electrode 85.

The source wiring 90 crosses at least one (in this embodiment, all) of the first to fourth connecting surface portions 10A to 10D from the first surface portion 8 and is led out onto the second surface portion 9. In this embodiment, the source wiring 90 is formed as an outermost peripheral wiring on the second surface portion 9. That is, the source wiring 90 does not face another electrode in the horizontal directions along the insulating main surface of the first inorganic film 75 in the outer peripheral region 19. In other words, the other electrodes are not interposed in a region between the peripheral edges of the second surface portion 9 and the source wiring 90.

On the first to fourth connecting surface portions 10A to 10D, the source wiring 90 covers the side wall wiring 79 with the first inorganic film 75 (the upper inorganic film 77) interposed therebetween. A film forming property of the source wiring 90 is improved by the side wall wiring 79. The source wiring 90 enters into the outer opening 81 from above the first inorganic film 75 and is connected to both the outer contact region 71 and the side wall wiring 79 inside the outer opening 81.

The source wiring 90 is thereby electrically connected to the outer contact region 71 and the side wall wiring 79. The source wiring 90 transmits the source potential applied to the source electrode 85 to the outer contact region 71 and the side wall wiring 79. That is, the source wiring 90 transmits the source potential to the first source structures 30, the second source structures 40, the dummy gate structures 50, the third source structures 55, and the fourth source structures 65 via the side wall wiring 79.

The source wiring 90 is arranged at intervals to the first surface portion 8 side from the plurality of field regions 72 and face the outer well region 70 with the first inorganic film 75 interposed therebetween. In this embodiment, the source wiring 90 is arranged at an interval to the first surface portion 8 side from the outer edge portion of the outer well region 70 and covers an entirety of the outer contact region 71.

The source wiring 90 may cross the outer edge portion of the outer well region 70. That is, the source wiring 90 may cover an entirety of the outer well region 70. In this case, the source wiring 90 is preferably formed at intervals to the first surface portion 8 side from the plurality of field regions 72. As a matter of course, the source wiring 90 may cover at least one of the plurality of field regions 72.

The source wiring 90 includes a first wiring surface 91, a first inner side wall 92 at an inner side (the source electrode 85 side), and a first outer side wall 93 at an outer side (the peripheral edge side of the chip 2). The first inner side wall 92 may be referred to as a “first wiring side wall” and a second inner side wall 102 may be referred to as a “second wiring side wall.”

The first wiring surface 91 has a portion positioned on the first surface portion 8 and a portion positioned on the second surface portion 9. The portion of the first wiring surface 91 positioned on the first surface portion 8 is positioned at a height position substantially equal to the first electrode surface 86 of the source electrode 85.

The portion of the first wiring surface 91 positioned on the second surface portion 9 is recessed further toward the second surface portion 9 side than the portion of the first wiring surface 91 positioned on the first surface portion 8. The portion of the first wiring surface 91 positioned on the second surface portion 9 is preferably positioned higher (further to the side of the portion of the first wiring surface 91 positioned on the first surface portion 8) than the height position of the first surface portion 8. As a matter of course, the portion of the first wiring surface 91 positioned on the second surface portion 9 may instead be positioned lower (further to the second surface portion 9 side) than the height position of the first surface portion 8.

The first inner side wall 92 is positioned, at an interval from the first electrode side wall 87 of the source electrode 85, on the covering portion of the first inorganic film 75 that covers the first surface portion 8. The first inner side wall 92 is inclined obliquely downward from the first wiring surface 91 toward the first inorganic film 75. In this embodiment, the first inner side wall 92 is inclined obliquely downward in a curved shape from the first wiring surface 91 toward the first inorganic film 75.

The first outer side wall 93 is positioned on the covering portion of the first inorganic film 75 that covers the second surface portion 9. The first outer side wall 93 is inclined obliquely downward from the first wiring surface 91 toward the first inorganic film 75. In this embodiment, the first outer side wall 93 is inclined obliquely downward in a curved shape from the first wiring surface 91 toward the first inorganic film 75.

In this embodiment, the first outer side wall 93 faces the outer well region 70 with the first inorganic film 75 interposed therebetween. The first outer side wall 93 may face the outer contact region 71 with the first inorganic film 75 interposed therebetween. The first outer side wall 93 may face the second semiconductor region 7 with the first inorganic film 75 interposed therebetween. The first outer side wall 93 may face at least one of the plurality of field regions 72 with the first inorganic film 75 interposed therebetween.

As with the source electrode 85, the source wiring 90 has the laminated structure including the first lower electrode film 88 and the first upper electrode film 89. The first lower electrode film 88 is laminated in a film shape as a base film (a barrier film) of the source wiring 90 on the first inorganic film 75 and forms lower layer portions of the first inner side wall 92 and the first outer side wall 93 of the source wiring 90.

The first lower electrode film 88 entirely covers, in a film shape, a region of the first inorganic film 75 in which the outer opening 81 is formed and enters into the outer opening 81 from above the first inorganic film 75. Inside the outer opening 81, the first lower electrode film 88 is mechanically and electrically connected to the outer contact region 71 and the side wall wiring 79.

As a main body portion of the source wiring 90, the first upper electrode film 89 is laminated in a film shape on the first lower electrode film 88 and forms the first wiring surface 91, an upper layer portion of the first inner side wall 92, and an upper layer portion of the first outer side wall 93 of the source wiring 90. The first upper electrode film 89 entirely covers, in a film shape, the region of the first inorganic film 75 in which the outer opening 81 is formed and refills the outer opening 81. Inside the outer opening 81, the first upper electrode film 89 is electrically connected to the outer contact region 71 and the side wall wiring 79 via the first lower electrode film 88.

In an interior of the chip 2, different electric field distributions are formed at the first surface portion 8 side (the active region 12 side) and the second surface portion 9 side (the outer peripheral region 19 side). For example, at the first surface portion 8 side, an electric field distribution that is substantially uniform along the first main surface 3 is formed. On the other hand, at the second surface portion 9 side, a terminal portion of the electric field distribution formed at the first surface portion 8 side is formed and the electric field concentrates more readily than in the first surface portion 8.

That is, the source electrode 85 is arranged on the active region 12 (a first region) having a comparatively low first electric field. On the other hand, the source wiring 90 is arranged on the outer peripheral region 19 (a second region) having a second electric field that is higher than the first electric field.

That is, since the source wiring 90 is arranged at a location at which the electric field concentrates readily, the second electric field with respect to the source wiring 90 becomes locally higher than the first electric field with respect to the source electrode 85 in some cases. For example, the electric field inside the chip 2 leaks out from the interior to the exterior of the chip 2 at an outer side of the source wiring 90. The second electric field at the outer peripheral region 19 thus becomes locally high in a vicinity of the first outer side wall 93 of the source wiring 90 in some cases.

The semiconductor device 1 includes the gate electrode 95 that is arranged on the first inorganic film 75. The gate electrode 95 is a terminal electrode to which the gate potential is applied from the exterior. The gate electrode 95 may be referred to as an “electrode,” a “second electrode,” a “second pad electrode,” a “second main surface electrode,” a “second terminal electrode,” a “gate pad electrode,” etc.

The gate electrode 95 has a thickness greater than the depth of the gate structure 25. The thickness of the gate electrode 95 is preferably greater than the depth of the first source structure 30. The thickness of the gate electrode 95 is preferably greater than the depth of the second surface portion 9. The thickness of the gate electrode 95 is preferably substantially equal to the thickness of the source electrode 85. The thickness of the gate electrode 95 is preferably greater than the thickness (the total thickness) of the first inorganic film 75.

The thickness of the gate electrode 95 may be not less than 0.5 μm and not more than 5 μm. The thickness of the gate electrode 95 may have a value belonging to at least one range among not less than 0.5 μm and not more than 1 μm, not less than 1 μm and not more than 1.5 μm, not less than 1.5 μm and not more than 2 μm, not less than 2 μm and not more than 2.5 μm, not less than 2.5 μm and not more than 3 μm, not less than 3 μm and not more than 3.5 μm, not less than 3.5 μm and not more than 4 μm, not less than 4 μm and not more than 4.5 μm, and not less than 4.5 μm and not more than 5 μm.

The gate electrode 95 is arranged on the first inorganic film 75 at an interval from the source electrode 85. Specifically, the gate electrode 95 is arranged on the covering portion of the first inorganic film 75 that covers the first surface portion 8.

The gate electrode 95 is arranged in a region at the first connecting surface portion 10A side with respect to the first pad portion 85a and is interposed in a region between the second pad portion 85b and the third pad portion 85c. The gate electrode 95 faces the first pad portion 85a in the second direction Y and faces both the second pad portion 85b and the third pad portion 85c in the first direction X.

The gate electrode 95, in plan view, is formed in a polygonal shape (in this embodiment, a quadrangle shape) having four sides parallel to the peripheral edges of the chip 2. The gate electrode 95 has a planar area less than a planar area of the source electrode 85. The gate electrode 95 has a planar area less than the planar area of the first pad portion 85a. The gate electrode 95 may have a planar area less than the planar area of the second pad portion 85b (the third pad portion 85c).

A proportion at which the gate electrode 95 occupies the first surface portion 8 is preferably not less than 1% and not more than 25%. The proportion of the gate electrode 95 may have a value belonging to any one range among not less than 1% and not more than 5%, not less than 5% and not more than 10%, not less than 10% and not more than 15%, not less than 15% and not more than 20%, and not less than 20% and not more than 25%. The proportion of the gate electrode 95 is preferably not more than 10%.

The gate electrode 95 covers at least the active region 12 in plan view. That is, the gate electrode 95 faces the plurality of gate structures 25 and the plurality of first source structures 30 partially with the first inorganic film 75 interposed therebetween. Also, the gate electrode 95 faces the body region 20, the source region 21, the plurality of first well regions 35, the plurality of second well regions 36, and the plurality of contact regions 37 with the first inorganic film 75 interposed therebetween.

The gate electrode 95 preferably covers the active region 12 at intervals from the first side end region 13 and the second side end region 14. That is, the gate electrode 95 preferably covers the first surface portion 8 at intervals from both end portions of the plurality of gate structures 25. Specifically, the gate electrode 95 is preferably formed at intervals inward from the plurality of gate connection electrodes 78.

In this embodiment, the gate electrode 95 does not have a part that is electrically connected directly to the plurality of gate structures 25. As a matter of course, the gate electrode 95 may be electrically connected to the plurality of gate structures 25 via the plurality of gate openings 82. As a matter of course, portions of the plurality of gate structures 25 positioned directly below the gate electrode 95 may be removed.

The gate electrode 95 may cover either or both of the first terminal region 15 and the third terminal region 17. That is, the gate electrode 95 may face the plurality of dummy gate structures 50 and the plurality of third source structures 55 with the first inorganic film 75 interposed therebetween at the first terminal region 15 side. Also, the gate electrode 95 may face the plurality of fourth source structures 65 at the third terminal region 17 side. As a matter of course, the gate electrode 95 may cover the active region 12 at intervals from both the first terminal region 15 and the third terminal region 17.

The gate electrode 95 includes a second electrode surface 96 and a second electrode side wall 97. The second electrode surface 96 extends along the first inorganic film 75. The second electrode surface 96 is positioned at a height position substantially equal to the first electrode surface 86 of the source electrode 85. As a matter of course, the second electrode surface 96 may be positioned lower than the first electrode surface 86 or may be positioned higher than the first electrode surface 86.

The second electrode side wall 97 is positioned on the first inorganic film 75. The second electrode side wall 97 is inclined obliquely downward from the second electrode surface 96 toward the first inorganic film 75. In this embodiment, the second electrode side wall 97 is inclined obliquely downward in a curved shape from the second electrode surface 96 toward the first inorganic film 75.

In this embodiment, the gate electrode 95 has a laminated structure that includes a second lower electrode film 98 and a second upper electrode film 99 that are laminated in that order from the first inorganic film 75 side. The second lower electrode film 98 is laminated in a film shape as a base film (a barrier film) of the gate electrode 95 on the first inorganic film 75 and forms a lower layer portion of the second electrode side wall 97 of the gate electrode 95.

In this embodiment, the second lower electrode film 98, as with the first lower electrode film 88 of the source electrode 85, has a laminated structure including a Ti film and a TiN film that are laminated in that order from the first inorganic film 75 side. The second lower electrode film 98 may instead have a single layer structure constituted of the Ti film or the TiN film. The second lower electrode film 98 has a thickness less than the thickness (the total thickness) of the first inorganic film 75. The thickness of the second lower electrode film 98 is preferably substantially equal to the thickness of the first lower electrode film 88.

The thickness (the total thickness) of the second lower electrode film 98 may be not less than 0.01 μm and not more than 1 μm. The thickness (the total thickness) of the second lower electrode film 98 may be not more than 0.75 μm, not more than 0.5 μm, not more than 0.25 μm, or not more than 0.1 μm.

As a main body portion of the gate electrode 95, the second upper electrode film 99 is laminated in a film shape on the second lower electrode film 98 and forms the second electrode surface 96 and an upper layer portion of the second electrode side wall 97 of the gate electrode 95. The second upper electrode film 99 includes a conductive material differing from the second lower electrode film 98. The second upper electrode film 99 may include at least one among an Al film, an Al alloy film, a Cu film, and a Cu alloy film. The Al alloy film may include at least one among an AlSi alloy film, an AlCu alloy film, and an AlSiCu alloy film.

The second upper electrode film 99 has a thickness greater than the thickness (the total thickness) of the second lower electrode film 98. The thickness of the second upper electrode film 99 is preferably greater than the thickness of the first inorganic film 75. The thickness of the second upper electrode film 99 is preferably greater than the depth of the gate structure 25. The thickness of the second upper electrode film 99 is preferably greater than the depth of the first source structure 30. The thickness of the second upper electrode film 99 is preferably greater than the depth of the second surface portion 9. The thickness of the second upper electrode film 99 is preferably substantially equal to the thickness of the first upper electrode film 89.

The thickness of the second upper electrode film 99 may be not less than 0.5 μm and not more than 5 μm. The thickness of the second upper electrode film 99 may have a value belonging to at least one range among not less than 0.5 μm and not more than 1 μm, not less than 1 μm and not more than 1.5 μm, not less than 1.5 μm and not more than 2 μm, not less than 2 μm and not more than 2.5 μm, not less than 2.5 μm and not more than 3 μm, not less than 3 μm and not more than 3.5 μm, not less than 3.5 μm and not more than 4 μm, not less than 4 μm and not more than 4.5 μm, and not less than 4.5 μm and not more than 5 μm.

The semiconductor device 1 includes the gate wiring 100 that is arranged in a periphery of the source electrode 85 on the first inorganic film 75. The same potential (the gate potential) as the potential (the gate potential) applied to the gate electrode 95 is applied to the gate wiring 100. The gate wiring 100 may be referred to as a “wiring,” a “second wiring,” a “finger electrode,” a “gate finger,” etc.

The gate wiring 100 has a thickness greater than the depth of the gate structure 25. The thickness of the gate wiring 100 is preferably greater than the depth of the first source structure 30. The thickness of the gate wiring 100 is preferably greater than the depth of the second surface portion 9. The thickness of the gate wiring 100 is preferably substantially equal to the thickness of the source electrode 85 (the gate electrode 95).

As a matter of course, the thickness of the gate wiring 100 may be greater than the thickness of the source electrode 85 (the gate electrode 95) or may be less than the thickness of the source electrode 85 (the gate electrode 95). The thickness of the gate wiring 100 is preferably greater than the thickness (the total thickness) of the first inorganic film 75.

The thickness of the gate wiring 100 may be not less than 0.5 μm and not more than 5 μm. The thickness of the gate wiring 100 may have a value belonging to at least one range among not less than 0.5 μm and not more than 1 μm, not less than 1 μm and not more than 1.5 μm, not less than 1.5 μm and not more than 2 μm, not less than 2 μm and not more than 2.5 μm, not less than 2.5 μm and not more than 3 μm, not less than 3 μm and not more than 3.5 μm, not less than 3.5 μm and not more than 4 μm, not less than 4 μm and not more than 4.5 μm, and not less than 4.5 μm and not more than 5 μm.

The gate wiring 100 has a wiring width that is smaller than an electrode width of the gate electrode 95 and is selectively routed on the first inorganic film 75. The gate wiring 100 is arranged at intervals inward from the peripheral edges of the first surface portion 8. Therefore, the gate wiring 100 is not positioned on the second surface portion 9.

The gate wiring 100 is electrically connected to the gate electrode 95 on the first surface portion 8. Specifically, the gate wiring 100 is connected to an end portion of the gate electrode 95 at the first connecting surface portion 10A side. That is, the gate wiring 100 is formed as a lead-out wiring that is led out from the gate electrode 95. A connection portion of the gate electrode 95 and the gate wiring 100 may be regarded as a portion of the gate electrode 95.

On the first inorganic film 75, the gate wiring 100 is routed in a region between the source electrode 85 and the source wiring 90 at intervals from the source electrode 85 and the source wiring 90. The gate wiring 100 extends in a band shape along the first electrode side wall 87 of the source electrode 85 at an interval from the first electrode side wall 87.

The gate wiring 100 preferably extends in a band shape along at least either of the third connecting surface portion 10C and the fourth connecting surface portion 10D. In this embodiment, the gate wiring 100 is formed in an annular shape with ends (specifically, a quadrangle annular shape with ends) extending along the first to fourth connecting surface portions 10A to 10D so as to surround the gate electrode 95.

Specifically, the gate wiring 100 has, in plan view, a portion extending in the first direction X along the first connecting surface portion 10A, a portion extending in the second direction Y along the second connecting surface portion 10B, a portion extending in the second direction Y along the third connecting surface portion 10C, and a portion extending in the second direction Y along the fourth connecting surface portion 10D.

In the portion extending along the second connecting surface portion 10B, the gate wiring 100 has a pair of open ends that allow the source wiring 90 to pass through. The gate wiring 100 may have an edge portion connecting, in an arcuate shape (preferably, a quarter arcuate shape), a portion extending in the first direction X and a portion extending in the second direction Y.

The gate wiring 100 intersects (specifically, is orthogonal to) both end portions of the plurality of gate structures 25 at the portion extending along the third connecting surface portion 10C and the portion extending along the fourth connecting surface portion 10D. The gate wiring 100 enters into the plurality of gate openings 82 from above the first inorganic film 75 and is electrically connected to the end portions (both end portions) of the plurality of gate structures 25 inside the plurality of gate openings 82.

Specifically, the gate wiring 100 is mechanically and electrically connected to the plurality of gate connection electrodes 78 inside the plurality of gate openings 82 and is electrically connected to the plurality of gate structures 25 via the plurality of gate connection electrodes 78. The gate potential applied to the gate electrode 95 is thereby applied to the plurality of gate structures 25 via the gate wiring 100.

The gate wiring 100 may cover the active region 12 at intervals from the first side end region 13 and the second side end region 14. That is, the gate wiring 100 may be formed at intervals from the plurality of second source structures 40. As a matter of course, the gate wiring 100 may have a portion facing the plurality of second source structures 40 with the first inorganic film 75 interposed therebetween.

The gate wiring 100 may cover at least one among the first terminal region 15, the second terminal region 16, the third terminal region 17, and the fourth terminal region 18. The gate electrode 95 may face the plurality of dummy gate structures 50 and the plurality of third source structures 55 with the first inorganic film 75 interposed therebetween at the first terminal region 15 (the second terminal region 16) side.

The gate electrode 95 may face the plurality of fourth source structures 65 with the first inorganic film 75 interposed therebetween at the third terminal region 17 (the fourth terminal region 18) side. As a matter of course, the gate electrode 95 may cover the active region 12 at intervals from the first terminal region 15, the second terminal region 16, the third terminal region 17, and the fourth terminal region 18.

The gate wiring 100 includes a second wiring surface 101, the second inner side wall 102 at an inner side (the source electrode 85 side), and a second outer side wall 103 at an outer side (the peripheral edge side of the chip 2). The second inner side wall 102 may be referred to as a “first wiring side wall” and the second inner side wall 102 may be referred to as a “second wiring side wall.”

The second wiring surface 101 is positioned at a height position substantially equal to the first electrode surface 86 of the source electrode 85. The second wiring surface 101 is positioned at a height position substantially equal to the portion of the first wiring surface 91 of the source wiring 90 positioned on the first surface portion 8.

The second inner side wall 102 is positioned, at an interval from the first electrode side wall 87 of the source electrode 85, on the covering portion of the first inorganic film 75 that covers the first surface portion 8. The second inner side wall 102 is inclined obliquely downward from the second wiring surface 101 toward the first inorganic film 75. In this embodiment, the second inner side wall 102 is inclined obliquely downward in a curved shape from the second wiring surface 101 toward the first inorganic film 75.

The second outer side wall 103 is positioned, at an interval from the first inner side wall 92 of the source wiring 90, on the covering portion of the first inorganic film 75 that covers the first surface portion 8. The second outer side wall 103 is inclined obliquely downward from the second wiring surface 101 toward the first inorganic film 75. In this embodiment, the second outer side wall 103 is inclined obliquely downward in a curved shape from the second wiring surface 101 toward the first inorganic film 75.

As with the gate electrode 95, the gate wiring 100 has the laminated structure including the second lower electrode film 98 and the second upper electrode film 99. The second lower electrode film 98 is laminated in a film shape as a base film (a barrier film) of the gate wiring 100 on the first inorganic film 75 and forms lower layer portions of the second inner side wall 102 and the second outer side wall 103 of the gate wiring 100.

The second lower electrode film 98 entirely covers, in a film shape, a region of the first inorganic film 75 in which the plurality of gate openings 82 are formed and enters into the plurality of gate openings 82 from above the first inorganic film 75. Inside the plurality of gate openings 82, the second lower electrode film 98 is mechanically and electrically connected to the plurality of gate structures 25 (the plurality of gate connection electrodes 78).

As a main body portion of the gate wiring 100, the second upper electrode film 99 is laminated in a film shape on the second lower electrode film 98 and forms the second wiring surface 101, an upper layer portion of the second inner side wall 102, and an upper layer portion of the second outer side wall 103 of the gate wiring 100.

The second upper electrode film 99 entirely covers, in a film shape, the region of the first inorganic film 75 in which the plurality of gate openings 82 are formed and refills the plurality of gate openings 82. Inside the plurality of gate openings 82, the second upper electrode film 99 is electrically connected to the plurality of gate structures 25 (the plurality of gate connection electrodes 78) via the second lower electrode film 98.

The semiconductor device 1 includes the second inorganic film 110 with an insulating property that selectively covers the first inorganic film 75. The second inorganic film 110 may be referred to as an “inorganic insulating film (a second inorganic insulating film),” an “upper insulating film,” a “passivation film,” etc. The second inorganic film 110 may include at least one among a silicon oxide film, a silicon nitride film, and a silicon oxynitride film.

The second inorganic film 110 preferably includes an insulating material differing from the insulating material of the first inorganic film 75. Specifically, the second inorganic film 110 preferably includes an insulating material differing from the insulating material of the upper inorganic film 77. In this embodiment, the second inorganic film 110 has a single layer structure constituted of a silicon nitride film.

The second inorganic film 110 preferably has a thickness less than the thickness of the source electrode 85 (the gate electrode 95). The thickness of the second inorganic film 110 is preferably greater than thickness of the lower inorganic film 76. The thickness of the second inorganic film 110 is preferably greater than the thickness of the upper inorganic film 77. The thickness of the second inorganic film 110 is preferably greater than the thickness (the total thickness) of the first inorganic film 75.

As a matter of course, the thickness of the second inorganic film 110 may be less than the thickness (the total thickness) of the first inorganic film 75. The thickness of the second inorganic film 110 may be less than the thickness of the upper inorganic film 77. The thickness of the second inorganic film 110 may be less than the thickness of the lower inorganic film 76.

The thickness of the second inorganic film 110 may be greater than the depth of the second surface portion 9 or may be less than the depth of the second surface portion 9. The thickness of the second inorganic film 110 may be greater than the depth of the gate structure 25 or may be less than the depth of the gate structure 25. The thickness of the second inorganic film 110 may be greater than the depth of the first source structure 30 or may be less than the depth of the first source structure 30.

The thickness of the second inorganic film 110 may be not less than 0.01 μm and not more than 5 μm. The thickness of the second inorganic film 110 may have a value belonging to at least one range among not less than 0.01 μm and not more than 0.1 μm, not less than 0.1 μm and not more than 0.5 μm, not less than 0.5 μm and not more than 1 μm, not less than 1 μm and not more than 1.5 μm, not less than 1.5 μm and not more than 2 μm, not less than 2 μm and not more than 2.5 μm, not less than 2.5 μm and not more than 3 μm, not less than 3 μm and not more than 3.5 μm, not less than 3.5 μm and not more than 4 μm, not less than 4 μm and not more than 4.5 μm, and not less than 4.5 μm and not more than 5 μm. The thickness of the second inorganic film 110 is preferably not less than 0.1 μm and not more than 2 μm.

The second inorganic film 110 selectively covers the source electrode 85, the source wiring 90, the gate electrode 95, and the gate wiring 100 on the first inorganic film 75. Specifically, the second inorganic film 110 has a first inner covering portion 111, a second inner covering portion 112, an outer covering portion 113, and a removed portion 114.

The first inner covering portion 111 selectively covers the source electrode 85. Specifically, the first inner covering portion 111 covers the first electrode surface 86 of the source electrode 85 in a film shape so as to expose at least a portion of the first electrode side wall 87 of the source electrode 85. In this embodiment, the first inner covering portion 111 exposes an entirety of the first electrode side wall 87. Specifically, the first inner covering portion 111 covers the first electrode surface 86 at an interval from the first electrode side wall 87 and exposes a peripheral edge portion of the first electrode surface 86 in addition to the first electrode side wall 87.

The first inner covering portion 111 extends flatly on the first electrode surface 86. The first inner covering portion 111 covers a peripheral edge portion of the first electrode surface 86 (the source electrode 85) and exposes an inner side of the first electrode surface 86 (the source electrode 85). On the peripheral edge portion of the first electrode surface 86, the first inner covering portion 111 extends in a band shape along the first electrode side wall 87. The first inner covering portion 111 includes a portion extending along the first pad portion 85a, a portion extending along the second pad portion 85b, and a portion extending along the third pad portion 85c.

In this embodiment, the first inner covering portion 111 has an extension portion 115 that is led out from above the source electrode 85 to above the connection portion of the source electrode 85 and the source wiring 90. In this embodiment, the extension portion 115 is formed wider than other portions. As a matter of course, the extension portion 115 may have a width substantially equal to the other portions.

The extension portion 115 covers the connection portion of the source electrode 85 and the source wiring 90 at intervals from the first electrode side wall 87 of the source electrode 85 and the first outer side wall 93 of the source wiring 90. The extension portion 115 preferably covers the connection portion of the source electrode 85 and the source wiring 90 at an interval to the first surface portion 8 side from the second surface portion 9. As a matter of course, the extension portion 115 may have a portion that crosses the second connecting surface portion 10B and covers the source wiring 90.

In this embodiment, the first inner covering portion 111 is formed in an annular shape surrounding an inner portion of the first electrode surface 86 in plan view. The first inner covering portion 111 is formed in a polygonal annular shape having four sides parallel to the peripheral edges of the chip 2 in plan view. Specifically, the first inner covering portion 111 is formed in the polygonal annular shape (a U-shaped annular shape) conforming to a planar shape of the first electrode surface 86 in plan view.

The first inner covering portion 111 demarcates a first pad opening 116 that exposes the inner portion of the first electrode surface 86. The first pad opening 116 is demarcated in a polygonal shape having four sides parallel to the peripheral edges of the chip 2 in plan view. In this embodiment, the first pad opening 116 is demarcated in a polygonal shape (a U-shape) conforming to the planar shape of the first electrode surface 86 in plan view.

The first inner covering portion 111 may face the active region 12 with the first inorganic film 75 and the source electrode 85 interposed therebetween. That is, the first inner covering portion 111 may face one or a plurality of the gate structures 25 and/or one or a plurality of the first source structures 30 with the first inorganic film 75 and the source electrode 85 interposed therebetween.

The first inner covering portion 111 may face either or both of the first terminal region 15 and the second terminal region 16 with the first inorganic film 75 and the source electrode 85 interposed therebetween. That is, the first inner covering portion 111 may face one or a plurality of the dummy gate structures 50 and/or one or a plurality of the third source structures 55 with the first inorganic film 75 and the source electrode 85 interposed therebetween.

The first inner covering portion 111 may face either or both of the third terminal region 17 and the fourth terminal region 18 with the first inorganic film 75 and the source electrode 85 interposed therebetween. That is, the first inner covering portion 111 may face one or a plurality of the fourth source structures 65 with the first inorganic film 75 and the source electrode 85 interposed therebetween.

The first inner covering portion 111 preferably has a width greater than the thickness of the source electrode 85. As a matter of course, the width of the first inner covering portion 111 may be less than the thickness of the source electrode 85. The width of the first inner covering portion 111 may be not less than 1 μm and not more than 100 μm.

The width of the first inner covering portion 111 may have a value belonging to at least one range among not less than 1 μm and not more than 5 μm, not less than 5 μm and not more than 10 μm, not less than 10 μm and not more than 20 μm, not less than 20 μm and not more than 30 μm, not less than 30 μm and not more than 40 μm, not less than 40 μm and not more than 50 μm, not less than 50 μm and not more than 60 μm, not less than 60 μm and not more than 70 μm, not less than 70 μm and not more than 80 μm, not less than 80 μm and not more than 90 μm, and not less than 90 μm and not more than 100 μm.

The first inner covering portion 111 is preferably formed at an interval greater than the thickness of the source electrode 85 from the first electrode side wall 87. As a matter of course, the interval of the first inner covering portion 111 may be less than the thickness of the source electrode 85. The interval of the first inner covering portion 111 may be not less than 0.1 μm and not more than 100 μm.

The interval of the first inner covering portion 111 may have a value belonging to at least one range among not less than 0.1 μm and not more than 1 μm, not less than 1 μm and not more than 5 μm, not less than 5 μm and not more than 10 μm, not less than 10 μm and not more than 20 μm, not less than 20 μm and not more than 30 μm, not less than 30 μm and not more than 40 μm, not less than 40 μm and not more than 50 μm, not less than 50 μm and not more than 60 μm, not less than 60 μm and not more than 70 μm, not less than 70 μm and not more than 80 μm, not less than 80 μm and not more than 90 μm, and not less than 90 μm and not more than 100 μm.

The second inner covering portion 112 selectively covers the gate electrode 95. Specifically, the second inner covering portion 112 covers, in a film shape, the second electrode surface 96 of the gate electrode 95 so as to expose at least a portion of the second electrode side wall 97 of the gate electrode 95. In this embodiment, the second inner covering portion 112 exposes an entirety of the second electrode side wall 97. Specifically, the second inner covering portion 112 covers the second electrode surface 96 at an interval from the second electrode side wall 97 and exposes a peripheral edge portion of the second electrode surface 96 in addition to the second electrode side wall 97.

The second inner covering portion 112 extends flatly on the second electrode surface 96. The second inner covering portion 112 covers a peripheral edge portion of the second electrode surface 96 (the gate electrode 95) and exposes an inner side of the second electrode surface 96 (the gate electrode 95). On the peripheral edge portion of the second electrode surface 96, the second inner covering portion 112 extends in a band shape along the second electrode side wall 97.

In this embodiment, the second inner covering portion 112 is formed in an annular shape surrounding an inner portion of the second electrode surface 96 in plan view. The second inner covering portion 112 is formed in a polygonal annular shape (in this embodiment, a quadrangle annular shape) having four sides parallel to the peripheral edges of the chip 2 in plan view. Specifically, the second inner covering portion 112 is formed in the polygonal annular shape (specifically, the quadrangle annular shape) conforming to a planar shape of the second electrode surface 96 in plan view.

The second inner covering portion 112 demarcates a second pad opening 117 that exposes the inner portion of the second electrode surface 96. The second pad opening 117 is demarcated in a polygonal shape (in this embodiment, a quadrangle shape) having four sides parallel to the peripheral edges of the chip 2 in plan view.

The second inner covering portion 112 may face the active region 12 with the first inorganic film 75 and the gate electrode 95 interposed therebetween. That is, the second inner covering portion 112 may face one or a plurality of the gate structures 25 and/or one or a plurality of the first source structures 30 with the first inorganic film 75 and the gate electrode 95 interposed therebetween.

The second inner covering portion 112 may face the first terminal region 15 with the first inorganic film 75 and the gate electrode 95 interposed therebetween. That is, the second inner covering portion 112 may face one or a plurality of the dummy gate structures 50 and/or one or a plurality of the third source structures 55 with the first inorganic film 75 and the gate electrode 95 interposed therebetween.

The second inner covering portion 112 may face the third terminal region 17 with the first inorganic film 75 and the gate electrode 95 interposed therebetween. That is, the second inner covering portion 112 may face one or a plurality of the fourth source structures 65 with the first inorganic film 75 and the gate electrode 95 interposed therebetween.

The second inner covering portion 112 preferably has a width greater than the thickness of the gate electrode 95. As a matter of course, the width of the second inner covering portion 112 may be less than the thickness of the gate electrode 95. The width of the second inner covering portion 112 may be substantially equal to the width of the first inner covering portion 111. As a matter of course, the width of the second inner covering portion 112 may be less than the width of the first inner covering portion 111 or may be greater than the width of the first inner covering portion 111. The width of the second inner covering portion 112 may be not less than 1 μm and not more than 100 μm.

The width of the second inner covering portion 112 may have a value belonging to at least one range among not less than 1 μm and not more than 5 μm, not less than 5 μm and not more than 10 μm, not less than 10 μm and not more than 20 μm, not less than 20 μm and not more than 30 μm, not less than 30 μm and not more than 40 μm, not less than 40 μm and not more than 50 μm, not less than 50 μm and not more than 60 μm, not less than 60 μm and not more than 70 μm, not less than 70 μm and not more than 80 μm, not less than 80 μm and not more than 90 μm, and not less than 90 μm and not more than 100 μm.

The second inner covering portion 112 is preferably formed at an interval greater than the thickness of the gate electrode 95 from the second electrode side wall 97. As a matter of course, the interval of the second inner covering portion 112 may be less than the thickness of the gate electrode 95. The interval of the second inner covering portion 112 may be substantially equal to the interval of the first inner covering portion 111. The interval of the second inner covering portion 112 may be less than the interval of the first inner covering portion 111 or may be greater than the interval of the first inner covering portion 111. The interval of the second inner covering portion 112 may be not less than 0.1 μm and not more than 100 μm.

The interval of the second inner covering portion 112 may have a value belonging to at least one range among not less than 0.1 μm and not more than 1 μm, not less than 1 μm and not more than 5 μm, not less than 5 μm and not more than 10 μm, not less than 10 μm and not more than 20 μm, not less than 20 μm and not more than 30 μm, not less than 30 μm and not more than 40 μm, not less than 40 μm and not more than 50 μm, not less than 50 μm and not more than 60 μm, not less than 60 μm and not more than 70 μm, not less than 70 μm and not more than 80 μm, not less than 80 μm and not more than 90 μm, and not less than 90 μm and not more than 100 μm.

The outer covering portion 113 selectively covers the first inorganic film 75 at intervals from the first inner covering portion 111 and the second inner covering portion 112. Specifically, the outer covering portion 113 is formed on a covering portion of the first inorganic film 75 that covers the second surface portion 9. The outer covering portion 113 extends in a band shape along the first surface portion 8 in plan view. The outer covering portion 113 is formed in an annular shape (in this embodiment, a quadrangle annular shape) surrounding the first surface portion 8 in plan view.

At the second surface portion 9 side, the outer covering portion 113 covers the outer well region 70 and the plurality of field regions 72 with the first inorganic film 75 interposed therebetween. At the second surface portion 9 side, the outer covering portion 113 enters into the anchor opening 83 from above the first inorganic film 75 and is mechanically connected to the second surface portion 9 (the second semiconductor region 7) inside the anchor opening 83.

The outer covering portion 113 extends in a film shape along the second surface portion 9 inside the anchor opening 83. In a covering portion that covers the anchor opening 83, the outer covering portion 113 demarcates an anchor recess 118 that is recessed toward the anchor opening 83.

When a plurality of anchor openings 83 are formed in the first inorganic film 75, the outer covering portion 113 demarcates a plurality of anchor recesses 118. The anchor recess 118 has a planar shape substantially similar to a planar shape of the anchor opening 83. The anchor recess 118 extends in a band shape (in this embodiment, an annular shape) extending along the anchor opening 83 in plan view.

In this embodiment, the outer covering portion 113 is led out from the anchor opening 83 toward the peripheral edges of the second surface portion 9 (toward the first to fourth side surfaces 5A to 5D). The outer covering portion 113 is formed at intervals inward from the peripheral edges of the second surface portion 9 and exposes the first inorganic film 75 from the peripheral edges of the second surface portion 9.

The outer covering portion 113 covers at least a portion of the source wiring 90 at the second surface portion 9 side. The outer covering portion 113 preferably covers at least a portion of the first outer side wall 93 of the source wiring 90. In this embodiment, the outer covering portion 113 covers an entirety of the source wiring 90 in sectional view.

The outer covering portion 113 covers the first wiring surface 91 of the source wiring 90 in a film shape and extends flatly on the first wiring surface 91 in conformance to a gradient of the first wiring surface 91. The outer covering portion 113 covers the first inner side wall 92 of the source wiring 90 in a film shape and has an inclined surface extending in conformance to an inclined surface of the first inner side wall 92. The outer covering portion 113 covers the first outer side wall 93 of the source wiring 90 in a film shape and has an inclined surface extending in conformance to an inclined surface of the first outer side wall 93.

In this embodiment, the outer covering portion 113 covers an entirety of the source wiring 90 in plan view with the exception of the connection portion of the source electrode 85 and the source wiring 90. At the connection portion of the source electrode 85 and the source wiring 90, the outer covering portion 113 exposes the first outer side wall 93 of the source wiring 90. A stress generated in the source electrode 85 is thereby suppressed from being applied to the second inorganic film 110 via the source wiring 90.

The outer covering portion 113 is led out from the second surface portion 9 side to the first surface portion 8 side via the source wiring 90. That is, the outer covering portion 113 has a portion facing the outer opening 81 with the source wiring 90 interposed therebetween. Also, the outer covering portion 113 has a portion facing the side wall wiring 79 with the first inorganic film 75 (upper inorganic film 77) and the source wiring 90 interposed therebetween.

At the first surface portion 8 side, the outer covering portion 113 covers at least a portion of the gate wiring 100. The outer covering portion 113 preferably covers at least a portion of the second outer side wall 103 of the gate wiring 100. In this embodiment, the outer covering portion 113 covers an entirety of the gate wiring 100 in sectional view.

The outer covering portion 113 covers the second wiring surface 101 of the gate wiring 100 in a film shape and extends flatly on the second wiring surface 101 in conformance to a gradient of the second wiring surface 101. The outer covering portion 113 covers the second inner side wall 102 of the gate wiring 100 in a film shape and has an inclined surface extending in conformance to an inclined surface of the second inner side wall 102. The outer covering portion 113 covers the second outer side wall 103 of the gate wiring 100 in a film shape and has an inclined surface extending in conformance to an inclined surface of the second outer side wall 103.

In this embodiment, the outer covering portion 113 covers the entirety of the gate wiring 100 in plan view with the exception of the connection portion of the gate electrode 95 and the gate wiring 100. At the connection portion of the gate electrode 95 and the gate wiring 100, the outer covering portion 113 exposes the second outer side wall 103 of the gate wiring 100. A stress generated in the gate electrode 95 is thereby suppressed from being applied to the second inorganic film 110 via the gate wiring 100.

At the first surface portion 8 side, the outer covering portion 113 covers the first inorganic film 75 at intervals from the first inner covering portion 111 and the second inner covering portion 112. The outer covering portion 113 covers the first inorganic film 75 so as to expose at least a portion of the first electrode side wall 87 of the source electrode 85.

In this embodiment, the outer covering portion 113 covers the first inorganic film 75 at an interval from the first electrode side wall 87 and exposes the entirety of the first electrode side wall 87. In this embodiment, the outer covering portion 113 has an inner edge portion positioned between the first electrode side wall 87 of the source electrode 85 and the second inner side wall 102 of the gate wiring 100. The inner edge portion of the outer covering portion 113 extends along the first electrode side wall 87 at an interval from the first electrode side wall 87.

The outer covering portion 113 covers the first inorganic film 75 so as to expose at least a portion of the second electrode side wall 97 of the gate electrode 95. In this embodiment, the outer covering portion 113 covers the first inorganic film 75 at an interval from the second electrode side wall 97 and exposes the entirety of the second electrode side wall 97.

That is, the outer covering portion 113 surrounds both the source electrode 85 and the gate electrode 95 entirely at intervals from the source electrode 85 and the gate electrode 95 in plan view. The inner edge portion of the outer covering portion 113 is positioned between the first inner side wall 92 of the source wiring 90 and the second electrode side wall 97 of the gate electrode 95. The inner edge portion of the outer covering portion 113 extends along the second electrode side wall 97 at an interval from the second electrode side wall 97.

The outer covering portion 113 may face the active region 12 with the first inorganic film 75 interposed therebetween. That is, the outer covering portion 113 may face one or a plurality of the gate structures 25 and/or one or a plurality of the first source structures 30 with the first inorganic film 75 interposed therebetween.

The outer covering portion 113 may face either or both of the first side end region 13 and the second side end region 14 with the first inorganic film 75 interposed therebetween. That is, the outer covering portion 113 may face one or a plurality of the first source structures 30 and/or one or a plurality of the second source structures 40 with the first inorganic film 75 interposed therebetween.

The outer covering portion 113 may face either or both of the first terminal region 15 and the second terminal region 16 with the first inorganic film 75 interposed therebetween. That is, the outer covering portion 113 may face one or a plurality of the dummy gate structures 50 and/or one or a plurality of the third source structures 55 with the first inorganic film 75 interposed therebetween.

The outer covering portion 113 may face either or both of the third terminal region 17 and the fourth terminal region 18 with the first inorganic film 75 interposed therebetween. That is, the outer covering portion 113 may face one or a plurality of the fourth source structures 65 with the first inorganic film 75 interposed therebetween.

The removed portion 114 includes a first removed portion 114a, a second removed portion 114b, and a third removed portion 114c. The first removed portion 114a is demarcated in a region between the first inner covering portion 111 and the outer covering portion 113 and exposes the first electrode side wall 87 of the source electrode 85. In this embodiment, the first removed portion 114a extends in a band shape along the first electrode side wall 87 and exposes a peripheral edge portion of the first electrode surface 86, the first electrode side wall 87, and the first inorganic film 75 between the source electrode 85 and the gate wiring 100.

The second removed portion 114b is demarcated in a region between the second inner covering portion 112 and the outer covering portion 113 and is in communication with the first removed portion 114a. The second removed portion 114b exposes the second electrode side wall 97 of the gate electrode 95. In this embodiment, the second removed portion 114b extends in a band shape along the second electrode side wall 97 and exposes a peripheral edge portion of the second electrode surface 96, the second electrode side wall 97, and the first inorganic film 75 between the source wiring 90 and the gate electrode 95.

The third removed portion 114c is demarcated in a region between the first inner covering portion 111 and the second inner covering portion 112 and is communication with the first removed portion 114a and the second removed portion 114b. The third removed portion 114c exposes the first electrode side wall 87 of the source electrode 85 and the second electrode side wall 97 of the gate electrode 95.

In this embodiment, the third removed portion 114c extends in a band shape along the first electrode side wall 87 and the second electrode side wall 97 and exposes a peripheral edge portion of the first electrode surface 86, the first electrode side wall 87, a peripheral edge portion of the second electrode surface 96, the second electrode side wall 97, and the first inorganic film 75 between the source electrode 85 and the gate electrode 95.

The semiconductor device 1 includes an organic film 120 with an insulating property that selectively covers the second inorganic film 110. The organic film 120 may be referred to as an “organic insulating film,” a “resin film,” etc. The organic film 120 preferably contains a transparent resin or a resin having translucency.

The organic film 120 preferably contains a photosensitive resin. The photosensitive resin may be of a negative type or a positive type. The organic film 120 may include at least one among a polyimide film, a polyamide film, and a polybenzoxazole film.

The organic film 120 may have a thickness greater than the depth of the gate structure 25. The thickness of the organic film 120 may be greater than the depth of the first source structure 30. The thickness of the organic film 120 may be greater than the thickness (the total thickness) of the first inorganic film 75. The thickness of the organic film 120 may be greater than the thickness of the source electrode 85 (the gate electrode 95).

The thickness of the organic film 120 may be greater than the thickness of the second inorganic film 110. The thickness of the organic film 120 is preferably less than a thickness of the chip 2. The thickness of the organic film 120 may be greater than the thickness of the second semiconductor region 7 or may be less than the thickness of the second semiconductor region 7.

The thickness of the organic film 120 may be not less than 1 μm and not more than 25 μm. The thickness of the organic film 120 may have a value belonging to at least one range among not less than 1 μm and not more than 5 μm, not less than 5 μm and not more than 10 μm, not less than 10 μm and not more than 15 μm, not less than 15 μm and not more than 20 μm, and not less than 20 μm and not more than 25 μm.

The organic film 120 crosses the first to fourth connecting surface portions 10A to 10D from above the first surface portion 8 and covers the second surface portion 9. At the first surface portion 8 side, the organic film 120 fills the removed portion 114 of the second inorganic film 110 and directly covers the first inner covering portion 111, the second inner covering portion 112, and the outer covering portion 113 of the second inorganic film 110.

The organic film 120 has a portion that extends across the first inner covering portion 111 and the outer covering portion 113 and fills the region (that is, the first removed portion 114a) between the first inner covering portion 111 and the outer covering portion 113. The organic film 120 directly covers the first electrode side wall 87 of the source electrode 85 in the first removed portion 114a.

In this embodiment, the organic film 120 directly covers the peripheral edge portion of the first electrode surface 86 and the first electrode side wall 87 in the first removed portion 114a. In the first removed portion 114a, the organic film 120 directly covers a portion of the first inorganic film 75 that is exposed from between the first electrode side wall 87 of the source electrode 85 and the outer covering portion 113 (the gate wiring 100).

The organic film 120 has a portion that extends across the second inner covering portion 112 and the outer covering portion 113 and fills the region (that is, the second removed portion 114b) between the second inner covering portion 112 and the outer covering portion 113. The organic film 120 directly covers the second electrode side wall 97 of the gate electrode 95 in the second removed portion 114b.

In this embodiment, the organic film 120 directly covers the peripheral edge portion of the second electrode surface 96 and the second electrode side wall 97 in the second removed portion 114b. In the second removed portion 114b, the organic film 120 directly covers a portion of the first inorganic film 75 that is exposed from between the second electrode side wall 97 of the gate electrode 95 and the outer covering portion 113 (the source wiring 90).

The organic film 120 has a portion that extends across the first inner covering portion 111 and the second inner covering portion 112 and fills the region (that is, the third removed portion 114c) between the first inner covering portion 111 and the second inner covering portion 112. The organic film 120 directly covers both the first electrode side wall 87 of the source electrode 85 and the second electrode side wall 97 of the gate electrode 95 in the third removed portion 114c.

In this embodiment, the organic film 120 directly covers the peripheral edge portion of the first electrode surface 86, the first electrode side wall 87, the peripheral edge portion of the second electrode surface 96, and the second electrode side wall 97 in the third removed portion 114c. In the third removed portion 114c, the organic film 120 directly covers a portion of the first inorganic film 75 that is exposed from between the first electrode side wall 87 of the source electrode 85 and the second electrode side wall 97 of the gate electrode 95.

The organic film 120 covers the first inner covering portion 111 along its entire periphery and demarcates a first upper pad opening 121 that exposes an inner portion of the first electrode surface 86 (see FIG. 1 to FIG. 3). Specifically, the organic film 120 covers the first inner covering portion 111 at an interval to an outer edge (an outer wall) side from an inner edge (an inner wall) of the first inner covering portion 111 and exposes the inner edge of the first inner covering portion 111. That is, a wall surface of the first upper pad opening 121 is positioned further to the first electrode side wall 87 side than a wall surface of the first pad opening 116 and faces the first electrode surface 86 with the first inner covering portion 111 interposed therebetween.

The organic film 120 covers the second inner covering portion 112 along its entire periphery and demarcates a second upper pad opening 122 that exposes an inner portion of the second electrode surface 96 (see FIG. 1 to FIG. 3). Specifically, the organic film 120 covers the second inner covering portion 112 at an interval to an outer edge (an outer wall) side from an inner edge (an inner wall) of the second inner covering portion 112 and exposes the inner edge of the second inner covering portion 112. That is, a wall surface of the second upper pad opening 122 is positioned further to the second electrode side wall 97 side than a wall surface of the second pad opening 117 and faces the second electrode surface 96 with the second inner covering portion 112 interposed therebetween.

The organic film 120 is led out from above the source electrode 85 and the gate electrode 95 to the gate wiring 100 side and covers at least a portion of the gate wiring 100 with the outer covering portion 113 interposed therebetween. The organic film 120 preferably covers the second outer side wall 103 of the gate wiring 100 with the outer covering portion 113 interposed therebetween.

In this embodiment, the organic film 120 covers the entirety of the gate wiring 100 with the outer covering portion 113 interposed therebetween in sectional view. That is, in sectional view, the organic film 120 has a portion that covers the second wiring surface 101 with the outer covering portion 113 interposed therebetween, a portion that covers the second inner side wall 102 with the outer covering portion 113 interposed therebetween, and a portion that covers the second outer side wall 103 with the outer covering portion 113 interposed therebetween.

In this embodiment, the organic film 120 has, at the connection portion of the gate electrode 95 and the gate wiring 100, a portion that directly covers a portion of the second outer side wall 103 of the gate wiring 100 exposed from the second inner covering portion 112 and the outer covering portion 113. The organic film 120 also covers the second wiring surface 101 of the gate wiring 100 at the connection portion of the gate electrode 95 and the gate wiring 100.

The organic film 120 is led out from above the gate wiring 100 to the source wiring 90 side and covers at least a portion of the source wiring 90 with the outer covering portion 113 interposed therebetween. The organic film 120 has a portion that directly covers the outer covering portion 113 in a region between the source wiring 90 and the gate wiring 100.

The organic film 120 preferably covers the first outer side wall 93 of the source wiring 90 with the outer covering portion 113 interposed therebetween. In this embodiment, the organic film 120 covers the entirety of the source wiring 90 with the outer covering portion 113 interposed therebetween in sectional view. That is, in sectional view, the organic film 120 has a portion that covers the first wiring surface 91 with the outer covering portion 113 interposed therebetween, a portion that covers the first inner side wall 92 with the outer covering portion 113 interposed therebetween, and a portion that covers the first outer side wall 93 with the outer covering portion 113 interposed therebetween.

In this embodiment, the organic film 120 has, at the connection portion of the source electrode 85 and the source wiring 90, a portion that directly covers a portion of the first outer side wall 93 of the source wiring 90 exposed from the first inner covering portion 111 and the outer covering portion 113. In this embodiment, the organic film 120 also covers the first wiring surface 91 of the source wiring 90 at the connection portion of the source electrode 85 and the source wiring 90.

The organic film 120 is led out from the first surface portion 8 side to the second surface portion 9 side via the source wiring 90. That is, the organic film 120 has a portion facing the outer opening 81 with the source wiring 90 interposed therebetween. Also, the organic film 120 has a portion facing the side wall wiring 79 with the source wiring 90 interposed therebetween.

At the second surface portion 9 side, the organic film 120 covers the outer well region 70 and the plurality of field regions 72 with the first inorganic film 75 and the second inorganic film 110 interposed therebetween. At a peripheral edge portion of the second surface portion 9, the organic film 120 covers the anchor opening 83 with the second inorganic film 110 interposed therebetween. The organic film 120 is engaged with the anchor recess 118 of the second inorganic film 110 (the anchor opening 83 of the first inorganic film 75).

In this embodiment, the organic film 120 is led out from the anchor opening 83 toward the peripheral edges of the second surface portion 9 (from the first to fourth side surfaces 5A to 5D). The organic film 120 is formed at an interval inward from the peripheral edges of the second surface portion 9 and exposes the first inorganic film 75 from the peripheral edge portion of the second surface portion 9. In this embodiment, the organic film 120 covers the outer covering portion 113 at an interval inward from an outer edge (an outer wall) of the outer covering portion 113 and exposes the outer edge of the outer covering portion 113.

The semiconductor device 1 includes a drain electrode 125 that covers the second main surface 4. The drain electrode 125 is a terminal electrode to which the drain potential is applied from the exterior. The drain electrode 125 may be referred to as an “electrode,” a “third electrode,” a “third pad electrode,” a “third main surface electrode,” a “third terminal electrode,” a “drain pad electrode,” etc.

The drain electrode 125 is electrically connected to the first semiconductor region 6. The drain electrode 125 may cover an entirety of the second main surface 4 so as to be continuous to the peripheral edges of the second main surface 4 (to the first to fourth side surfaces 5A to 5D). The drain electrode 125 may cover the second main surface 4 partially so as to expose a peripheral edge portion of the second main surface 4.

A breakdown voltage applicable between the source electrode 85 and the drain electrode 125 (between the first main surface 3 and the second main surface 4) may be not less than 500 V and not more than 3000 V. The breakdown voltage may have a value belonging to at least one range among not less than 500 V and not more than 1000 V, not less than 1000 V and not more than 1500 V, not less than 1500 V and not more than 2000 V, not less than 2000 V and not more than 2500 V, and not less than 2500 V and not more than 3000 V.

As described above, the semiconductor device 1 (the electronic component) includes the first inorganic film 75 (the covered object) with the insulating property, the source electrode 85 (the electrode), the source wiring 90 (the wiring), the second inorganic film 110 (the inorganic film) with the insulating property, and the organic film 120 with the insulating property. The source electrode 85 is arranged on the first inorganic film 75 and has the first electrode side wall 87 on the first inorganic film 75. The source wiring 90 is arranged on the first inorganic film 75 in a periphery of the source electrode 85.

The second inorganic film 110 has the first inner covering portion 111 that covers the source electrode 85 so as to expose the first electrode side wall 87 and the outer covering portion 113 that covers the source wiring 90 at an interval from the first inner covering portion 111. The organic film 120 extends across the first inner covering portion 111 and the outer covering portion 113 and covers the source electrode 85 between the first inner covering portion 111 and the outer covering portion 113.

According to this arrangement, the semiconductor device 1 having a novel layout is provided. The semiconductor device 1 is used under various environments according to intended use and therefore, durability suited for various usage environment conditions is required of the semiconductor device 1.

For example, when the semiconductor device 1 is installed in a vehicle, etc., having a motor as a drive source such as a hybrid vehicle, an electric vehicle, a fuel cell vehicle, etc., excellent durability suitable to the usage environment conditions of these is required. The durability of the semiconductor device 1 is evaluated, for example, by a temperature humidity bias test. In the temperature humidity bias test, electrical operation of the semiconductor device 1 is operated under a condition of being exposed to a high-temperature, high-humidity environment.

Under a high-temperature environment, stress due to thermal expansion of the source electrode 85 concentrates in a vicinity of the first electrode side wall 87 of the source electrode 85. When the second inorganic film 110 covers the first electrode side wall 87, there is a possibility for the second inorganic film 110 to peel off from the first electrode side wall 87 due to the stress of the source electrode 85. When peeling of the second inorganic film 110 occurs, there is a possibility for intrusion of moisture (water) with a peeled portion of the second inorganic film 110 as a starting point under a high humidity environment.

In this regard, with the semiconductor device 1, the first inner covering portion 111 of the second inorganic film 110 exposes the first electrode side wall 87 and the outer covering portion 113 of the second inorganic film 110 is formed at an interval from the first inner covering portion 111. A starting point of the peeling of the second inorganic film 110 due to the stress of the source electrode 85 is thereby diminished and the peeling of the second inorganic film 110 is suppressed. On the other hand, in the region between the first inner covering portion 111 and the outer covering portion 113, the organic film 120 covers an exposed portion of the source electrode 85. The organic film 120 has a hardness lower than a hardness of the second inorganic film 110. Therefore, even when stress due to thermal expansion arises in the source electrode 85, the organic film 120 elastically absorbs the stress. Peeling of the organic film 120 from the first electrode side wall 87 is thereby suppressed and the source electrode 85 is protected by the organic film 120.

Due to the layout in which the source wiring 90 is arranged in a periphery of the source electrode 85, an electric field that is higher than an electric field at the source electrode 85 side concentrates in a vicinity of the source wiring 90 in some cases. When, under a high-temperature environment, moisture (water) reaches the source wiring 90 with a peeled portion as a starting point, there is a possibility for an oxidation reaction of the moisture (water) and the source wiring 90 to be accelerated due to the high electric field in the vicinity of the source wiring 90.

In this regard, with the semiconductor device 1, since the source wiring 90 is protected by the outer covering portion 113, contact of the source wiring 90 with moisture (water) is suppressed by the outer covering portion 113. The oxidation of the source wiring 90 is thereby suppressed. Consequently, lowering of adhesion force of the organic film 120 and lowering of wiring resistance of the source wiring 90 due to an oxidized portion are suppressed.

The source wiring 90 has the first outer side wall 93 (the wiring side wall) at an opposite side to the source electrode 85 in sectional view. In this case, the outer covering portion 113 of the second inorganic film 110 preferably covers the first outer side wall 93 of the source wiring 90 in sectional view. The organic film 120 preferably covers the first outer side wall 93 of the source wiring 90 with the outer covering portion 113 interposed therebetween in sectional view. According to this arrangement, the oxidation of the source wiring 90 with the first outer side wall 93 as a starting point is suppressed appropriately. Such an arrangement is particularly effective in a case where an electric field concentrates at the first outer side wall 93 side.

The outer covering portion 113 may cover the entirety of the source wiring 90 in sectional view. In this case, the organic film 120 may cover the entirety of the source wiring 90 with the outer covering portion 113 interposed therebetween in sectional view. According to this arrangement, the oxidation of the source wiring 90 is suppressed appropriately across the entirety of the source wiring 90.

The first inner covering portion 111 preferably covers the source electrode 85 at an interval from the first electrode side wall 87. According to this arrangement, peeling of the first inner covering portion 111 due to the thermal expansion of the source electrode 85 is suppressed appropriately.

The outer covering portion 113 preferably exposes the first electrode side wall 87. According to this arrangement, peeling of the outer covering portion 113 due to thermal expansion of the source electrode 85 is suppressed appropriately. The outer covering portion 113 preferably covers the first inorganic film 75 at an interval from the first electrode side wall 87.

The organic film 120 preferably has a portion that directly covers the first electrode side wall 87. According to this arrangement, the first electrode side wall 87 is protected by the organic film 120 appropriately. The first inner covering portion 111 preferably exposes a peripheral edge portion of the source electrode 85. In this case, the organic film 120 preferably has a portion that directly covers the first electrode side wall 87 of the source electrode 85 and the peripheral edge portion of the source electrode 85.

The organic film 120 preferably has, in the region between the source electrode 85 and the source wiring 90, a portion that directly covers an exposed portion of the first inorganic film 75 between the source electrode 85 and the outer covering portion 113.

The organic film 120 preferably has a portion that directly covers an exposed portion of the first inorganic film 75 between the source electrode 85 and the outer covering portion 113. According to these arrangements, the peeling of the organic film 120 is suppressed and, at the same time, intrusion of moisture (water) is suppressed by increase in creeping distance.

The first inner covering portion 111 preferably exposes an inner portion of the source electrode 85. According to this arrangement, the inner portion of the source electrode 85 is used as an application terminal for electric potential. The organic film 120 may expose an edge portion of the first inner covering portion 111 at the inner portion side of the source electrode 85. The source wiring 90 may be electrically connected to the source electrode 85. The source wiring 90 may be led out from the source electrode 85. The source wiring 90 may be the outermost peripheral wiring.

The semiconductor device 1 may include the gate wiring 100 (the second wiring) that is arranged on the first inorganic film 75 in the region between the source electrode 85 and the source wiring 90. The gate wiring 100 is electrically separated from the source wiring 90. The organic film 120 may cover the gate wiring 100. According to this arrangement, the gate wiring 100 is protected by the organic film 120.

The outer covering portion 113 may cover the gate wiring 100. In this case, the organic film 120 may cover the gate wiring 100 with the outer covering portion 113 interposed therebetween. According to this arrangement, contact of moisture (water) with the gate wiring 100 is suppressed by the outer covering portion 113. Oxidation of the gate wiring 100 is thereby suppressed.

The outer covering portion 113 may cover the entirety of the gate wiring 100 in sectional view. In this case, the organic film 120 may cover the entirety of the gate wiring 100 with the outer covering portion 113 interposed therebetween in sectional view. According to this arrangement, the oxidation of the gate wiring 100 is appropriately suppressed across the entirety of the gate wiring 100.

The first inorganic film 75 may have the anchor opening 83. In this case, the second inorganic film 110 may have a portion positioned inside the anchor opening 83. According to this arrangement, an adhesion force of the second inorganic film 110 with respect to the first inorganic film 75 is increased by the anchor opening 83. Peeling of the second inorganic film 110 from the first inorganic film 75 is thereby suppressed. Also, since a creeping distance is increased by the anchor opening 83, intrusion of moisture (water) is suppressed.

The organic film 120 may cover a portion of the second inorganic film 110 that covers the anchor opening 83. According to this arrangement, an adhesion force of the organic film 120 with respect to the second inorganic film 110 is increased by an unevenness of the second inorganic film 110 due to the anchor opening 83. Peeling of the second inorganic film 110 from the organic film 120 is thereby suppressed.

The semiconductor device 1 may include the chip 2. The first inorganic film 75 may be formed on the chip 2. The semiconductor device 1 may include the active region 12 provided in an inner portion of the chip 2 and the outer peripheral region 19 provided in a peripheral edge portion of the chip 2. In this case, the first inorganic film 75 may cover both the active region 12 and the outer peripheral region 19. The source electrode 85 may be arranged on the active region 12. The source wiring 90 may be arranged on the outer peripheral region 19.

An electric field at the outer peripheral region 19 side tends to be higher than an electric field at the active region 12 side. Therefore, in some cases, an electric field that is higher than the electric field at the source electrode 85 side concentrates at the source wiring 90 at the outer peripheral region 19 region. Thus, when there is intrusion of moisture (water) from the outer peripheral region 19 side, a risk of oxidation is higher at the source wiring 90 than at the source electrode 85. The arrangement in which the source wiring 90 is protected by the outer covering portion 113 is therefore particularly effective in the arrangement in which the source wiring 90 is arranged in the outer peripheral region 19.

The chip 2 preferably contains SiC. According to this arrangement, the semiconductor device 1 is provided as an SiC semiconductor device. By the SiC semiconductor device, excellent electrical characteristics and durability performance are exhibited in severe usage environments.

In another aspect, the semiconductor device 1 (the electronic component) includes the source electrode 85 (the terminal electrode), the source wiring 90 (the wiring), the second inorganic film 110 (the inorganic film) with the insulating property, and the organic film 120 with the insulating property. The source wiring 90 is arranged in a periphery of the source electrode 85. The second inorganic film 110 covers the source wiring 90 at an interval from the source electrode 85. The organic film 120 has a portion that directly covers the source electrode 85 and a portion that covers the source wiring 90 with the second inorganic film 110 interposed therebetween.

According to this arrangement, the semiconductor device 1 having a novel layout is provided. For example, according to the semiconductor device 1, the peeling of the second inorganic film 110 due to the stress of the source electrode 85 is suppressed and the oxidation of the source wiring 90 is suppressed by the second inorganic film 110. Also, both the source electrode 85 and the source wiring 90 are protected by the organic film 120.

In another aspect, the semiconductor device 1 (the electronic component) includes the first region (12), the second region (19), the source electrode 85 (the terminal electrode), the source wiring 90 (the wiring), the second inorganic film 110 (the inorganic film) with the insulating property, and the organic film 120 with the insulating property. The first region (12) has the first electric field. The second region (19) has the second electric field higher than the first electric field in a periphery of the first region (12). In this embodiment, the active region 12 is given as an example of a mode of the first region (12) and the outer peripheral region 19 is given as an example of a mode of the second region (19).

The source electrode 85 is arranged in the first region (12). The source wiring 90 is arranged in the second region (19) in a periphery of the source electrode 85. The second inorganic film 110 exposes the source electrode 85 and covers the source wiring 90. The organic film 120 has a portion that directly covers the source electrode 85 and a portion that covers the source wiring 90 with the second inorganic film 110 interposed therebetween.

According to this arrangement, the semiconductor device 1 having a novel layout is provided. For example, according to the semiconductor device 1, the peeling of the second inorganic film 110 due to the stress of the source electrode 85 is suppressed and the oxidation of the source wiring 90 is suppressed by the second inorganic film 110. In particular, according to this semiconductor device 1, the oxidation reaction of the moisture (water) and the source wiring 90 due to the second electric field in the vicinity of the source wiring 90 are suppressed. Also, both the source electrode 85 and the source wiring 90 are protected by the organic film 120.

In another aspect, the semiconductor device 1 includes the chip 2, the active region 12, the outer peripheral region 19, the transistor structure Tr (the device structure), the outer well region 70 (the impurity region), the source electrode 85 (the electrode), the source wiring 90 (the wiring), the second inorganic film 110 with the insulating property, and the organic film 120 with the insulating property.

The chip 2 has the first main surface 3. The active region 12 is provided in an inner portion of the first main surface 3. The outer peripheral region 19 is provided in a peripheral edge portion of the first main surface 3. The transistor structure Tr is formed in the first main surface 3 in the active region 12. The outer well region 70 is formed in a surface layer portion of the first main surface 3 in the outer peripheral region 19.

The source electrode 85 is arranged on the first main surface 3 in the active region 12 and is electrically connected to the transistor structure Tr. The source wiring 90 is arranged on the first main surface 3 in the outer peripheral region 19 and is electrically connected to the outer well region 70. The second inorganic film 110 exposes the source electrode 85 and covers the source wiring 90. The organic film 120 has a portion that directly covers the source electrode 85 and a portion that covers the source wiring 90 with the second inorganic film 110 interposed therebetween.

According to this arrangement, the semiconductor device 1 having a novel layout is provided. For example, according to the semiconductor device 1, the peeling of the second inorganic film 110 due to the stress of the source electrode 85 is suppressed and the oxidation of the source wiring 90 is suppressed by the second inorganic film 110. In particular, according to this semiconductor device 1, the oxidation reaction of the moisture (water) and the source wiring 90 due to the electric field in the vicinity of the source wiring 90 are suppressed. Also, both the source electrode 85 and the source wiring 90 are protected by the organic film 120.

Although a relationship of the source electrode 85 and the source wiring 90 was described here, the source electrode 85 may be replaced by the gate electrode 95 and the source wiring 90 may be replaced by the gate wiring 100.

That is, in another aspect, the semiconductor device 1 (the electronic component) includes the first inorganic film 75 (the covered object) with the insulating property, the gate electrode 95 (the electrode), the gate wiring 100 (the wiring), the second inorganic film 110 (the inorganic film) with the insulating property, and the organic film 120 with the insulating property. The gate electrode 95 is arranged on the first inorganic film 75 and has the second electrode side wall 97 on the first inorganic film 75. The gate wiring 100 is arranged on the first inorganic film 75 in a periphery of the gate electrode 95.

The second inorganic film 110 has the second inner covering portion 112 that covers the gate electrode 95 so as to expose the second electrode side wall 97 and the outer covering portion 113 that covers the gate wiring 100 at an interval from the second inner covering portion 112. The organic film 120 extends across the second inner covering portion 112 and the outer covering portion 113 and covers the gate electrode 95 between the second inner covering portion 112 and the outer covering portion 113.

According to this arrangement, the semiconductor device 1 having a novel layout is provided. For example, according to the semiconductor device 1, peeling of the second inorganic film 110 due to stress of the gate electrode 95 is suppressed and oxidation of the gate wiring 100 is suppressed by the second inorganic film 110. Also, both the gate electrode 95 and the gate wiring 100 are protected by the organic film 120.

In another aspect, the semiconductor device 1 (the electronic component) includes the first inorganic film 75 (the covered object) with the insulating property, the source electrode 85 (the electrode), the gate wiring 100 (the wiring), the second inorganic film 110 (the inorganic film) with the insulating property, and the organic film 120 with the insulating property. The source electrode 85 is arranged on the first inorganic film 75 and has the first electrode side wall 87 on the first inorganic film 75. The gate wiring 100 is arranged on the first inorganic film 75 in a periphery of the source electrode 85.

The second inorganic film 110 has the first inner covering portion 111 that covers the source electrode 85 so as to expose the first electrode side wall 87 and the outer covering portion 113 that covers the gate wiring 100 at an interval from the first inner covering portion 111. The organic film 120 extends across the first inner covering portion 111 and the outer covering portion 113 and covers the source electrode 85 between the first inner covering portion 111 and the outer covering portion 113.

According to this arrangement, the semiconductor device 1 having a novel layout is provided. For example, according to the semiconductor device 1, the peeling of the second inorganic film 110 due to the stress of the source electrode 85 is suppressed and the oxidation of the gate wiring 100 is suppressed by the second inorganic film 110. Also, both the source electrode 85 and the gate wiring 100 are protected by the organic film 120.

In another aspect, the semiconductor device 1 (the electronic component) includes the first inorganic film 75 (the covered object) with the insulating property, the gate electrode 95 (the electrode), the source wiring 90 (the wiring), the second inorganic film 110 (the inorganic film) with the insulating property, and the organic film 120 with the insulating property. The gate electrode 95 is arranged on the first inorganic film 75 and has the second electrode side wall 97 on the first inorganic film 75. The source wiring 90 is arranged on the first inorganic film 75 in a periphery of the gate electrode 95.

The second inorganic film 110 has the second inner covering portion 112 that covers the gate electrode 95 so as to expose the second electrode side wall 97 and the outer covering portion 113 that covers the source wiring 90 at an interval from the second inner covering portion 112. The organic film 120 extends across the second inner covering portion 112 and the outer covering portion 113 and covers the gate electrode 95 between the second inner covering portion 112 and the outer covering portion 113.

According to this arrangement, the semiconductor device 1 having a novel layout is provided. For example, according to the semiconductor device 1, the peeling of the second inorganic film 110 due to the stress of the gate electrode 95 is suppressed and the oxidation of the source wiring 90 is suppressed by the second inorganic film 110. Also, both the gate electrode 95 and the source wiring 90 are protected by the organic film 120.

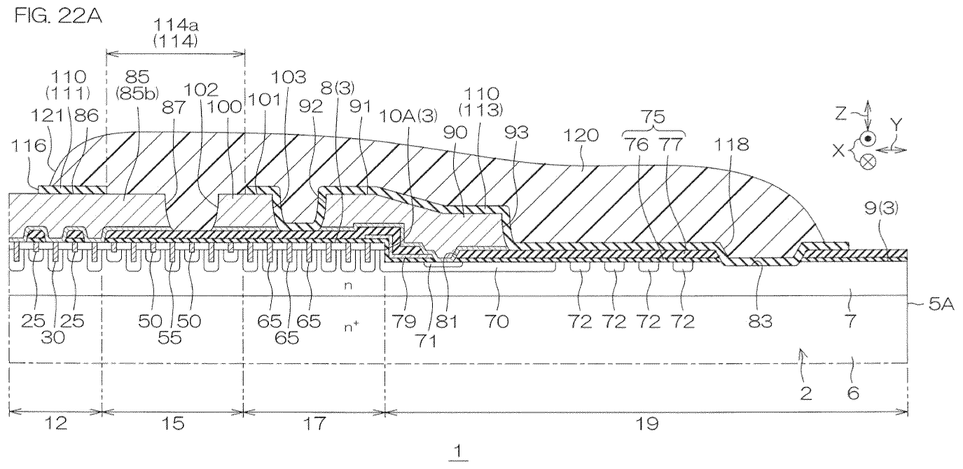

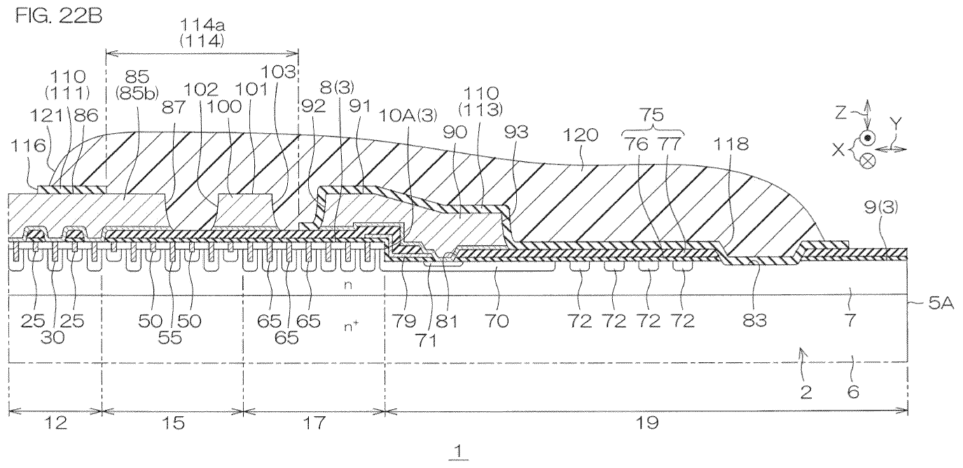

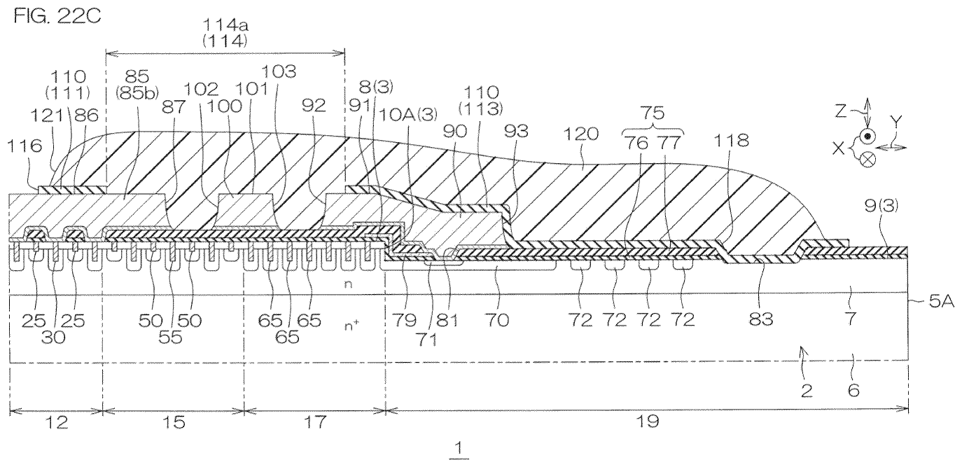

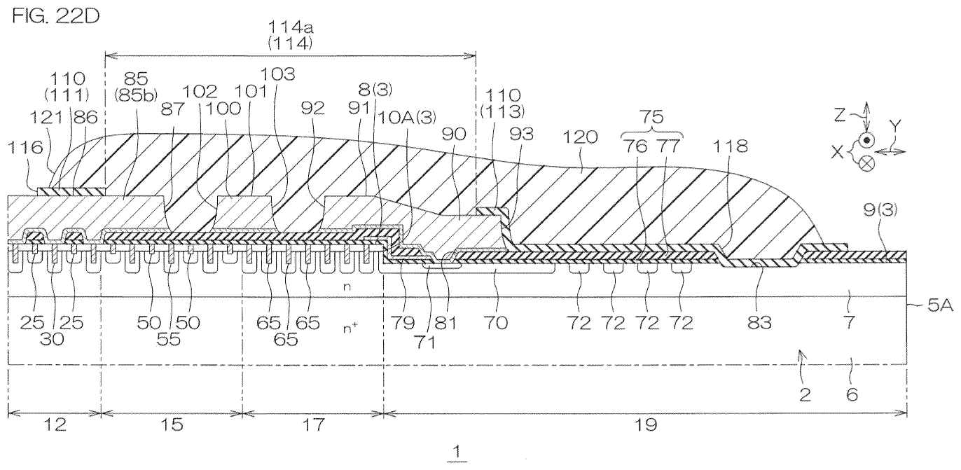

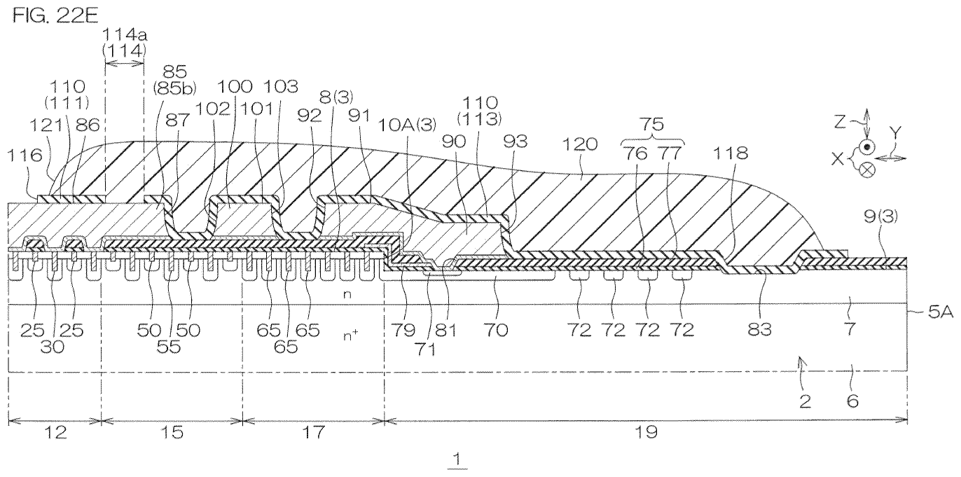

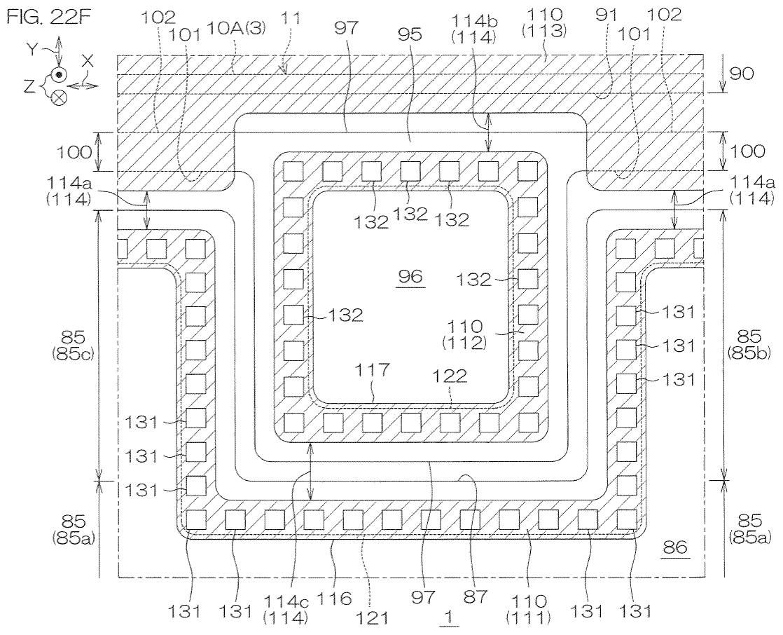

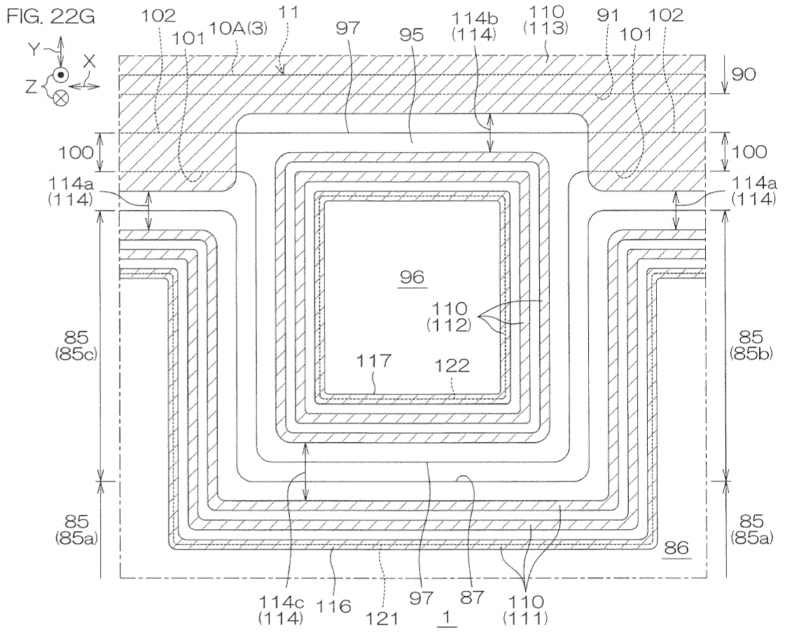

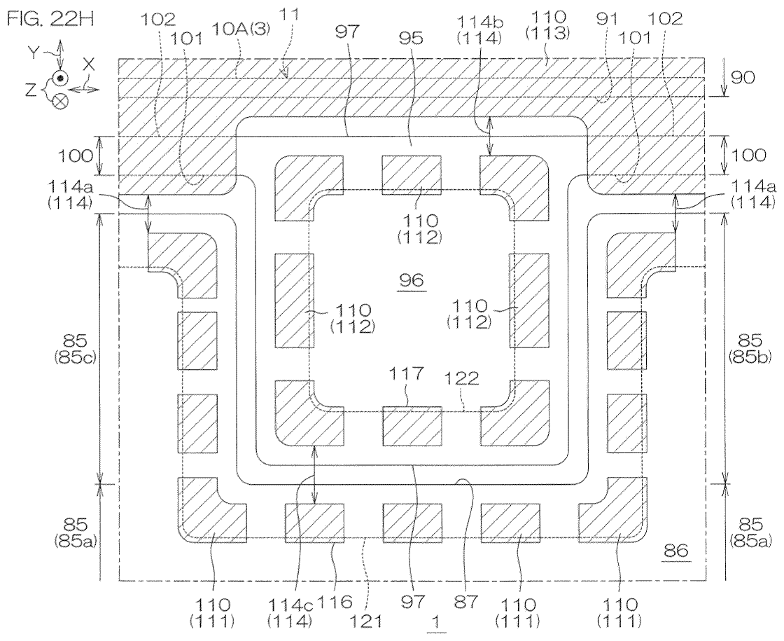

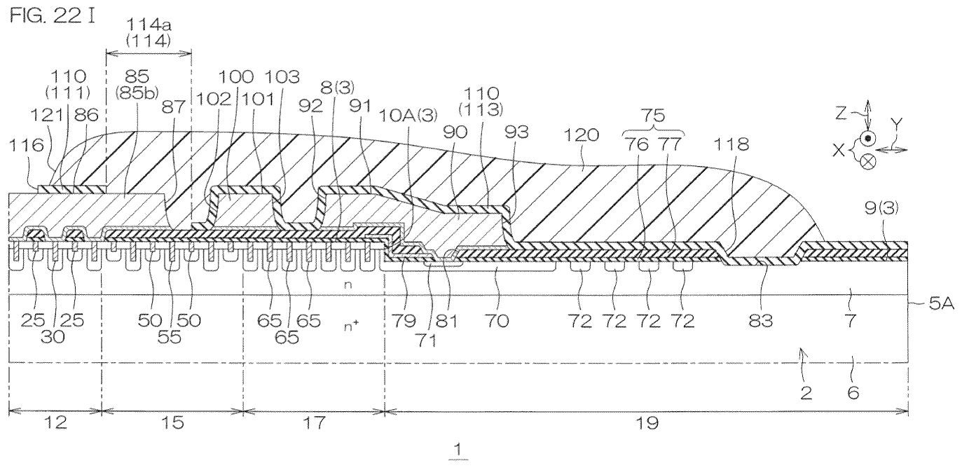

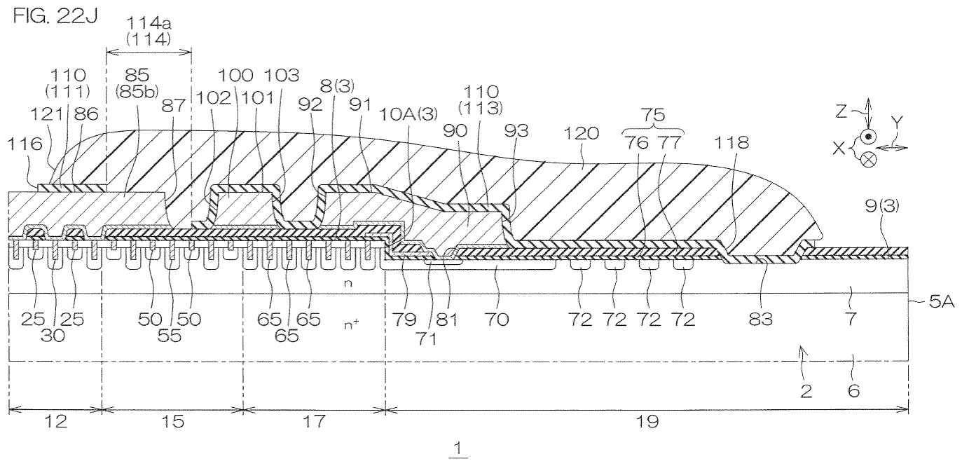

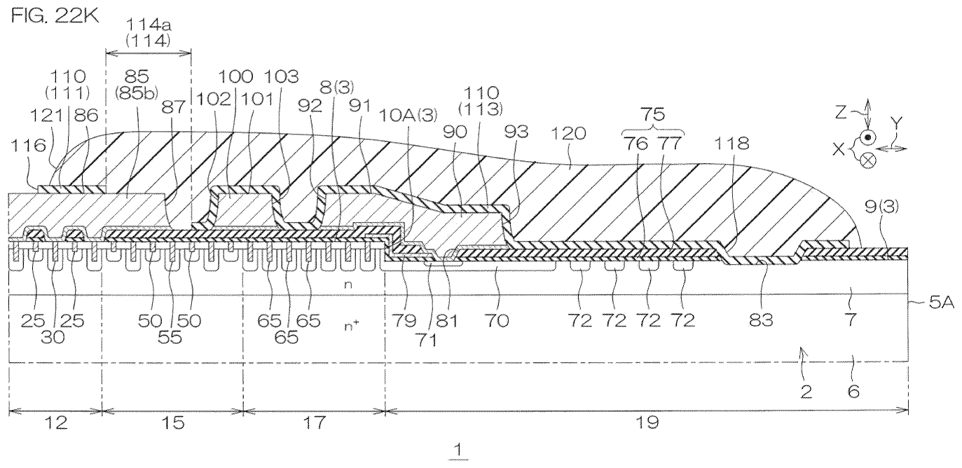

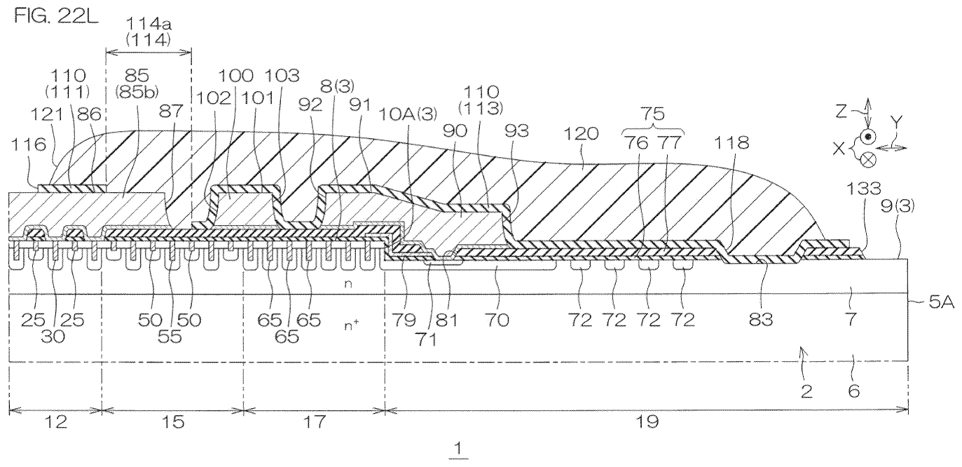

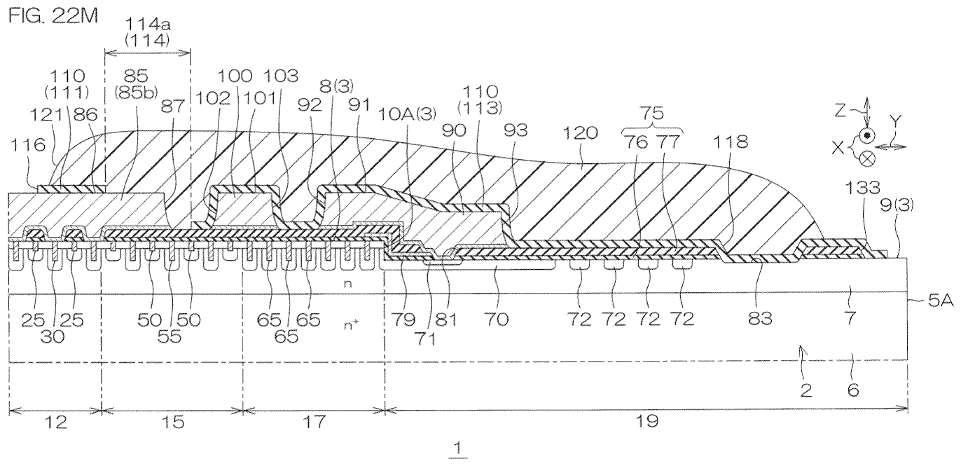

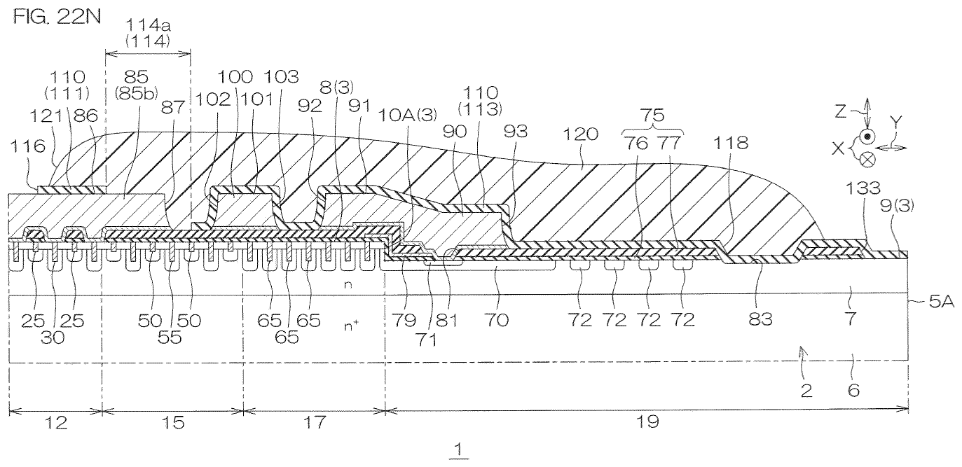

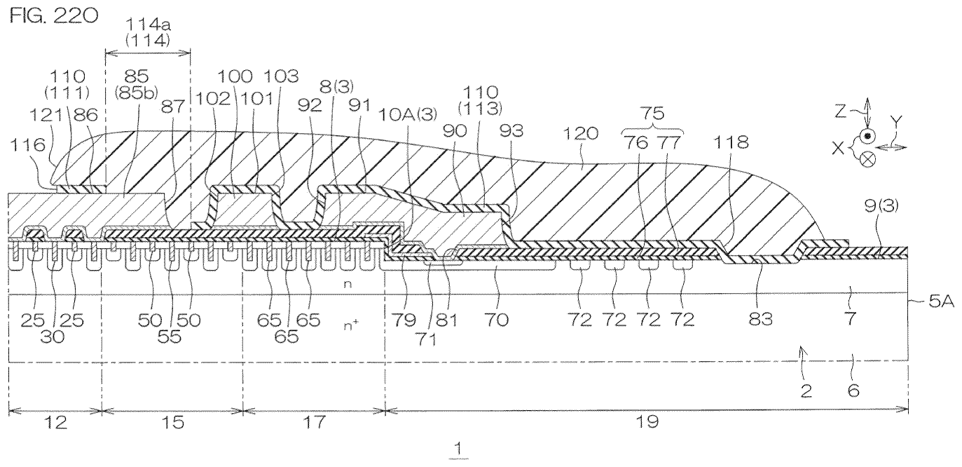

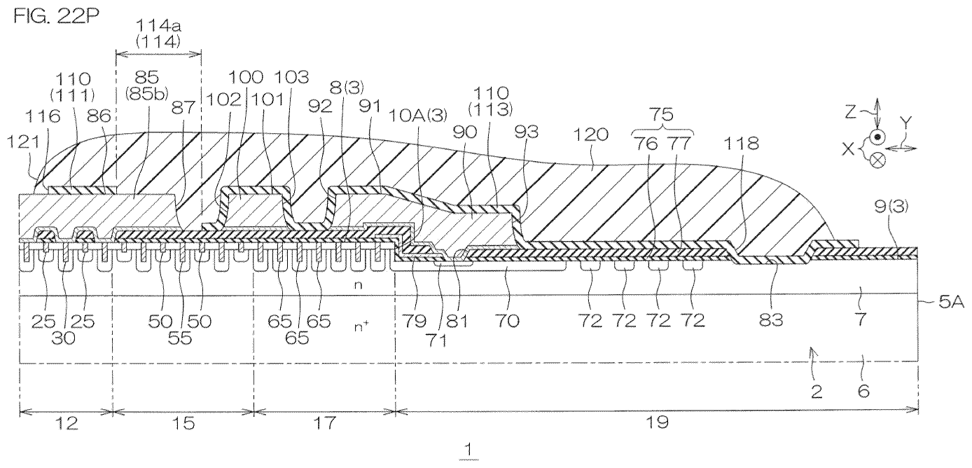

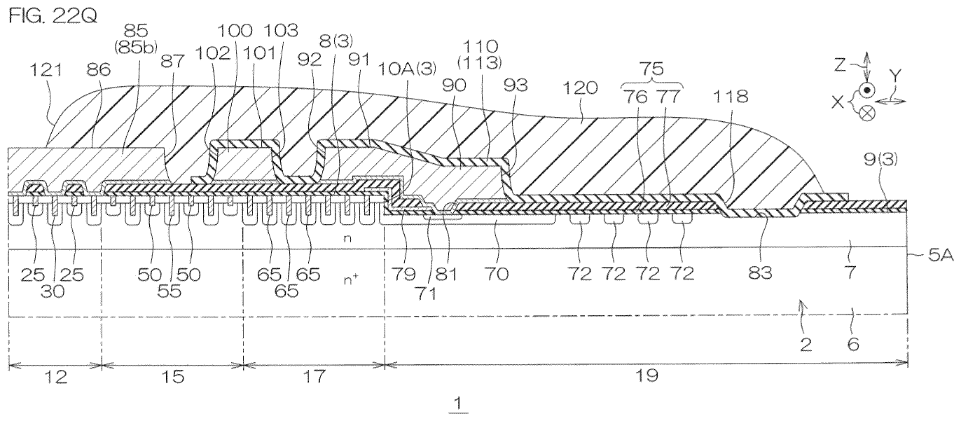

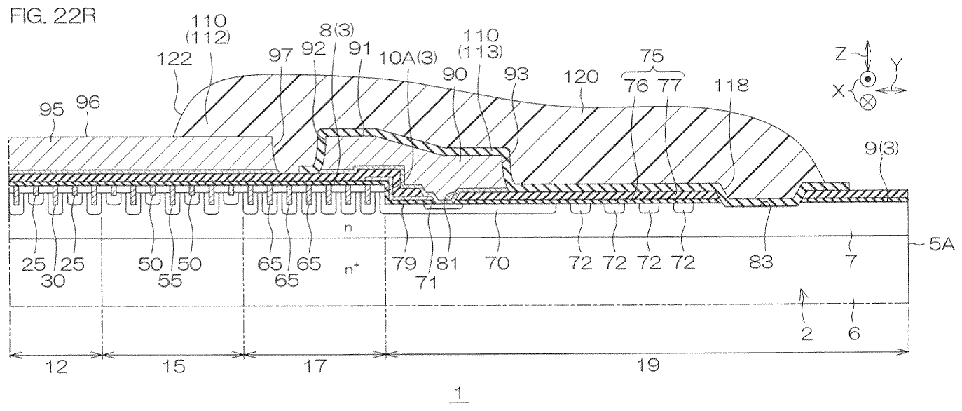

Hereinafter, second to nineteenth layout examples of the second inorganic film 110 shall be illustrated with reference to FIG. 22A to FIG. 22R. FIG. 22A to FIG. 22E are sectional views showing the second to sixth layout examples of the second inorganic film 110. FIG. 22F to FIG. 22H are enlarged plan views showing the seventh to ninth layout examples of the second inorganic film 110. FIG. 22I to FIG. 22R are sectional views showing the tenth to nineteenth layout examples of the second inorganic film 110.

The semiconductor device 1 may include a feature of any one second inorganic film 110 among the second inorganic films 110 according to the first to nineteenth layout examples. As a matter of course, the features of the second inorganic films 110 according to the first to nineteenth layout examples can be combined as appropriate with each other. Therefore, the semiconductor device 1 can include at least two features among the features of the second inorganic films 110 according to the first to nineteenth layout examples at the same time in the same region or in different regions.

With reference to FIG. 22A (the second layout example), the second inorganic film 110 may have the outer covering portion 113 that exposes the second inner side wall 102 of the gate wiring 100 and covers the second wiring surface 101 of the gate wiring 100 and the second outer side wall 103 of the gate wiring 100. The outer covering portion 113 may have an inner edge portion that is positioned on the second wiring surface 101 of the gate wiring 100.

In this embodiment, the organic film 120 has a portion that directly covers the first inorganic film 75 in a region (the first removed portion 114a) between the source electrode 85 and the gate wiring 100. The organic film 120 directly covers the second inner side wall 102 of the gate wiring 100 and covers the second outer side wall 103 of the gate wiring 100 with the outer covering portion 113 interposed therebetween. In this embodiment, the organic film 120 has a portion that directly covers the second wiring surface 101 of the gate wiring 100 and a portion that covers the second wiring surface 101 of the gate wiring 100 with the outer covering portion 113 interposed therebetween.

With reference to FIG. 22B (the third layout example), the second inorganic film 110 may have the outer covering portion 113 that exposes the entirety of the gate wiring 100. The outer covering portion 113 may have an inner edge portion that is positioned in a region between the source wiring 90 and the gate wiring 100. The inner edge portion of the outer covering portion 113 may cover the first inorganic film 75 at an interval to the source wiring 90 side from the second outer side wall 103 of the gate wiring 100.

In this embodiment, the organic film 120 has, in the first removed portion 114a, a portion that directly covers the second wiring surface 101, the second inner side wall 102, and the second outer side wall 103 of the gate wiring 100. In this embodiment, the organic film 120 has, in the region between the source wiring 90 and the gate wiring 100, a portion that directly covers the first inorganic film 75 and a portion that covers the first inorganic film 75 with the second inorganic film 110 interposed therebetween.

With reference to FIG. 22C (the fourth layout example), the second inorganic film 110 may have the outer covering portion 113 that exposes the first inner side wall 92 of the source wiring 90 and covers the first wiring surface 91 of the source wiring 90 and the first outer side wall 93 of the source wiring 90. The outer covering portion 113 may have an inner edge portion that is positioned on the first wiring surface 91 of the source wiring 90. The inner edge portion of the outer covering portion 113 may face the first surface portion 8 with the source wiring 90 interposed therebetween.

In this embodiment, the organic film 120 directly covers the second wiring surface 101, the second inner side wall 102, and the second outer side wall 103 of the gate wiring 100 in the first removed portion 114a. The organic film 120 directly covers the first inorganic film 75 in the region between the source wiring 90 and the gate wiring 100.

The organic film 120 directly covers the first inner side wall 92 of the source wiring 90 and covers the first outer side wall 93 of the source wiring 90 with the outer covering portion 113 interposed therebetween. In this embodiment, the organic film 120 has a portion that directly covers the first wiring surface 91 of the source wiring 90 and a portion that covers the first wiring surface 91 of the source wiring 90 with the outer covering portion 113 interposed therebetween.

With reference to FIG. 22D (the fifth layout example), the second inorganic film 110 may have the outer covering portion 113 that exposes the first inner side wall 92 of the source wiring 90 and covers the first wiring surface 91 of the source wiring 90 and the first outer side wall 93 of the source wiring 90.

The outer covering portion 113 may have an inner edge portion that is positioned on the first wiring surface 91 of the source wiring 90. The inner edge portion of the outer covering portion 113 may face the second surface portion 9 with the source wiring 90 interposed therebetween. The inner edge portion of the outer covering portion 113 may be positioned further to the first outer side wall 93 side than the outer opening 81 or may be positioned further to the first inner side wall 92 side than the outer opening 81.

In this embodiment, the organic film 120 directly covers the second wiring surface 101, the second inner side wall 102, and the second outer side wall 103 of the gate wiring 100 in the first removed portion 114a. The organic film 120 directly covers the first inorganic film 75 in the region between the source wiring 90 and the gate wiring 100.

The organic film 120 directly covers the first inner side wall 92 of the source wiring 90 and covers the first outer side wall 93 of the source wiring 90 with the outer covering portion 113 interposed therebetween. In this embodiment, the organic film 120 has a portion that directly covers the first wiring surface 91 of the source wiring 90 and a portion that covers the first wiring surface 91 of the source wiring 90 with the outer covering portion 113 interposed therebetween.

With reference to FIG. 22E (the sixth layout example), the second inorganic film 110 may have the outer covering portion 113 that covers the first electrode side wall 87 of the source electrode 85 at an interval from the first inner covering portion 111.

In this case, the outer covering portion 113 may have an inner edge portion that is positioned on a peripheral edge portion of the first electrode surface 86 of the source electrode 85. The outer covering portion 113, together with the first inner covering portion 111, may expose the peripheral edge portion of the first electrode surface 86 of the source electrode 85. The first removed portion 114a may expose just the peripheral edge portion of the first electrode surface 86 of the source electrode 85.

In this embodiment, the organic film 120 covers the first electrode side wall 87 of the source electrode 85 with the outer covering portion 113 interposed therebetween. The organic film 120 has a portion that covers the peripheral edge portion of the first electrode surface 86 of the source electrode 85 with the outer covering portion 113 interposed therebetween. The organic film 120 has a portion that directly covers a portion of the peripheral edge portion of the first electrode surface 86 exposed from the first inner covering portion 111 and the outer covering portion 113. The organic film 120 may directly cover just the peripheral edge portion of the first electrode surface 86 in the first removed portion 114a.

With reference to FIG. 22F (the seventh layout example), the second inorganic film 110 may have one or a plurality of first openings 131 formed in the first inner covering portion 111 so as to expose the first electrode surface 86 of the source electrode 85. The plurality of first openings 131 may be formed at intervals along an extension direction of the first inner covering portion 111. The plurality of first openings 131 may each be demarcated in a band shape, a quadrangle shape, a rectangular shape, a polygonal shape, a circular shape, etc., in plan view.

Similarly, the second inorganic film 110 may have one or a plurality of second openings 132 formed in the second inner covering portion 112 so as to expose the second electrode surface 96 of the gate electrode 95. The plurality of second openings 132 may be formed at intervals along an extension direction of the second inner covering portion 112. The plurality of second openings 132 may each be demarcated in a band shape, a quadrangle shape, a rectangular shape, a polygonal shape, a circular shape, etc., in plan view.

In this embodiment, the organic film 120 enters into the plurality of first openings 131 from above the first inner covering portion 111 and is connected to the first electrode surface 86 of the source electrode 85 inside the plurality of first openings 131. An adhesion force of the organic film 120 with respect to the first inner covering portion 111 (the second inorganic film 110) is increased by the plurality of first openings 131.

Similarly, the organic film 120 enters into the plurality of second openings 132 from above the second inner covering portion 112 and is connected to the second electrode surface 96 of the gate electrode 95 inside the plurality of second openings 132. An adhesion force of the organic film 120 with respect to the second inner covering portion 112 (the second inorganic film 110) is increased by the plurality of second openings 132.

With reference to FIG. 22G (the eighth layout example), the second inorganic film 110 may have a plurality of the first inner covering portions 111 arranged at intervals to an inner side of the source electrode 85 from the first electrode side wall 87 side of the source electrode 85.

The first inner covering portions 111 arranged at the inner side of the source electrode 85 demarcate the first pad opening 116. The plurality of first inner covering portions 111 may each be formed in a band shape with ends or an endless band shape extending along the first electrode side wall 87 of the source electrode 85. The plurality of first inner covering portions 111 may each be formed in an annular shape surrounding an inner portion of the source electrode 85.

Similarly, the second inorganic film 110 may have a plurality of the second inner covering portions 112 arranged at intervals to an inner side of the gate electrode 95 from the second electrode side wall 97 side of the gate electrode 95. The second inner covering portions 112 arranged at the inner side of the source electrode 85 demarcate the second pad opening 117. The plurality of second inner covering portions 112 may each be formed in a band shape with ends or an endless band shape extending along the second electrode side wall 97 of the gate electrode 95. The plurality of second inner covering portions 112 may each be formed in an annular shape surrounding an inner portion of the gate electrode 95.

In this embodiment, the organic film 120 enters into regions (openings) between the plurality of first inner covering portions 111 from above the plurality of first inner covering portions 111 and is connected to the first electrode surface 86 of the source electrode 85 in the regions between the plurality of first inner covering portions 111. An adhesion force of the organic film 120 with respect to the first inner covering portions 111 (the second inorganic film 110) is increased by the plurality of first inner covering portions 111.

Similarly, in this embodiment, the organic film 120 enters into regions (openings) between the plurality of second inner covering portions 112 from above the plurality of second inner covering portions 112 and is connected to the second electrode surface 96 of the gate electrode 95 in the regions between the plurality of second inner covering portions 112. An adhesion force of the organic film 120 with respect to the second inner covering portions 112 (the second inorganic film 110) is increased by the plurality of second inner covering portions 112.

With reference to FIG. 22H (the ninth layout example), the second inorganic film 110 may have the plurality of first inner covering portions 111 arranged at intervals along the first electrode side wall 87 of the source electrode 85. The plurality of first inner covering portions 111 may each be formed in a band shape, a quadrangle shape, a rectangular shape, a polygonal shape, a circular shape, etc., in plan view.

Similarly, the second inorganic film 110 may have the plurality of second inner covering portions 112 arranged at intervals along the second electrode side wall 97 of the gate electrode 95. The plurality of second inner covering portions 112 may each be formed in a band shape, a quadrangle shape, a rectangular shape, a polygonal shape, a circular shape, etc., in plan view.

In this embodiment, the organic film 120 enters into regions (openings) between the plurality of first inner covering portions 111 from above the plurality of first inner covering portions 111 and is connected to the first electrode surface 86 of the source electrode 85 in the regions between the plurality of first inner covering portions 111. An adhesion force of the organic film 120 with respect to the first inner covering portions 111 (the second inorganic film 110) is increased by the plurality of first inner covering portions 111.

Similarly, in this embodiment, the organic film 120 enters into regions (openings) between the plurality of second inner covering portions 112 from above the plurality of second inner covering portions 112 and is connected to the second electrode surface 96 of the gate electrode 95 in the regions between the plurality of second inner covering portions 112. An adhesion force of the organic film 120 with respect to the second inner covering portions 112 (the second inorganic film 110) is increased by the plurality of second inner covering portions 112.

With reference to FIG. 22I (the tenth layout example), the second inorganic film 110 may have the outer covering portion 113 that is exposed from at least one (for example, all) of the first to fourth side surfaces 5A to 5D. The outer covering portion 113 may be formed flush with at least one (for example, all) of the first to fourth side surfaces 5A to 5D.

With reference to FIG. 22J (the eleventh layout example), the second inorganic film 110 may have the outer covering portion 113 that is positioned further inward than an outer edge portion of the organic film 120. That is, the organic film 120 may protrude further outward than the outer edge portion of the outer covering portion 113.

With reference to FIG. 22K (the twelfth layout example), the second inorganic film 110 may have the outer covering portion 113 that is positioned in an interior of the organic film 120. That is, the organic film 120 may cover the outer edge portion of the outer covering portion 113.

With reference to FIG. 22L (the thirteenth layout example), the first inorganic film 75 may have a notched portion 133 that is formed at an interval inward from at least one (for example, all) of the first to fourth side surfaces 5A to 5D and exposes a peripheral edge portion of the second surface portion 9 (exposes the second semiconductor region 7). In this case, the second inorganic film 110 may have the outer covering portion 113 that has an outer edge portion arranged on the first inorganic film 75 at an interval inward from the notched portion 133.

With reference to FIG. 22M (the fourteenth layout example), the first inorganic film 75 may have the notched portion 133 as in the thirteenth layout example. In this case, the second inorganic film 110 may have the outer covering portion 113 having a portion that enters into the notched portion 133 from above the first inorganic film 75 and directly covers a peripheral edge portion of the second surface portion 9 inside the notched portion 133. The outer covering portion 113 may be formed at an interval inward from at least one (for example, all) of the first to fourth side surfaces 5A to 5D.

With reference to FIG. 22N (the fifteenth layout example), the second inorganic film 110 may have the outer covering portion 113 positioned inside the notched portion 133 as in the fourteenth layout example. The outer covering portion 113 may be exposed from at least one (for example, all) of the first to fourth side surfaces 5A to 5D. The outer covering portion 113 may be formed flush with at least one (for example, all) of the first to fourth side surfaces 5A to 5D.

With reference to FIG. 22O (the sixteenth layout example), the second inorganic film 110 may have the first inner covering portion 111 that is positioned further inward than an inner edge portion of the organic film 120. That is, the organic film 120 may protrude further to the inside of the source electrode 85 (the first electrode surface 86) than an inner edge portion of the first inner covering portion 111.

A wall surface of the first upper pad opening 121 may be positioned further to an inner portion side of the first electrode surface 86 than a wall surface of the first pad opening 116. The wall surface of the first upper pad opening 121 may be formed at an interval in a lamination direction from the first electrode surface 86.

Similarly, the second inorganic film 110 may have the second inner covering portion 112 that is positioned further inward than an inner edge portion of the organic film 120. That is, the organic film 120 may protrude further to the inside of the gate electrode 95 (the second electrode surface 96) than an inner edge portion of the second inner covering portion 112.

A wall surface of the second upper pad opening 122 may be positioned further to an inner portion side of the second electrode surface 96 than a wall surface of the second pad opening 117. The wall surface of the second upper pad opening 122 may be formed at an interval in the lamination direction from the second electrode surface 96.

With reference to FIG. 22P (the seventeenth layout example), the second inorganic film 110 may have the first inner covering portion 111 that is positioned in the interior of the organic film 120. That is, the organic film 120 may cover an inner edge portion of the first inner covering portion 111. In this case, the organic film 120 may cover an entirety of the first inner covering portion 111.

The organic film 120 may directly cover the source electrode 85 (the first electrode surface 86) in a region further to the inner side than the inner edge portion of the first inner covering portion 111. The wall surface of the first upper pad opening 121 may be positioned further to the inner portion side of the first electrode surface 86 than the wall surface of the first pad opening 116. The wall surface of the first upper pad opening 121 may directly cover the first electrode surface 86 in the region further to the inner side than the inner edge portion of the first inner covering portion 111.

Similarly, the second inorganic film 110 may have the second inner covering portion 112 that is positioned in the interior of the organic film 120. That is, the organic film 120 may cover an inner edge portion of the second inner covering portion 112. In this case, the organic film 120 may cover an entirety of the second inner covering portion 112.

The organic film 120 may directly cover the gate electrode 95 (the second electrode surface 96) in a region further to the inner side than the inner edge portion of the second inner covering portion 112. The wall surface of the second upper pad opening 122 may be positioned further to the inner portion side of the second electrode surface 96 than the wall surface of the second pad opening 117. The wall surface of the second upper pad opening 122 may directly cover the second electrode surface 96 in the region further to the inner side than the inner edge portion of the second inner covering portion 112.

With reference to FIG. 22Q (the eighteenth layout example), the second inorganic film 110 does not necessarily have to have the first inner covering portion 111 and may expose an entirety of the source electrode 85. In this case, the second inorganic film 110 suffices to have at least the outer covering portion 113. The second inorganic film 110 may have the second inner covering portion 112 or does not have to have the second inner covering portion 112.

In this embodiment, the organic film 120 directly covers a peripheral edge portion of the first electrode surface 86 and the first electrode side wall 87 without interposition of the first inner covering portion 111 in a peripheral edge portion of the source electrode 85. That is, the wall surface of the first upper pad opening 121 may directly cover the peripheral edge portion of the first electrode surface 86.

With reference to FIG. 22R (the nineteenth layout example), the second inorganic film 110 does not necessarily have to have the second inner covering portion 112 and may expose an entirety of the gate electrode 95. In this case, the second inorganic film 110 suffices to have at least the outer covering portion 113. The second inorganic film 110 may have the first inner covering portion 111 or does not have to have the first inner covering portion 111.

In this embodiment, the organic film 120 directly covers a peripheral edge portion of the second electrode surface 96 and the second electrode side wall 97 without interposition of the second inner covering portion 112 in a peripheral edge portion of the gate electrode 95. That is, the wall surface of the second upper pad opening 122 may directly cover the peripheral edge portion of the second electrode surface 96.

The embodiment (including the modification examples) described above can be implemented in yet other modes. For example, with the embodiment described above, an example in which the mesa 11 (the first surface portion 8, the second surface portion 9, and the first to fourth connecting surface portions 10A to 10D) is demarcated in the first main surface 3 was illustrated. However, the first main surface 3 does not necessarily have to have the mesa 11 and may be formed flatly instead.

In this case, the active region 12 and the outer peripheral region 19 are demarcated by the outer well region 70. Also in this case, the first side end region 13, the second side end region 14, the first terminal region 15, the second terminal region 16, the third terminal region 17, and the fourth terminal region 18 may be removed.

With the embodiment described above, an example in which the anchor openings 83 are formed in the first inorganic film 75 was illustrated. However, the first inorganic film 75 not having the anchor openings 83 may be adopted instead.

With the embodiment described above, an example in which the source wiring 90 is connected to the source electrode 85 was illustrated. However, with the source wiring 90, a mode that is electrically separated from the source electrode 85 may be adopted instead. In this case, the source wiring 90 may be formed in an electrically floating state as a floating wiring or a field wiring (a so-called field plate).

In the embodiment described above, a structure in which the conductivity type of a semiconductor region of the “n-type” is inverted to the “p-type” and the conductivity type of a semiconductor region of the “p-type” is inverted to the “n-type” may be adopted. The specific arrangement in this case is obtained by replacing “n-type” with “p-type” and replacing “p-type” with “n-type” at the same time in the above description and attached drawings.

With the embodiment described above, the chip 2 including the SiC monocrystal is adopted. However, the chip 2 may include a silicon monocrystal instead. Similarly, the first semiconductor region 6 may include a silicon monocrystal. Similarly, the second semiconductor region 7 may include a silicon monocrystal.

In the embodiment described above, a collector region of the p-type may be formed in a surface layer portion of the second main surface 4 of the chip 2. In this case, the transistor structure Tr includes an IGBT (insulated gate bipolar transistor) structure in place of the MISFET structure. The specific arrangement in this case is obtained by replacing the “source” of the MISFET structure with an “emitter” of the IGBT structure and replacing the “drain” of the MISFET structure with a “collector” of the IGBT structure in the above description. In this case, the chip 2 may have a single layer structure constituted of a semiconductor substrate of the n-type.

In the embodiment described above, the first semiconductor region 6 (the second semiconductor region 7) may be formed as a portion or a whole of a cathode region of a semiconductor rectifier (a diode) and the body region 20 may be formed as a portion or a whole of an anode region of the semiconductor rectifier (the diode). In this case, the source electrode 85 is formed as an anode electrode and the drain electrode 125 is formed as a cathode electrode. As a matter of course, a Schottky electrode (an anode electrode) forming a Schottky junction with the second semiconductor region 7 may be adopted in place of the body region 20 (the anode region) and the source electrode 85.

Hereinafter, examples of features extracted from the present description and the drawings shall be indicated below. Hereinafter, the alphanumeric characters, etc., in parentheses represent the corresponding constituent elements, etc., in the embodiment described above, but are not intended to limit the scope of each clause to the embodiment. The “electronic component” in the following clauses may be replaced with a “semiconductor device,” an “SiC semiconductor device,” a “wide bandgap semiconductor device,” “a semiconductor switching device,” a “MISFET device,” an “IGBT device,” a “semiconductor rectifier,” etc., as needed.

[A1] An electronic component (1) comprising: a covered object (75); an electrode (85, 95) that is arranged on the covered object (75) and has an electrode side wall (87, 97) on the covered object (75); a wiring (90, 100) that is arranged on the covered object (75) in a periphery of the electrode (85, 95); an inorganic film (110) with an insulating property that has an inner covering portion (111, 112) covering the electrode (85, 95) so as to expose the electrode side wall (87, 97) and an outer covering portion (113) covering the wiring (90, 100) at an interval from the inner covering portion (111, 112); and an organic film (120) with an insulating property that extends across the inner covering portion (111, 112) and the outer covering portion (113) and covers the electrode (85, 95) between the inner covering portion (111, 112) and the outer covering portion (113).

[A2] The electronic component (1) according to A1, wherein the wiring (90, 100) has a wiring side wall (93, 103) on an opposite side to the electrode (85, 95) in sectional view, the outer covering portion (113) covers the wiring side wall (93, 103) of the wiring (90, 100) in sectional view, and the organic film (120) covers the wiring side wall (93, 103) with the outer covering portion (113) interposed therebetween in sectional view.

[A3] The electronic component (1) according to A2, wherein the outer covering portion (113) covers an entirety of the wiring (90, 100) in sectional view, and the organic film (120) covers the entirety of the wiring (90, 100) with the outer covering portion (113) interposed therebetween in sectional view.

[A4] The electronic component (1) according to any one of A1 to A3, wherein the outer covering portion (113) exposes the electrode side wall (87, 97) in sectional view, and the organic film (120) has a portion that directly covers the electrode side wall (87, 97) in sectional view.

[A5] The electronic component (1) according to A4, wherein the inner covering portion (111, 112) covers the electrode (85, 95) at an interval from the electrode side wall (87, 97), and the outer covering portion (113) covers the covered object (75) at an interval from the electrode side wall (87, 97).

[A6] The electronic component (1) according to A5, wherein the inner covering portion (111, 112) exposes a peripheral edge portion of the electrode (85, 95), and the organic film (120) has a portion that directly covers the peripheral edge portion of the electrode (85, 95).

[A7] The electronic component (1) according to A5 or A6, wherein the organic film (120) has a portion that directly covers an exposed portion of the covered object (75) between the electrode (85, 95) and the outer covering portion (113).

[A8] The electronic component (1) according to any one of A1 to A7, wherein the inner covering portion (111, 112) exposes an inner portion of the electrode (85, 95).

[A9] The electronic component (1) according to any one of A1 to A8, wherein the organic film (120) exposes an edge portion of the inner covering portion (111, 112) on an inner portion side of the electrode (85, 95).

[A10] The electronic component (1) according to any one of A1 to A9, wherein the wiring (90, 100) is electrically connected to the electrode (85, 95).

[A11] The electronic component (1) according to any one of A1 to A10, wherein the wiring (90, 100) is led out from the electrode (85, 95).

[A12] The electronic component (1) according to any one of A1 to A11, wherein the wiring (90, 100) is an outermost peripheral wiring (90).

[A13] The electronic component (1) according to any one of A1 to A12, wherein the electrode (85, 95) is a source electrode (85) and the wiring (90, 100) is a source wiring (90).

[A14] The electronic component (1) according to any one of A1 to A13, further comprising: a chip (2); and wherein the covered object (75) is formed on the chip (2).

[A15] The electronic component (1) according to A14, further comprising: an active region (12) provided in an inner portion of the chip (2); and an outer peripheral region (19) provided in a peripheral edge portion of the chip (2); and wherein the covered object (75) covers both the active region (12) and the outer peripheral region (19), the electrode (85, 95) is arranged on the active region (12), and the wiring (90) is arranged on the outer peripheral region (19).

[A16] The electronic component (1) according to A14 or A15, wherein the chip (2) contains SiC.

[A17] The electronic component (1) according to any one of A1 to A16, further comprising: a second wiring (100) that is arranged on the covered object (75) in a region between the electrode (85) and the wiring (90); and wherein the organic film (120) covers the second wiring (100).

[A18] The electronic component (1) according to A17, wherein the outer covering portion (113) covers the second wiring (100), and the organic film (120) covers the second wiring (100) with the outer covering portion (113) interposed therebetween.

[B1] An electronic component (1) comprising: an electrode (85, 95) that is arranged in a first region (12) having a first electric field; a wiring (90) that is arranged in a second region (19) having a second electric field higher than the first electric field in a periphery of the electrode (85, 95); an inorganic film (110) with an insulating property that exposes the electrode (85, 95) and covers the wiring (90); and an organic film (120) with an insulating property that has a portion directly covering the electrode (85, 95) and a portion covering the wiring (90) with the inorganic film (110) interposed therebetween.

[B2] The electronic component (1) according to B1, wherein the electrode (85, 95) is a terminal electrode (85, 95).

[B3] The electronic component (1) according to B1 or B2, wherein the wiring (90) has a width smaller than a width of the electrode (85, 95).

[B4] The electronic component (1) according to any one of B1 to B3, wherein the inorganic film (110) exposes an electrode side wall (87, 97) of the electrode (85, 95).

[B5] The electronic component (1) according to B4, wherein the inorganic film (110) has an inner covering portion (111, 112) that covers the electrode (85, 95) at an interval from the electrode side wall (87, 97) and an outer covering portion (113) that covers the wiring (90) at an interval from the inner covering portion (111, 112), and the organic film (120) extends across the inner covering portion (111, 112) and the outer covering portion (113) and covers the electrode side wall (87, 97) of the electrode (85, 95) between the inner covering portion (111, 112) and the outer covering portion (113).

[B6] The electronic component (1) according to any one of B1 to B5, wherein the wiring (90) is equipotential with the electrode (85).

[B7] The electronic component (1) according to any one of B1 to B6, wherein the wiring (90) is connected to the electrode (85).

[B8] The electronic component (1) according to any one of B1 to B7, further comprising: a chip (2); and wherein the first region (12) is formed in the chip (2), the second region (19) is formed in a periphery of the first region (12) in the chip (2), the electrode (85, 95) is arranged on the first region (12), and the wiring (90) is arranged on the second region (19).

[B9] The electronic component (1) according to B8, wherein the first region (12) is an active region (12), the second region (19) is an outer peripheral region (19) in a periphery of the active region (12), the electrode (85, 95) is arranged on the active region (12), and the wiring (90) is arranged on the outer peripheral region (19).

[B10] The electronic component (1) according to B8 or B9, wherein the chip (2) contains SiC.

[C1] An electronic component (1) comprising: a chip (2) that has a main surface (3); an active region (12) that is provided in an inner portion of the main surface (3); an outer peripheral region (19) that is provided in a peripheral edge portion of the main surface (3); a device structure (Tr) that is formed in the main surface (3) in the active region (12); an impurity region (70) that is formed in a surface layer portion of the main surface (3) in the outer peripheral region (19); an electrode (85) that is arranged on the main surface (3) in the active region (12) and is electrically connected to the device structure (Tr); a wiring (90) that is arranged on the main surface (3) in the outer peripheral region (19) and is electrically connected to the impurity region (70); an inorganic film (110) with an insulating property that exposes the electrode (85) and covers the wiring (90); and an organic film (120) with an insulating property that has a portion directly covering the electrode (85) and a portion covering the wiring (90) with the inorganic film (110) interposed therebetween.

[C2] The electronic component (1) according to C1, wherein a conductivity type of the impurity region (70) is a p-type.

[C3] The electronic component (1) according to C1 or C2, wherein the device structure (Tr) includes a MISFET structure.

[C4] The electronic component (1) according to C1 or C2, wherein the device structure (Tr) includes an IGBT structure.

[D1] An electronic component (1) comprising: a terminal electrode; a wiring that is arranged in a periphery of the terminal electrode; an inorganic film with an insulating property that covers the wiring at an interval from the terminal electrode; and an organic film with an insulating property that has a portion directly covering the terminal electrode and a portion covering the wiring with the inorganic film interposed therebetween.

[E1] An electronic component (1) comprising: a covered object (75); a gate electrode (95) that is arranged on the covered object (75) and has an electrode side wall (97) on the covered object (75); a gate wiring (100) that is arranged on the covered object (75) in a periphery of the gate electrode (95); an inorganic film (110) with an insulating property that has an inner covering portion (112) covering the gate electrode (95) so as to expose the electrode side wall (97) and an outer covering portion (113) covering the gate wiring (100) at an interval from the inner covering portion (112); and an organic film (120) with an insulating property that extends across the inner covering portion (112) and the outer covering portion (113) and covers the gate electrode (95) between the inner covering portion (112) and the outer covering portion (113).

[F1] An electronic component (1) comprising: a covered object (75); a source electrode (85) that is arranged on the covered object (75) and has an electrode side wall (87) on the covered object (75); a gate wiring (100) that is arranged on the covered object (75) in a periphery of the source electrode (85); an inorganic film (110) with an insulating property that has an inner covering portion (111) covering the source electrode (85) so as to expose the electrode side wall (87) and an outer covering portion (113) covering the gate wiring (100) at an interval from the inner covering portion (111); and an organic film (120) with an insulating property that extends across the inner covering portion (111) and the outer covering portion (113) and covers the source electrode (85) between the inner covering portion (111) and the outer covering portion (113).

[G1] An electronic component (1) comprising: a covered object (75); a gate electrode (95) that is arranged on the covered object (75) and has an electrode side wall (97) on the covered object (75); a source wiring (90) that is arranged on the covered object (75) in a periphery of the gate electrode (95); an inorganic film (110) with an insulating property that has an inner covering portion (112) covering the gate electrode (95) so as to expose the electrode side wall (97) and an outer covering portion (113) covering the source wiring (90) at an interval from the inner covering portion (112); and an organic film (120) with an insulating property that extends across the inner covering portion (112) and the outer covering portion (113) and covers the gate electrode (95) between the inner covering portion (112) and the outer covering portion (113).

While specific embodiments have been described in detail above, this is merely a specific example used to clarify the technical contents. The various technical ideas extracted from this Description are not limited by the order of description, the order of embodiments, etc., in the Description and can be combined as appropriate with each other.

What is claimed is:

1. An electronic component comprising:
a covered object;
an electrode that is arranged on the covered object and has an electrode side wall on the covered object;
a wiring that is arranged on the covered object in a periphery of the electrode;
an inorganic film with an insulating property that has an inner covering portion covering the electrode so as to expose the electrode side wall and an outer covering portion covering the wiring at an interval from the inner covering portion; and
an organic film with an insulating property that extends across the inner covering portion and the outer covering portion and covers the electrode between the inner covering portion and the outer covering portion.

2. The electronic component according to claim 1,
wherein the wiring has a wiring side wall on an opposite side to the electrode in sectional view,
the outer covering portion covers the wiring side wall of the wiring in sectional view, and
the organic film covers the wiring side wall with the outer covering portion interposed therebetween in sectional view.

3. The electronic component according to claim 2,
wherein the outer covering portion covers an entirety of the wiring in sectional view, and
the organic film covers the entirety of the wiring with the outer covering portion interposed therebetween in sectional view.

4. The electronic component according to claim 1,
wherein the outer covering portion exposes the electrode side wall in sectional view, and
the organic film has a portion that directly covers the electrode side wall in sectional view.

5. The electronic component according to claim 4,
wherein the inner covering portion covers the electrode at an interval from the electrode side wall, and
the outer covering portion covers the covered object at an interval from the electrode side wall.

6. The electronic component according to claim 5,
wherein the inner covering portion exposes a peripheral edge portion of the electrode, and
the organic film has a portion directly that covers the peripheral edge portion of the electrode.

7. The electronic component according to claim 5,
wherein the organic film has a portion directly that covers a region of the covered object between the electrode and the outer covering portion.

8. The electronic component according to claim 1,
wherein the inner covering portion exposes an inner portion of the electrode.

9. The electronic component according to claim 1,
wherein the organic film exposes an edge portion of the inner covering portion on an inner portion side of the electrode.

10. The electronic component according to claim 1,
wherein the wiring is electrically connected to the electrode.

11. The electronic component according to claim 1,
wherein the wiring is led out from the electrode.

12. The electronic component according to claim 1,
wherein the wiring is an outermost peripheral wiring.

13. The electronic component according to claim 1,
wherein the electrode is a source electrode, and
the wiring is a source wiring.

14. The electronic component according to claim 1, further comprising:
a chip; and
wherein the covered object is formed on the chip.

15. The electronic component according to claim 14, further comprising:
an active region provided in an inner portion of the chip; and
an outer peripheral region provided in a peripheral edge portion of the chip; and
wherein the covered object covers both the active region and the outer peripheral region,
the electrode is arranged on the active region, and
the wiring is arranged on the outer peripheral region.

16. The electronic component according to claim 14,
wherein the chip contains SiC.

17. The electronic component according to claim 1, further comprising:
a second wiring that is arranged on the covered object in a region between the electrode and the wiring; and
wherein the organic film covers the second wiring.

18. The electronic component according to claim 17,
wherein the outer covering portion covers the second wiring, and
the organic film covers the second wiring with the outer covering portion interposed therebetween.

19. An electronic component comprising:
a terminal electrode;
a wiring that is arranged in a periphery of the terminal electrode;
an inorganic film with an insulating property that covers the wiring at an interval from the terminal electrode; and
an organic film with an insulating property that has a portion directly covering the terminal electrode and a portion covering the wiring with the inorganic film interposed therebetween.

20. An electronic component comprising:
an electrode that is arranged in a first region having a first electric field;
a wiring that is arranged in a second region having a second electric field higher than the first electric field in a periphery of the electrode;
an inorganic film with an insulating property that exposes the electrode and covers the wiring; and
an organic film with an insulating property that has a portion directly covering the electrode and a portion covering the wiring with the inorganic film interposed therebetween.
